(19) United States
(12) Patent Application Publication
(10) Pub. No.: US 2025/0280531 A1
(43) Pub. Date: Sep. 4, 2025

(54) SEMICONDUCTOR DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Satoru OHSHITA, Hadano, Kanagawa (JP); Hiromichi GODO, Isehara, Kanagawa (JP); Yoshiyuki KUROKAWA, Sagamihara, Kanagawa (JP)

(21) Appl. No.: 18/857,991

(22) PCT Filed: Apr. 10, 2023
(86) PCT No.: PCT/IB2023/053623

§ 371 Date: Oct. 18, 2024

(30) Foreign Application Priority Data
Apr. 22, 2022 (JP) 2022-070580

(51) Int. Cl. H10B 12/00; H10D 30/67

(52) U.S. Cl. CPC H10B 12/50; H10D 30/6755

(57) ABSTRACT

A semiconductor device with a small circuit scale and reduced power consumption is provided. The semiconductor device includes first to fourth cells, first and second circuits, and first to fourth current generation circuits. The first cell is electrically connected to the third cell through a first wiring and the first current generation circuit, and is electrically connected to the first circuit through a second wiring. The second cell is electrically connected to the fourth cell through a third wiring and the second current generation circuit, and is electrically connected to the second circuit through a fourth wiring. The third cell is electrically connected to the second cell through the third current generation circuit and the fourth wiring. The fourth cell is electrically connected to the first cell through the fourth current generation circuit and the second wiring. The first and second current generation circuits each function as a current mirror circuit, and the third and fourth current generation circuits each function as an arithmetic circuit of a function system. The first and second cells perform an arithmetic operation of a product, and the third and fourth cells retain the result of the arithmetic operation.

### TECHNICAL FIELD

One embodiment of the present invention relates to a semiconductor device and an electronic device.

Note that one embodiment of the present invention is not limited to the above technical field. The technical field of the invention disclosed in this specification and the like relates to an object, a driving method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an image capturing device, a memory device, a signal processing device, a processor, an electronic device, a system, a driving method thereof, a manufacturing method thereof, and a testing method thereof.

### BACKGROUND ART

Integrated circuits that imitate the mechanism of the human brain are currently under active development. The integrated circuits incorporate the brain mechanism as electronic circuits and include circuits corresponding to “neurons” and “synapses” of the human brain. Such integrated circuits may therefore be referred to as “neuromorphic”, “brain-morphic”, or “brain-inspired” circuits, for example. The integrated circuits have a non-von Neumann architecture and are expected to be able to perform parallel processing with extremely low power consumption as compared with a von Neumann architecture, which consumes higher power with increasing processing speed.

An information processing model that imitates a biological neural network including “neurons” and “synapses” is referred to as an artificial neural network (ANN). For example, Non-Patent Document 1 and Non-Patent Document 2 each disclose an arithmetic device including an artificial neural network constructed using an SRAM (Static Random Access Memory).

An attempt has been made to use an arithmetic device in which an artificial neural network is constructed, for example, for correction of images to be displayed by a display apparatus. For example, in a display apparatus disclosed in Patent Document 1, an arithmetic circuit in which an artificial neural network is constructed is used to adjust the luminance, tone, and the like of displayed images in accordance with the preference of the person who watches the images.

### REFERENCES

### Patent Document

[Patent Document 1] Japanese Published Patent Application No. 2018-36639

### Non-Patent Documents

[Non-Patent Document 1] M. Kang et al., “IEEE Journal Of Solid-State Circuits”, 2018, Volume 53, No. 2, p. 642-655.
[Non-Patent Document 2] J. Zhang et al., “IEEE Journal Of Solid-State Circuits”, 2017, Volume 52, No. 4, p. 915-924.

### SUMMARY OF THE INVENTION

### Problems to be Solved by the Invention

Examples of an arithmetic circuit in which an artificial neural network is constructed include an arithmetic circuit (hereinafter sometimes referred to as analog product-sum operation circuit) that performs a product-sum operation by yielding the sum of analog currents each corresponding to the product of a weight coefficient and input data. Since the arithmetic circuit uses analog currents for an arithmetic operation, the circuit scale can be smaller than that of an arithmetic circuit formed of a digital circuit, and the circuit area can be small. Furthermore, the arithmetic circuit can have lower power consumption when designed such that the analog current used in the arithmetic operation becomes lower.

On another note, in the case of using the above-described analog product-sum operation circuit, digital data to be input to the analog product-sum operation circuit needs to be converted into an analog current. Since the arithmetic operation result of the analog product-sum operation circuit is output as analog data, the analog data needs to be converted into digital data in the case where the arithmetic operation result is used by a digital circuit. That is, using the analog product-sum operation circuit necessitates a digital-analog converter circuit (a digital voltage (signal)-analog current converter circuit, IDAC) and an analog-digital converter circuit (ADC).

In particular, since an artificial neural network sometimes performs a product-sum operation a plurality of times, digital-analog conversion and analog-digital conversion are performed every time a product-sum operation is performed; thus, the conversion processing may consume high power. In the case where a product-sum operation is performed a plurality of times, a plurality of analog product-sum operation circuits are preferably used, in which case, however, as many digital-analog converter circuits and as many analog-digital converter circuits as the analog product-sum operation circuits are needed, and thus, the circuit area is increased in some cases.

An object of one embodiment of the present invention is to provide a semiconductor device with reduced power consumption. Another object of one embodiment of the present invention is to provide a semiconductor device with a small circuit area. Another object of one embodiment of the present invention is to provide a semiconductor device capable of performing arithmetic operations successively. Another object of one embodiment of the present invention is to provide a novel semiconductor device. Another object of one embodiment of the present invention is to provide an electronic device that includes the above semiconductor device.

Note that the objects of one embodiment of the present invention are not limited to the above objects. The above objects do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the above objects and the other objects. Note that one embodiment of the present invention does not necessarily achieve all of the above objects and the other objects.

### Means for Solving the Problems

(1)

One embodiment of the present invention is a semiconductor device that includes a first cell, a second cell, a third cell, a fourth cell, a first circuit, a second circuit, a first current generation circuit, a second current generation circuit, a third current generation circuit, and a fourth current generation circuit.

The first cell is electrically connected to a first input terminal of the first current generation circuit through a first wiring, and the first cell is electrically connected to the first circuit and a fourth output terminal of the fourth current generation circuit through a second wiring. The second cell is electrically connected to a second input terminal of the second current generation circuit through a third wiring, and the second cell is electrically connected to the second circuit and a third output terminal of the third current generation circuit through a fourth wiring. The third cell is electrically connected to a first output terminal of the first current generation circuit and a third input terminal of the third current generation circuit. The fourth cell is electrically connected to a second output terminal of the second current generation circuit and a fourth input terminal of the fourth current generation circuit.

The first circuit has a function of generating a first current and outputting the first current to the second wiring. The second circuit has a function of generating a second current and outputting the second current to the fourth wiring. The first current generation circuit as a current mirror circuit has a function of outputting, from the first output terminal, a current with an amount corresponding to an amount of a current flowing through the first input terminal. The second current generation circuit as a current mirror circuit has a function of outputting, from the second output terminal, a current with an amount corresponding to an amount of a current flowing through the second input terminal. The third current generation circuit as an arithmetic circuit of a function system has a function of outputting, from the third output terminal, a third current with an amount corresponding to an amount of a current flowing through the third input terminal. The fourth current generation circuit as an arithmetic circuit of a function system has a function of outputting, from the fourth output terminal, a fourth current with an amount corresponding to an amount of a current flowing through the fourth input terminal.

The first cell has a function of retaining a potential corresponding to first data and a function of generating a fifth current with an amount corresponding to a product of a value of the first data and a value corresponding to the first current or the fourth current flowing through the second wiring and outputting the fifth current to the first wiring. The second cell has a function of retaining a potential corresponding to second data and a function of generating a sixth current with an amount corresponding to a product of a value of the second data and a value corresponding to the second current or the third current flowing through the fourth wiring and outputting the sixth current to the third wiring. The third cell has a function of retaining a potential corresponding to the fifth current. The fourth cell has a function of retaining a potential corresponding to the sixth current.

(2)

Another embodiment of the present invention may have the structure of (1) above that further includes a first switching circuit, a second switching circuit, a third switching circuit, a fourth switching circuit, and a fifth switching circuit.

Specifically, the first switching circuit preferably includes a first terminal, a second terminal, a third terminal, and a fourth terminal. The second switching circuit preferably includes a fifth terminal, a sixth terminal, and a seventh terminal. The third switching circuit preferably includes an eighth terminal, a ninth terminal, and a tenth terminal. The fourth switching circuit preferably includes an eleventh terminal, a twelfth terminal, and a thirteenth terminal. The fifth switching circuit preferably includes a fourteenth terminal, a fifteenth terminal, and a sixteenth terminal.

It is preferable that the first terminal of the first switching circuit be electrically connected to the first wiring, the second terminal of the first switching circuit be electrically connected to the first input terminal of the first current generation circuit, the third terminal of the first switching circuit be electrically connected to the third wiring, and the fourth terminal of the first switching circuit be electrically connected to the second input terminal of the second current generation circuit. It is preferable that the fifth terminal of the second switching circuit be electrically connected to the first output terminal of the first current generation circuit, the sixth terminal of the second switching circuit be electrically connected to the third cell, and the seventh terminal of the second switching circuit be electrically connected to the third input terminal of the third current generation circuit. It is preferable that the eighth terminal of the third switching circuit be electrically connected to the second output terminal of the second current generation circuit, the ninth terminal of the third switching circuit be electrically connected to the fourth cell, and the tenth terminal of the third switching circuit be electrically connected to the fourth input terminal of the fourth current generation circuit. It is preferable that the eleventh terminal of the fourth switching circuit be electrically connected to the first circuit, the twelfth terminal of the fourth switching circuit be electrically connected to the second wiring, and the thirteenth terminal of the fourth switching circuit be electrically connected to the fourth output terminal of the fourth current generation circuit. It is preferable that the fourteenth terminal of the fifth switching circuit be electrically connected to the second circuit, the fifteenth terminal of the fifth switching circuit be electrically connected to the fourth wiring, and the sixteenth terminal of the fifth switching circuit be electrically connected to the third output terminal of the third current generation circuit.

It is preferable that the first switching circuit have a function of establishing a conduction state or a non-conduction state between the first terminal and the second terminal, a function of establishing a conduction state or a non-conduction state between the first terminal and the third terminal, and a function of establishing a conduction state or a non-conduction state between the third terminal and the fourth terminal. It is preferable that the second switching circuit have a function of establishing a conduction state or a non-conduction state between the fifth terminal and the sixth terminal and a function of establishing a conduction state or a non-conduction state between the sixth terminal and the seventh terminal. It is preferable that the third switching circuit have a function of establishing a conduction state or a non-conduction state between the eighth terminal and the ninth terminal and a function of establishing a conduction state or a non-conduction state between the ninth terminal and the tenth terminal. It is preferable that the fourth switching circuit have a function of establishing a conduction state or a non-conduction state between the eleventh terminal and the twelfth terminal and a function of establishing a conduction state or a non-conduction state between the twelfth terminal and the thirteenth terminal. It is preferable that the fifth switching circuit have a function of establishing a conduction state or a non-conduction state between the fourteenth terminal and the fifteenth terminal and a function of establishing a conduction state or a non-conduction state between the fifteenth terminal and the sixteenth terminal.

(3)

Another embodiment of the present invention may have the structure of (2) above that further includes a third circuit. Specifically, it is preferable that the third circuit be electrically connected to the first wiring. It is preferable that the third circuit have a function of making a seventh current corresponding to the first data flow to the first cell and a function of making an eighth current corresponding to the second data flow to the second cell.

(4)

Another embodiment of the present invention may have the structure of (3) above that further includes a fifth cell and a sixth cell. Specifically, it is preferable that each of the first cell, the second cell, the fifth cell, and the sixth cell include a first transistor, a second transistor, and a first capacitor.

In each of the first cell, the second cell, the fifth cell, and the sixth cell, it is preferable that one of a source and a drain of the first transistor be electrically connected to a gate of the second transistor, one of a source and a drain of the second transistor be electrically connected to the one of the source and the drain of the first transistor, and one of a pair of terminals of the first capacitor be electrically connected to the gate of the second transistor.

In the first cell, it is preferable that the other of the source and the drain of the first transistor be electrically connected to the first wiring, and the other of the pair of terminals of the first capacitor be electrically connected to the second wiring. In the second cell, it is preferable that the other of the source and the drain of the first transistor be electrically connected to the third wiring, and the other of the pair of terminals of the first capacitor be electrically connected to the fourth wiring.

In the fifth cell, it is preferable that the other of the source and the drain of the first transistor be electrically connected to the second wiring, and the other of the pair of terminals of the first capacitor be electrically connected to the second wiring. In the sixth cell, it is preferable that the other of the source and the drain of the first transistor be electrically connected to the fourth wiring, and the other of the pair of terminals of the first capacitor be electrically connected to the fourth wiring.

A channel formation region of each of the first transistor and the second transistor preferably includes a first oxide semiconductor. The first oxide semiconductor preferably includes one or more selected from indium, zinc, and an element M. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

(5)

Another embodiment of the present invention may have the structure of (4) above in which each of the third cell and the fourth cell includes a third transistor, a fourth transistor, a fifth transistor, and a second capacitor.

In each of the third cell and the fourth cell, it is preferable that one of a source and a drain of the third transistor be electrically connected to a gate of the fourth transistor, one of a source and a drain of the fourth transistor be electrically connected to one of a source and a drain of the fifth transistor, the other of the source and the drain of the fifth transistor be electrically connected to the other of the source and the drain of the third transistor, and the one of the pair of terminals of the first capacitor be electrically connected to the gate of the fourth transistor.

In the third cell, it is preferable that the other of the source and the drain of the third transistor be electrically connected to the sixth terminal of the second switching circuit. In the fourth cell, it is preferable that the other of the source and the drain of the third transistor be electrically connected to the ninth terminal of the third switching circuit.

A channel formation region of each of the third transistor and the fourth transistor preferably includes a second oxide semiconductor. The second oxide semiconductor preferably includes one or more selected from indium, zinc, and the element M described in (4).

(6)

Another embodiment of the present invention may have the structure of (5) above that further includes a first layer, a second layer located above the first layer, and a third layer located above the second layer. Specifically, it is preferable that the first layer include the first circuit, the second circuit, the third circuit, the first current generation circuit, the second current generation circuit, the third current generation circuit, and the fourth current generation circuit, the second layer include the third cell and the fourth cell, and the third layer include the first cell, the second cell, the fifth cell, and the sixth cell.

(7)

Another embodiment of the present invention may have the structure of (5) above that further includes a first layer, a second layer located above the first layer, a third layer located above the second layer, a fourth layer located above the third layer, and a fifth layer located above the fourth layer. Specifically, it is preferable that the first layer include the first circuit, the second circuit, the third circuit, the first current generation circuit, the second current generation circuit, the third current generation circuit, and the fourth current generation circuit, the second layer include the third cell, the third layer include the fourth cell, the fourth layer include the first cell and the fifth cell, and the fifth layer include the second cell and the sixth cell.

(8)

Another embodiment of the present invention is an electronic device that includes the semiconductor device of any one of (1) to (7) above and a housing.

### Effect of the Invention

According to one embodiment of the present invention, a semiconductor device with reduced power consumption can be provided. According to another embodiment of the present invention, a semiconductor device with a small circuit area can be provided. According to another embodiment of the present invention, a semiconductor device capable of performing arithmetic operations successively can be provided. According to another embodiment of the present invention, a novel semiconductor device can be provided. According to another embodiment of the present invention, an electronic device that includes the above semiconductor device can be provided.

Note that the effects of one embodiment of the present invention are not limited to the effects described above. The effects described above do not preclude the existence of other effects. The other effects are the ones that are not described in this section and will be described below. The effects that are not described in this section can be derived from the description of the specification, the drawings, and the like and can be extracted as appropriate from the description by those skilled in the art. One embodiment of the present invention has at least one of the above effects and the other effects. Accordingly, one embodiment of the present invention does not have the above effects in some cases.

### BRIEF DESCRIPTION OF THE DRAWINGS

FIG. 1 is a block diagram illustrating a structure example of a semiconductor device.

FIG. 2 is a circuit diagram illustrating a structure example of a circuit included in a semiconductor device.

FIG. 3 is a circuit diagram illustrating a structure example of a circuit included in a semiconductor device.

FIG. 4A and FIG. 4B are circuit diagrams each illustrating a structure example of a circuit included in a semiconductor device.

FIG. 5A to FIG. 5C are circuit diagrams each illustrating a structure example of a circuit included in a semiconductor device.

FIG. 6A to FIG. 6D are circuit diagrams each illustrating a structure example of a circuit included in a semiconductor device.

FIG. 7A to FIG. 7C are circuit diagrams each illustrating a structure example of a circuit included in a semiconductor device.

FIG. 8A and FIG. 8B are circuit diagrams each illustrating a structure example of a circuit included in a semiconductor device.

FIG. 9A to FIG. 9C are circuit diagrams each illustrating a structure example of a circuit included in a semiconductor device.

FIG. 10 is a circuit diagram illustrating a structure example of a circuit included in a semiconductor device.

FIG. 11A and FIG. 11B are circuit diagrams each illustrating a structure example of a circuit included in a semiconductor device.

FIG. 12 is a timing chart illustrating an operation example of a semiconductor device.

FIG. 13A to FIG. 13C are block diagrams illustrating an operation example of a semiconductor device.

FIG. 14A to FIG. 14C are block diagrams illustrating an operation example of a semiconductor device.

FIG. 15A and FIG. 15B are block diagrams illustrating an operation example of a semiconductor device.

FIG. 16 is a flowchart illustrating an operation example of a semiconductor device.

FIG. 17 is a block diagram illustrating a structure example of a semiconductor device.

FIG. 18A is a schematic perspective view showing a structure example of a semiconductor device, and FIG. 18B is a block diagram showing the structure example of the semiconductor device.

FIG. 19 is a schematic cross-sectional view showing a structure example of a semiconductor device.

FIG. 20 is a schematic cross-sectional view showing a structure example of a semiconductor device.

FIG. 21 is a schematic perspective view showing a structure example of a semiconductor device.

FIG. 22 is a block diagram showing a structure example of a semiconductor device.

FIG. 23A and FIG. 23B are diagrams showing examples of electronic components.

FIG. 24A and FIG. 24B are diagrams showing examples of electronic devices, and FIG. 24C to FIG. 24E are diagrams showing an example of a large computer.

FIG. 25 is a diagram showing an example of space equipment.

FIG. 26 is a diagram showing an example of a storage system applicable to a data center.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, and an electronic component including a chip in a package are each an example of the semiconductor device. Moreover, a memory device, a display apparatus, a light-emitting apparatus, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, and a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conduction state (on state) or a non-conduction state (off state) to control whether a current flows or not.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of a current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

This specification describes a circuit structure in which a plurality of elements are electrically connected to a wiring (a wiring for supplying a constant potential or a wiring for transmitting a signal). For example, in the case where X is directly connected to a wiring and Y is directly connected to the wiring, this specification may describe that X and Y are directly electrically connected to each other.

It can be expressed as, for example, “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression similar to the above examples, a source and a drain of a transistor can be distinguished from each other to specify the technical scope. Note that these expressions are examples and the expression is not limited to these expressions. Here, each of X and Y denotes an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0 Ω or a wiring having a resistance value higher than 0Ω. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of an off-state current can be reduced, and the breakdown voltage of the transistor can be increased (the reliability can be improved). Alternatively, with the multi-gate structure, a drain-source current does not change very much even if a drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. For another example, the case where a single capacitor is illustrated in a circuit diagram may indicate a case where two or more capacitors are electrically connected to each other in parallel. For another example, the case where a single transistor is illustrated in a circuit diagram may indicate a case where two or more transistors are electrically connected to each other in series and their gates are electrically connected to each other. Similarly, for another example, the case where a single switch is illustrated in a circuit diagram may indicate a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, an impurity region, or the like depending on the circuit structure and the device structure. Furthermore, a terminal, a wiring, or the like can be referred to as a node.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to a charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive charge moves, and the amount of the current is expressed as a positive value. In other words, the direction in which a carrier with negative charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) the top surface of a conductor” can be replaced with the expression “an insulator positioned under (on) a bottom surface of a conductor” when the direction of a drawing showing these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed over and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relation are sometimes described using terms such as “row” and “column”. The positional relation between components is changed as appropriate in accordance with the direction in which the components are described. Thus, the positional relation is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be replaced with the term “insulating layer” in some cases. Alternatively, the terms “film” and “layer” are not used and can be interchanged with another term depending on the case or the situation. For example, the term “conductive layer” or “conductive film” can be replaced with the term “conductor” in some cases. For another example, the term “insulating layer” or “insulating film” can be replaced with the term “insulator” in some cases.

In this specification and the like, the terms “electrode”, “wiring”, and “terminal” do not limit the functions of such components. For example, an “electrode” is used as part of a “wiring” in some cases, and vice versa. Furthermore, the term “electrode” or “wiring” also includes, for example, the case where a plurality of “electrodes”, “wirings”, or the like are formed in an integrated manner. For example, a “terminal” is used as part of a “wiring” or an “electrode” in some cases, and vice versa. Furthermore, the term “terminal” also includes, for example, the case where one or more selected from “electrodes”, “wirings”, and “terminals” are formed in an integrated manner. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be replaced with the term “signal line” in some cases. For another example, the term “wiring” can be replaced with the term “power supply line” or the like in some cases. Conversely, the term “signal line” or “power supply line” can be replaced with the term “wiring” in some cases. The term “power supply line” can be replaced with the term “signal line” in some cases. Conversely, the term “signal line” can be replaced with the term “power supply line” in some cases. The term “potential” that is applied to a wiring can be replaced with the term “signal” depending on the case or the situation. Conversely, the term “signal” can be replaced with the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the circumstances. For example, even when two periods are shown to have an equal length, the two periods have different lengths in some cases. Furthermore, for example, even when one of two periods is shown long and the other is shown short, the two periods have the equal length in some cases, and the one period has a short length and the other has a long length in other cases.

In this specification and the like, a flowchart is used in some cases to describe an operation method of a semiconductor device. In this specification and the like, processing shown in the flowchart is classified on the operation basis and illustrated as independent steps. However, in actual processing, it is difficult to separate processing shown in the flowchart on the operation basis, and there is a case where a plurality of steps are associated with one step or a case where one step is associated with a plurality of steps. Thus, the processing illustrated in the flowchart is not limited to each step described in the specification, and the steps can be interchanged as appropriate according to circumstances. Specifically, the order of steps can be changed, a step can be added or omitted according to circumstances.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also collectively referred to as a metal oxide in some cases. A metal oxide containing nitrogen may be called a metal oxynitride.

In this specification and the like, an impurity in a semiconductor refers to, for example, an element other than a main component of a semiconductor layer. For example, an element with a concentration lower than 0.1 atomic % is an impurity. When an impurity is contained, for example, one or more selected from an increase in the density of defect states in a semiconductor, a decrease in carrier mobility, and a decrease in crystallinity may occur. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen.

In this specification and the like, a switch has a function of being in a conduction state (on state) or a non-conduction state (off state) to control whether a current flows or not. Alternatively, a switch has a function of selecting and changing a current path. Thus, a switch may have two or more terminals through which a current flows, in addition to a control terminal. For example, an electrical switch or a mechanical switch can be used. That is, a switch can be any element capable of controlling a current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor (a transistor in which a conduction state is established between its gate and drain)), and a logic circuit in which such elements are combined. Note that in the case of using a transistor as a switch, a “conduction state” of the transistor refers to a state where a source electrode and a drain electrode of the transistor can be regarded as being electrically short-circuited or a state where a current can be made to flow between the source electrode and the drain electrode. Furthermore, a “non-conduction state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) described in the embodiment and a content (or part of the content) described in one or more different embodiments.

Note that in each embodiment, a content described in the embodiment is a content described using a variety of diagrams or a content described with text disclosed in the specification. Note that by combining a diagram (or part thereof) described in one embodiment with at least one of another part of the diagram, a different diagram (or part thereof) described in the embodiment, and a diagram (or part thereof) described in one or more different embodiments, much more diagrams can be formed.

Embodiments described in this specification are described with reference to the drawings. Note that the embodiments can be implemented in many different modes, and it will be readily appreciated by those skilled in the art that modes and details can be changed in various ways without departing from the spirit and scope thereof. Therefore, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes denoted without such identification signs in this specification and the like when the components do not need to be distinguished from each other.

In the drawings in this specification, the size, the layer thickness, or the region is exaggerated for clarity in some cases. Therefore, they are not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### Embodiment 1

In this embodiment, an arithmetic circuit that is a semiconductor device of one embodiment of the present invention will be described.

### <Structure Example of Arithmetic Circuit>

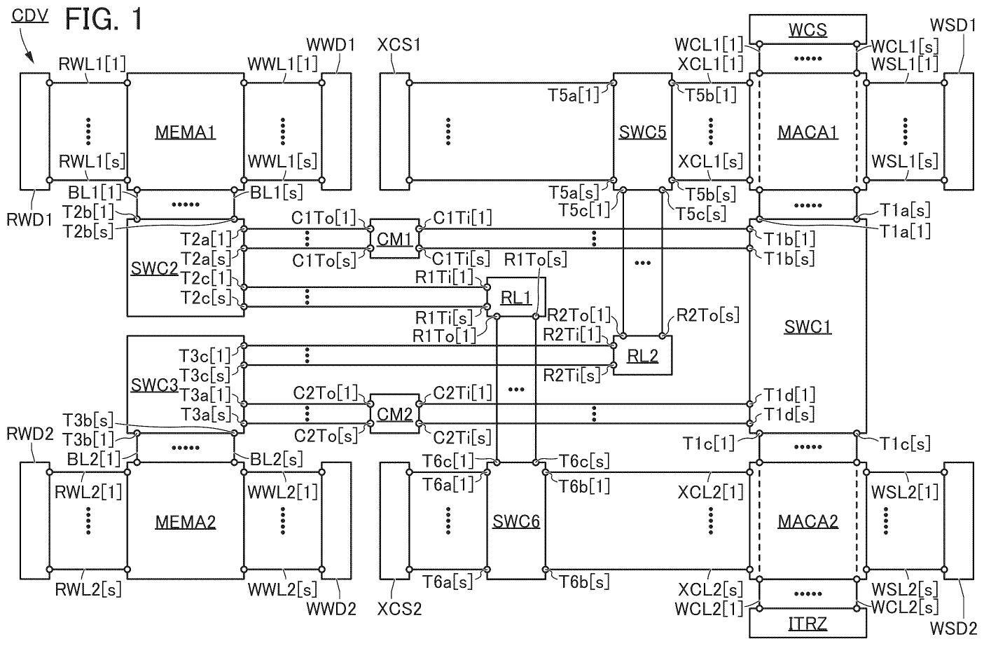

An arithmetic circuit CDV illustrated in FIG. 1 is a semiconductor device of one embodiment of the present invention, and is an arithmetic circuit capable of successively executing a product-sum operation and an arithmetic operation of a function system a plurality of times.

The arithmetic circuit CDV includes an arithmetic cell array MACA1, an arithmetic cell array MACA2, a memory cell array MEMA1, and a memory cell array MEMA2.

The arithmetic circuit CDV includes a circuit XCS1 and a circuit WSD1 as driver circuits of the arithmetic cell array MACA1. The arithmetic circuit CDV includes a circuit XCS2 and a circuit WSD2 as driver circuits of the arithmetic cell array MACA2. The arithmetic circuit CDV includes a circuit WCS and a circuit ITRZ as driver circuits of the arithmetic cell array MACA1 and the arithmetic cell array MACA2.

The arithmetic circuit CDV includes a circuit WWD1 and a circuit RWD1 as driver circuits of the memory cell array MEMA1. The arithmetic circuit CDV includes a circuit WWD2 and a circuit RWD2 as driver circuits of the memory cell array MEMA2.

The arithmetic circuit CDV includes a current generation circuit CM1, a current generation circuit CM2, a current generation circuit RL1, and a current generation circuit RL2.

The current generation circuit CM1 includes a terminal C1Ti[1] to a terminal C1Ti[s] and a terminal C1To[1] to a terminal C1To[s]. The current generation circuit CM2 includes a terminal C2Ti[1] to a terminal C2Ti[s] and a terminal C2To[1] to a terminal C2To[s]. The current generation circuit RL1 includes a terminal R1Ti[1] to a terminal R1Ti[s] and a terminal R1To[1] to a terminal R1To[s]. The current generation circuit RL2 includes a terminal R2Ti[1] to a terminal R2Ti[s] and a terminal R2To[1] to a terminal R2To[s].

The arithmetic circuit CDV includes a switching circuit SWC1, a switching circuit SWC2, a switching circuit SWC3, a switching circuit SWC5, and a switching circuit SWC6.

The switching circuit SWC1 includes a terminal T1a[1] to a terminal T1a[s], a terminal T1b[1] to a terminal T1b[s], a terminal T1c[1] to a terminal T1c[s], and a terminal T1d[1] to a terminal T1d[s]. The switching circuit SWC2 includes a terminal T2a[1] to a terminal T2a[s], a terminal T2b[1] to a terminal T2b[s], and a terminal T2c[1] to a terminal T2c[s]. The switching circuit SWC3 includes a terminal T3a[1] to a terminal T3a[s], a terminal T3b[1] to a terminal T3b[s], and a terminal T3c[1] to a terminal T3c[s]. The switching circuit SWC5 includes a terminal T5a[1] to a terminal T5a[s], a terminal T5b[1] to a terminal T5b[s], and a terminal T5c[1] to a terminal T5c[s]. The switching circuit SWC6 includes a terminal T6a[1] to a terminal T6a[s], a terminal T6b[1] to a terminal T6b[s], and a terminal T6c[1] to a terminal T6c[s]. Each of the arithmetic cell array MACA1 and the arithmetic cell array MACA2 includes a plurality of arithmetic cells arranged in a matrix of s rows and s columns (s is an integer greater than or equal to 1), for example.

Furthermore, a wiring XCL1[1] to a wiring XCL1[s] and a wiring WSL1[1] to a wiring WSL1[s] extend in the row direction of the arithmetic cell array MACA1. A wiring WCL1[1] to a wiring WCL1[s] extend in the column direction of the arithmetic cell array MACA1.

A wiring XCL2[1] to a wiring XCL2[s] and a wiring WSL2[1] to a wiring WSL2[s] extend in the row direction of the arithmetic cell array MACA2. A wiring WCL2[1] to a wiring WCL2[s] extend in the column direction of the arithmetic cell array MACA2.

The circuit WCS is electrically connected to the wiring WCL1[1] to the wiring WCL1[s]. The circuit WSD1 is electrically connected to the wiring WSL1[1] to the wiring WSL1[s]. The terminal T5a[1] to the terminal T5a[s] of the switching circuit SWC5 are electrically connected to the circuit XCS1.

The terminal T5b[k] (k is an integer greater than or equal to 1 and less than or equal to s) of the switching circuit SWC5 is electrically connected to the wiring XCL1[k] (note that the terminal T5b[k] and the wiring XCL1[k] are not shown in FIG. 1). In the structure shown in FIG. 1, the terminal T5b[1] of the switching circuit SWC5 is electrically connected to the wiring XCL1[1], and the terminal T5b[s] of the switching circuit SWC5 is electrically connected to the wiring XCL1[s]. The terminal T5c[k] of the switching circuit SWC5 is electrically connected to the terminal R2To[k] of the current generation circuit RL2 (note that the terminal T5c[k] and the terminal R2To[k] are not shown in FIG. 1). In the structure shown in FIG. 1, the terminal T5c[1] of the switching circuit SWC5 is electrically connected to the terminal R2To[1] of the current generation circuit RL2, and the terminal T5c[s] of the switching circuit SWC5 is electrically connected to the terminal R2To[s] of the current generation circuit RL2.

Note that in the description in this embodiment, the first to s-th components are collectively replaced with the k-th component in some cases. For example, description of the terminal T5a[1] to the terminal T5a[s] of the switching circuit SWC5 is sometimes replaced with description of the terminal T5a[k] of the switching circuit SWC5. For another example, description of the terminal R2To[1] to the terminal R2To[s] of the current generation circuit RL2 is sometimes replaced with description of the terminal R2To[k] of the current generation circuit RL2.

The terminal T1a[k] of the switching circuit SWC1 is electrically connected to the wiring WCL1[k] (note that the terminal T1a[k] and the wiring WCL1[k] are not shown in FIG. 1). The terminal T1b[k] of the switching circuit SWC1 is electrically connected to the terminal C1Ti[k] of the current generation circuit CM1 (note that the terminal T1b[k] and the terminal C1Ti[k] are not shown in FIG. 1). The terminal T1c[k] of the switching circuit SWC1 is electrically connected to the wiring WCL2[k] (note that the terminal T1c[k] and the wiring WCL2[k] are not shown in FIG. 1). The terminal T1d[k] of the switching circuit SWC1 is electrically connected to the terminal C2Ti[k] of the current generation circuit CM2 (note that the terminal T1d[k] and the terminal C2Ti[k] are not shown in FIG. 1).

The circuit WSD2 is electrically connected to the wiring WSL2[1] to the wiring WSL2[s]. The terminal T6a[1] to the terminal T6a[s] of the switching circuit SWC6 are electrically connected to the circuit XCS2. The terminal T6b[k] of the switching circuit SWC6 is electrically connected to the wiring XCL2[k] (note that the terminal T6b[1] and the wiring XCL2[k] are not shown in FIG. 1). The terminal T6c[k] of the switching circuit SWC6 is electrically connected to the terminal R1To[k] of the current generation circuit RL1 (note that the terminal T6c[k] and the terminal R1To[k] are not shown in FIG. 1).

Each of the memory cell array MEMA1 and the memory cell array MEMA2 includes a plurality of arithmetic cells arranged in a matrix of s rows and s columns, for example.

Furthermore, a wiring WWL1[1] to a wiring WWL1[s] and a wiring RWL1[1] to a wiring RWL1[s] extend in the row direction of the memory cell array MEMA1. A wiring BL1[1] to a wiring BL1[s] extend in the column direction of the arithmetic cell array MEMA1.

Furthermore, a wiring WWL2[1] to a wiring WWL2[s] and a wiring RWL2[1] to a wiring RWL2[s] extend in the row direction of the memory cell array MEMA2. A wiring BL2[1] to a wiring BL2[s] extend in the column direction of the arithmetic cell array MEMA2.

The circuit WWD1 is electrically connected to the wiring WWL1[1] to the wiring WWL1[s]. The circuit RWD1 is electrically connected to the wiring RWL1[1] to the wiring RWL1[s].

The terminal T2b[k] of the switching circuit SWC2 is electrically connected to the wiring BL1[k] (note that the terminal T2b[k] and the wiring BL1[k] are not shown in FIG. 1). The terminal T2a[k] of the switching circuit SWC2 is electrically connected to the terminal C1To[k] of the current generation circuit CM1 (note that the terminal T2a[k] and the terminal C1To[k] are not shown in FIG. 1). The terminal T2c[k] of the switching circuit SWC2 is electrically connected to the terminal R1Ti[k] of the current generation circuit RL1 (note that the terminal T2c[k] and the terminal R1Ti[k] are not shown in FIG. 1).

The circuit WWD2 is electrically connected to the wiring WWL2[1] to the wiring WWL2[s]. The circuit RWD2 is electrically connected to the wiring RWL2[1] to the wiring RWL2[s].

The terminal T3b[k] of the switching circuit SWC3 is electrically connected to the wiring BL2[k] (note that the terminal T3b[k] and the wiring BL2[k] are not shown in FIG. 1). The terminal T3a[k] of the switching circuit SWC3 is electrically connected to the terminal C2To[k] of the current generation circuit CM2 (note that the terminal T3a[k] and the terminal C2To[k] are not shown in FIG. 1). The terminal T3c[k] of the switching circuit SWC3 is electrically connected to the terminal C2Ti[k] of the current generation circuit RL2 (note that the terminal T3c[k] and the terminal R2Ti[k] are not shown in FIG. 1).

### <Structure Example of Circuits Included in Arithmetic Circuit>

Next, components included in the arithmetic circuit CDV illustrated in FIG. 1 will be described.

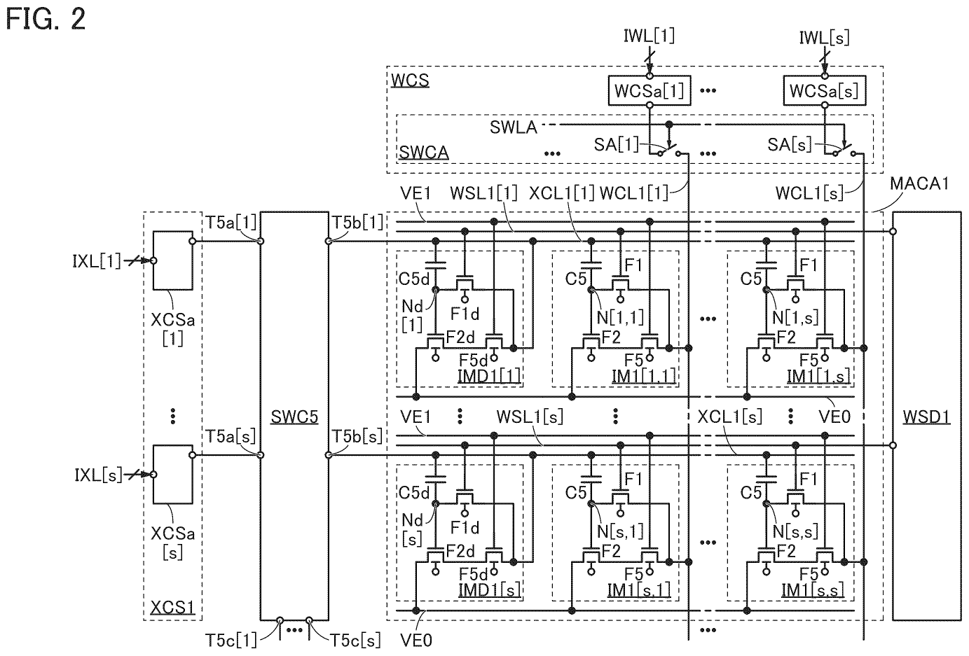

FIG. 2 is a diagram selectively illustrating the arithmetic cell array MACA1, the circuit WSD1, the circuit WCS, the circuit XCS1, and the switching circuit SWC5 in the arithmetic circuit CDV in FIG. 1. Specifically, FIG. 2 also illustrates circuit structures of the arithmetic cell array MACA1, the circuit WCS, and the circuit XCS1.

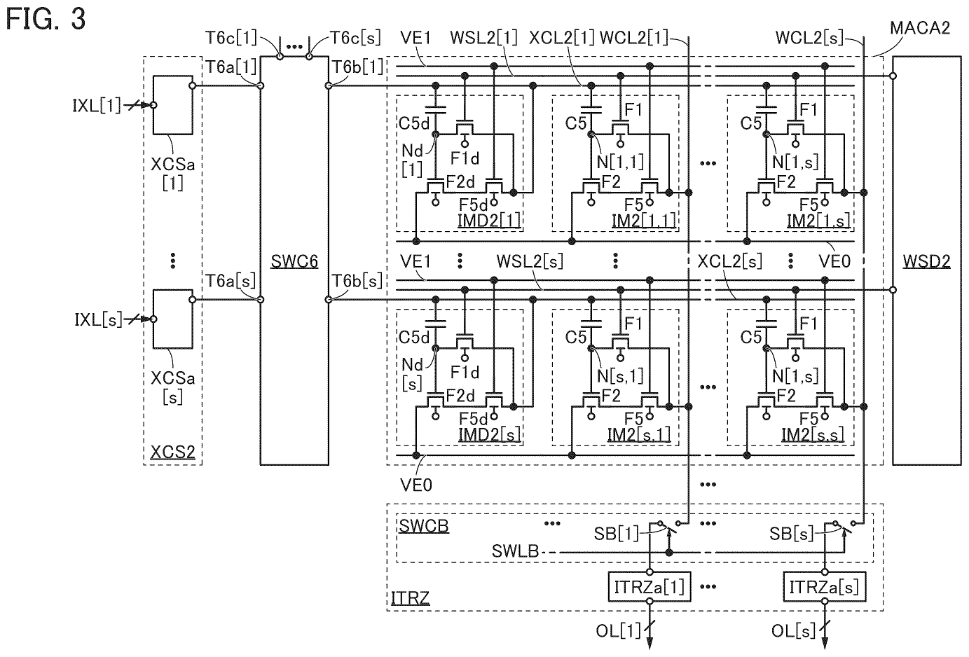

FIG. 3 is a diagram selectively illustrating the arithmetic cell array MACA2, the circuit WSD2, the circuit XCS2, the circuit ITRZ, and the switching circuit SWC6 in the arithmetic circuit CDV in FIG. 1. Specifically, FIG. 3 also illustrates circuit structures of the arithmetic cell array MACA2, the circuit XCS2, and the circuit ITRZ.

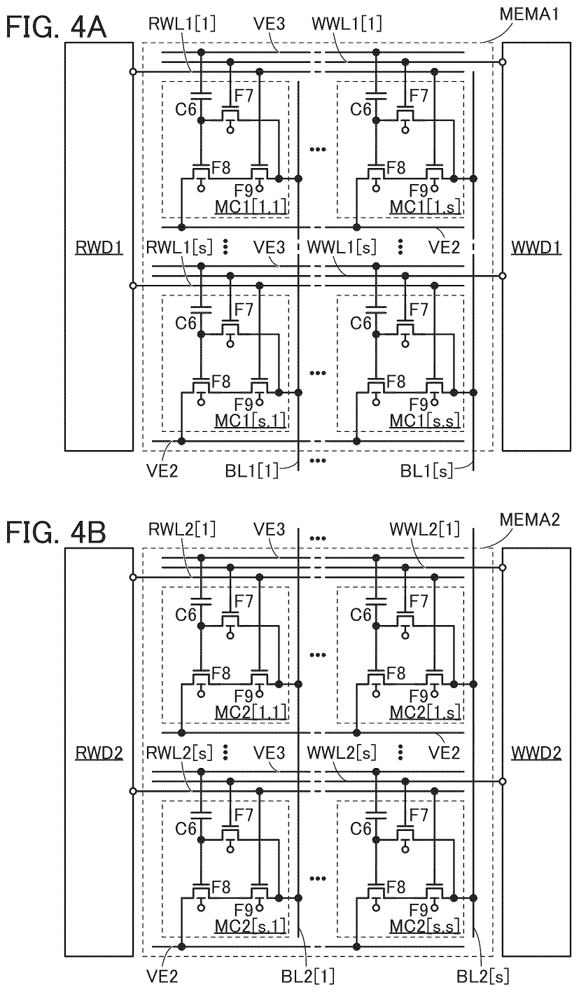

FIG. 4A is a diagram selectively illustrating the memory cell array MEMA1, the circuit WWD1, and the circuit RWD1 in the arithmetic circuit CDV in FIG. 1. Specifically, FIG. 4A also illustrates a circuit structure of the memory cell array MEMA1.

FIG. 4B is a diagram selectively illustrating the memory cell array MEMA2, the circuit WWD2, and the circuit RWD2 in the arithmetic circuit CDV in FIG. 1. Specifically, FIG. 4B also illustrates a circuit structure of the memory cell array MEMA2.

### [Arithmetic Cell Array MACA1 and Arithmetic Cell Array MACA2]

Each of the arithmetic cell array MACA1 and the arithmetic cell array MACA2 has a function of performing a product-sum operation of a plurality of pieces of first data and a plurality of pieces of second data, for example. In this embodiment, the first data and the second data each have a positive value or a “0” value.

The arithmetic cell array MACA1 includes a cell IM1[1,1] to a cell IM1[s,s], for example. The arithmetic cell array MACA1 further includes a cell IMD1[1] to a cell IMD1[s]. The arithmetic cell array MACA2 includes a cell IM2[1,1] to a cell IM2[s,s], for example. The arithmetic cell array MACA2 further includes a cell IMD2[1] to a cell IMD2[s].

Note that the structure of the arithmetic cell array MACA2 is the same as that of the arithmetic cell array MACA1. That is, the structures of the cell IM2[1,1] to the cell IM2[s,s] are the same as those of the cell IM1[1,1] to the cell IM1[s,s], respectively, and the structures of the cell IMD2[1] to the cell IMD2[s] are the same as those of the cell IMD1[1] to the cell IMD1[s], respectively. Thus, for the structures of the cell IM2[1,1] to the cell IM2[s,s] and the cell IMD2[1] to the cell IMD2[s], the following description of the structures of the cell IM1[1,1] to the cell IM1[s,s] and the cell IMD1[1] to the cell IMD1[s] is to be referred to. In this case, the description of the structures of the cell IM2[1,1] to the cell IM2[s,s] and the cell IMD2[1] to the cell IMD2[s] is made when, in the following description of the structures of the IM1[1,1] to the cell IM1[s,s] and the cell IMD1[1] to the cell IMD1[s], the arithmetic cell array MACA1 is replaced with the arithmetic cell array MACA2, the wiring WSL1[1] to the wiring WSL1[s] are replaced with the wiring WSL2[1] to the wiring WSL2[s], the wiring WCL1[1] to the wiring WCL1[s] are replaced with the wiring WCL2[1] to the wiring WCL2[s], and the wiring XCL1[1] to the wiring XCL1[s] are replaced with the wiring XCL2[1] to the wiring XCL2[s].

The cell IM1[1,1] to the cell IM1[s,s] function as arithmetic cells, for example. The cell IMD1[1] to the cell IMD1[s] each have a function of retaining a potential corresponding to reference data in order to perform an arithmetic operation in the cell IM1[1,1] to the cell IM1[s,s], for example. Note that the reference data will be described later in detail.

The cell IM1[1,1] to the cell IM1[s,s] each include a transistor F1, a transistor F2, a transistor F5, and a capacitor C5, for example. The cell IMD1[1] to the cell IMD1[s] each include a transistor Fld, a transistor F2d, a transistor F5d, and a capacitor C5d, for example.

In particular, the structures (including the channel lengths and the channel widths) of the transistors F1 included in the cell IM1[1,1] to the cell IM1[s,s] are preferably the same, the structures of the transistors F2 included in the cell IM1[1,1] to the cell IM1[s,s] are preferably the same, and the structures of the transistors F5 included in the cell IM1[1,1] to the cell IM1[s,s] are preferably the same. The structures of the transistors Fld included in the cell IMD1[1] to the cell IMD1[s] are preferably the same, the structures of the transistors F2d included in the cell IMD1[1] to the cell IMD1[s] are preferably the same, and the structures of the transistors F5d included in the cell IMD1[1] to the cell IMD1[s] are preferably the same. The structures of the transistor F1 and the transistor Fld are preferably the same, the structures of the transistor F2 and the transistor F2d are preferably the same, and the structures of the transistor F5 and the transistor F5d are preferably the same.

By making the transistors have the same structure, the transistors can have substantially the same electrical characteristics. Thus, by making the transistors F1 included in the cell IM1[1,1] to the cell IM1[s,s] have the same structure, making the transistors F2 included in the cell IM1[1,1] to the cell IM1[s,s] have the same structure, and making the transistors F5 included in the cell IM1[1,1] to the cell IM1[s,s] have the same structure, the cell IM1[1,1] to the cell IM1[s,s] can perform almost the same operation when under the same conditions. The same conditions here refer to, for example, the potentials of a source, a drain, and a gate of the transistor F1, the potentials of a source, a drain, and a gate of the transistor F2, the potentials of a source, a drain, and a gate of the transistor F5, and voltages input to the cell IM1[1,1] to the cell IM1[s,s]. Similarly, by making the transistors Fld included in the cell IMD1[1] to the cell IMD1[s] have the same structure, making the transistors F2d included in the cell IMD1[1] to the cell IMD1[s] have the same structure, and making the transistors F5d included in the cell IMD1[1] to the cell IMD1[s] have the same structure, the cell IMD1[1] to the cell IMD1[s] can perform almost the same operation when under the same conditions. The same conditions here refer to, for example, the potentials of a source, a drain, and a gate of the transistor Fld, the potentials of a source, a drain, and a gate of the transistor F2d, the potentials of a source, a drain, and a gate of the transistor F5d, and voltages input to the cell IMD1[1] to the cell IMD1[s].

Note that the transistor F1 and the transistor Fld may function as switching elements unless otherwise specified. In other words, the gate voltage, the source voltage, and the drain voltage of each of the above transistors may be appropriately biased to voltages in the range where the transistor operates as switching elements. However, one embodiment of the present invention is not limited thereto. For example, the transistor F1 and the transistor Fld in an on state may operate in a linear region or a saturation region or may operate both in a linear region and a saturation region.

Unless otherwise specified, the transistor F2 and the transistor F2d may operate in the subthreshold region (i.e., the gate-source voltage may be lower than the threshold voltage in the transistor F2 or the transistor F2d, further preferably, the drain current increases exponentially with respect to the gate-source voltage). In other words, the gate voltage, the source voltage, and the drain voltage of each of the above transistors may be appropriately biased to voltages in the range where the transistor operates in the subthreshold region. Thus, the transistor F2 and the transistor F2d may operate such that an off-state current flows between the source and the drain.

The transistor F5 and the transistor F5d each function as a clamp transistor (also called a clamp FET in some cases), for example. Thus, a constant potential is preferably applied to the gates of the transistor F5 and the transistor F5d. Providing the transistor F5 (transistor F5d) can prevent drain-induced barrier lowering (DIBL) in the transistor F2 (transistor F2d), which will be described later in detail.

Meanwhile, in the case where drain-induced barrier lowering (DIBL) in the transistor F2 (transistor F2d) can be ignored, the cell IM1 (cell IMD1) may have a structure in which the transistor F5 (transistor F5d) is not provided.

One or both of the transistor F1 and the transistor Fld are preferably an OS transistor, for example. Specific examples of a metal oxide included in a channel formation region of the OS transistor include indium oxide, gallium oxide, and zinc oxide. The metal oxide preferably includes one or more selected from indium, an element M, and zinc. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony. Specifically, the element M is preferably one or more selected from aluminum, gallium, yttrium, and tin. Note that a metal oxide containing indium, the element M, and zinc is referred to as an In-M-Zn oxide in some cases.

It is particularly preferable that an oxide containing indium (In), gallium (Ga), and zinc (Zn) (also referred to as IGZO) be used as the metal oxide used for a semiconductor layer. Alternatively, it is preferable to use an oxide containing indium, tin, and zinc (also referred to as ITZO (registered trademark)). Alternatively, it is preferable to use an oxide containing indium (In), gallium (Ga), tin (Sn), and zinc (Zn). Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

The metal oxide included in the channel formation region of the OS transistor preferably has a stacked-layer structure of a plurality of oxide layers with different chemical compositions. For example, an oxide layer having a two-layer structure of a first layer and a second layer positioned directly over the first layer is considered. The atomic ratio of the element M to the metal element that is a main component in the metal oxide used for the first layer is preferably higher than the atomic ratio of the element M to the metal element that is a main component in the metal oxide used for the second layer. Moreover, the atomic ratio of the element M to In in the metal oxide used for the first layer is preferably higher than the atomic ratio of the element M to In in the metal oxide used for the second layer. With this structure, impurities and oxygen can be inhibited from diffusing into the second layer from the components formed below the first layer.

The atomic ratio of In to the element M in the metal oxide used for the second layer is preferably higher than the atomic ratio of In to the element M in the metal oxide used for the first layer. With this structure, the OS transistor can have a high on-state current and high frequency characteristics.

Specifically, as the metal oxide used for the first layer, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used, for example. As the metal oxide used for the second layer, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio.

One or both of the transistor F1 and the transistor F1d can be, other than an OS transistor, a transistor including silicon in its channel formation region (hereinafter, referred to as a Si transistor). As the silicon, amorphous silicon (referred to as hydrogenated amorphous silicon in some cases), microcrystalline silicon, polycrystalline silicon, single crystal silicon, or the like can be used, for example.

Examples of a transistor that can be used as one or both of the transistor F1 and the transistor F1d other than an OS transistor and a Si transistor include a transistor including germanium or the like in its channel formation region, a transistor including a compound semiconductor, such as zinc selenide, cadmium sulfide, gallium arsenide, indium phosphide, gallium nitride, or silicon germanium, in its channel formation region, a transistor including a carbon nanotube in its channel formation region, and a transistor including an organic semiconductor in its channel formation region.

The use of an OS transistor as one or both of the transistor F1 and the transistor F1d can reduce the leakage current of one or both of the transistor F1 and the transistor F1d, so that power consumption of the arithmetic circuit can be reduced. Specifically, the amount of a leakage current from a retention node (e.g., a later-described node N or a later-described node Nd) to a write word line can be extremely small when one or both of the transistor F1 and the transistor F1d is in a non-conduction state; thus, the frequency of refresh operations for the potential of the retention node can be reduced. By reducing the frequency of refresh operations, power consumption of the arithmetic circuit can be reduced. An extremely low leakage current from the retention node to the wiring WCL or the wiring XCL allows the cells to retain the potential of the retention node for a long time, increasing the arithmetic operation accuracy of the arithmetic circuit.

Using an OS transistor also as one or both of the transistor F2 and the transistor F2d enables an operation with a wide range of a current in the subthreshold region, leading to a reduction in the current consumption.

Using OS transistors also as the transistor F2, the transistor F2d, the transistor F5, and the transistor F5d allows the transistor F2, the transistor F2d, the transistor F5, and the transistor F5d to be manufactured concurrently with the transistor F1 and the transistor F1d, which sometimes shortens the manufacturing process of the arithmetic circuit. The transistor F2, the transistor F2d, the transistor F5, and the transistor F5d can be, if not OS transistors, Si transistors.

When semiconductor devices are highly integrated into a chip, heat may be generated in the chip by driving of the circuit. This heat generation increases the temperature of a transistor to change the characteristics of the transistor; thus, the field-effect mobility thereof might change or the operation frequency thereof might decrease, for example. Since an OS transistor has higher heat resistance than a Si transistor, a change in field-effect mobility and a decrease in operation frequency due to a temperature change do not easily occur. Even when having a high temperature, an OS transistor is likely to keep a property of the drain current increasing exponentially with respect to the gate-source voltage. With the use of an OS transistor, an arithmetic operation, processing, or the like can thus be easily performed even in a high-temperature environment. To form a semiconductor device highly resistant to heat due to driving, an OS transistor is preferably used as its transistor.

In each of the cell IM1[1,1] to the cell IM1[s,s], a first terminal of the transistor F1 is electrically connected to the gate of the transistor F2. A first terminal of the transistor F2 is electrically connected to a wiring VE0. A first terminal of the capacitor C5 is electrically connected to the gate of the transistor F2. A second terminal of the transistor F2 is electrically connected to a first terminal of the transistor F5. A second terminal of the transistor F5 is electrically connected to a second terminal of the transistor F1, and the gate of the transistor F5 is electrically connected to a wiring VE1.

In the cell IM1[1,1] to the cell IM1[s,s], the second terminal of the transistor F2 and the wiring WCL1 are electrically connected in series with each other through the first terminal and the second terminal of the transistor F5, thereby preventing direct application of a high-level potential from the wiring WCL1 to the second terminal of the transistor F2. Thus, drain-induced barrier lowering in the transistor F2 can be prevented.

In the case where the second terminal of the transistor F2 is directly electrically connected to the wiring WCL1 (i.e., the case where the transistor F5 is not provided) in the cell IM1[1,1] to the cell IM1[s,s], direct application of a high-level potential from the wiring WCL1 to the second terminal of the transistor F2 might cause drain-induced barrier lowering in the transistor F2. When drain-induced barrier lowering occurs in the transistor F2, the threshold voltage of the transistor F2 is lowered, so that the voltage range of the subthreshold region of the transistor F2 might change. As a result, when the cell IM1[1,1] to the cell IM1[s,s] each have a structure in which the transistor F5 is not provided, a current in the subthreshold region that flows through the transistor F2 might vary.

In each of the cell IMD1[1] to the cell IMD1[s], a first terminal of the transistor F1d is electrically connected to the gate of the transistor F2d. A first terminal of the transistor F2d is electrically connected to the wiring VE0. A first terminal of the capacitor C5d is electrically connected to the gate of the transistor F2d. A second terminal of the transistor F2d is electrically connected to a first terminal of the transistor F5d. A second terminal of the transistor F5d is electrically connected to a second terminal of the transistor F1d, and the gate of the transistor F5d is electrically connected to the wiring VE1.

Like the transistors F5 in the cell IM1[1,1] to the cell IM1[s,s], the transistors F5d in the cell IMD1[1] to the cell IMD1[s] have a function of preventing drain-induced barrier lowering in the transistor F2d.

In FIG. 2, back gates are illustrated for the transistor F1, the transistor F2, the transistor F5, the transistor F1d, the transistor F2d, and the transistor F5d. Although the connection structure of the back gates is not illustrated, points to which the back gates are electrically connected can be determined at the design stage. For example, in a transistor including a back gate, a gate and the back gate may be electrically connected to each other to increase the on-state current of the transistor. In other words, the gate and the back gate of the transistor F1 may be electrically connected to each other, and the gate and the back gate of the transistor F1d may be electrically connected to each other, for example. Furthermore, for example, in a transistor including a back gate, a wiring electrically connecting the back gate of the transistor to an external circuit or the like may be provided and a potential may be supplied to the back gate of the transistor with the external circuit or the like to change the threshold voltage of the transistor or to reduce the off-state current of the transistor.

The transistor F1, the transistor F2, and the transistor F5 illustrated in FIG. 2 have back gates; however, the semiconductor device of one embodiment of the present invention is not limited thereto. For example, the transistor F1, the transistor F2, and the transistor F5 illustrated in FIG. 2 may each be a transistor having a structure not including a back gate, i.e., a single-gate structure. It is also possible that some transistors have a structure including a back gate and the other transistors have a structure not including a back gate.

The transistor F1, the transistor F2, and the transistor F5 illustrated in FIG. 2 are n-channel transistors; however, the semiconductor device of one embodiment of the present invention is not limited thereto. For example, the transistor F1 may be an n-channel transistor, and the transistor F2 and the transistor F5 may be replaced with p-channel transistors.

The above-described examples of changes in the structure and polarity of the transistor are not limited to the transistor F1, the transistor F2, and the transistor F5. For example, the same applies to the transistor F1d, the transistor F2d, the transistor F5d, transistors described in other parts of this specification, and transistors illustrated in other drawings.

The wiring VE0 functions as a wiring for making a current flow between the first terminal and the second terminal of the transistor F2 in each of the cell IM1[1,1] to the cell IM1[s,s]. The wiring VE0 functions as a wiring for making a current flow between the first terminal and the second terminal of the transistor F2d in each of the cell IMD1[1] to the cell IMD1[s]. The wiring VE0 functions as a wiring for supplying a constant potential, for example. The constant potential can be, for example, a low-level potential or a ground potential.

The wiring VE1 functions as a wiring for applying a potential to the gates of the transistors F5 in the cell IM1[1,1] to the cell IM1[s,s] and the gates of the transistors F5d in the cell IMD1[1] to the cell IMD1[s]. Note that the potential is preferably a potential within a range where the transistor F5 and the transistor F5d function as clamp transistors.

In the cell IM1[1,1], the second terminal of the transistor F1 and the second terminal of the transistor F5 are electrically connected to the wiring WCL1[1], and the gate of the transistor F1 is electrically connected to the wiring WSL1[1]. A second terminal of the capacitor C5 is electrically connected to the wiring XCL1[1]. In the cell IM1[1,1] in FIG. 2, a connection portion of the first terminal of the transistor F1, the gate of the transistor F2, and the first terminal of the capacitor C5 is the node N[1,1].

In the cell IM1[s,1], the second terminal of the transistor F1 and the second terminal of the transistor F5 are electrically connected to the wiring WCL1[1], and the gate of the transistor F1 is electrically connected to the wiring WSL1[s]. The second terminal of the capacitor C5 is electrically connected to the wiring XCL1[s]. In the cell IM1[s,1] in FIG. 2, a connection portion of the first terminal of the transistor F1, the gate of the transistor F2, and the first terminal of the capacitor C5 is the node N[s, 1].

In the cell IM1[1,s], the second terminal of the transistor F1 and the second terminal of the transistor F5 are electrically connected to the wiring WCL1[s], and the gate of the transistor F1 is electrically connected to the wiring WSL1[1]. The second terminal of the capacitor C5 is electrically connected to the wiring XCL1[1]. In the cell IM1[1,s] in FIG. 2, a connection portion of the first terminal of the transistor F1, the gate of the transistor F2, and the first terminal of the capacitor C5 is the node N[1,s].

In the cell IM1[s,s], the second terminal of the transistor F1 and the second terminal of the transistor F5 are electrically connected to the wiring WCL1[s], and the gate of the transistor F1 is electrically connected to the wiring WSL1[s]. The second terminal of the capacitor C5 is electrically connected to the wiring XCL1[s]. In the cell IM1[s,s] in FIG. 2, a connection portion of the first terminal of the transistor F1, the gate of the transistor F2, and the first terminal of the capacitor C5 is the node N[s,s].

In the cell IMD1[1], the second terminal of the transistor F1d and the second terminal of the transistor F5d are electrically connected to the wiring XCL1[1], and the gate of the transistor F1d is electrically connected to the wiring WSL1[1]. A second terminal of the capacitor C5d is electrically connected to the wiring XCL1[1]. In the cell IMD1[1] in FIG. 2, a connection portion of the first terminal of the transistor F1d, the gate of the transistor F2d, and the first terminal of the capacitor C5d is the node Nd[1].

In the cell IMD1[s], the second terminal of the transistor F1d and the second terminal of the transistor F5d are electrically connected to the wiring XCL1[s], and the gate of the transistor F1d is electrically connected to the wiring WSL1[s]. The second terminal of the capacitor C5d is electrically connected to the wiring XCL1[s]. In the cell IMD1[s] in FIG. 2, a connection portion of the first terminal of the transistor F1d, the gate of the transistor F2d, and the first terminal of the capacitor C5d is the node Nd[s].

Note that the node N[1,1], the node N[1,s], the node N[s, 1], the node N[s,s], the node Nd[1], and the node Nd[s] function as retention nodes of their respective cells.

In the cell IM1[1,1] to the cell IM1[s,s], for example, when the transistor F1 and the transistor F5 are in an on state, a conduction state is established between the gate and the second terminal of the transistor F2. When a constant potential applied from the wiring VE0 is the ground potential (GND), the transistor F1 is in an on state, and a current with a current amount I flows from the wiring WCL1 to the second terminal of the transistor F2, the potential of the gate of the transistor F2 (the node N) is determined in accordance with a current amount I. Since the transistor F1 is in an on state, the potential of the second terminal of the transistor F2 is ideally equal to that of the gate of the transistor F2 (the node N). Here, by turning off the transistor F1, the potential of the gate of the transistor F2 (the node N) is retained by the capacitor C5. Accordingly, the transistor F2 can make a current with a current amount I corresponding to the ground potential of the first terminal of the transistor F2 and the potential of the gate of the transistor F2 (the node N) flow between the source and the drain of the transistor F2. In this specification and the like, such an operation is called “setting (programing) the amount of a current flowing between the source and the drain of the transistor F2 in the cell IM1 to I”, for example.

In a similar manner, the amount of a current flowing between the source and the drain of the transistor F2d in the cell IMD1[1] to the cell IMD1[s] can be set when the transistor F1 is replaced with the transistor F1d, the transistor F2 is replaced with the transistor F2d, and the node N is replaced with the node Nd in the above description.

### [Circuit WSD1 and Circuit WSD2]

The circuit WSD1 has a function of selecting a row in the arithmetic cell array MACA1 to which the first data is to be written, by supplying a predetermined signal to the wiring WSL1[k] at the time of writing the first data to each of the arithmetic cells included in the arithmetic cell array MACA1, for example.

In a similar manner, the circuit WSD2 has a function of selecting a row in the arithmetic cell array MACA2 to which the first data is to be written, by supplying a predetermined signal to the wiring WSL2[k] at the time of writing the first data to each of the arithmetic cells included in the arithmetic cell array MACA2, for example.

For example, in FIG. 2, when the circuit WSD1 supplies a high-level potential to the wiring WSL1[1] and supplies a low-level potential to the wiring WSL1[2] (not shown) to the wiring WSL1[s], the transistor F1 and the transistor F1d each including a gate electrically connected to the wiring WSL1[1] can be turned on and the transistors F1 and the transistors F1d including gates electrically connected to the wiring WSL1[2] to the wiring WSL1[s] can be turned off.

Note that the circuit WSD1 and the circuit WSD2 may have the same structure.

### [Circuit WCS]

The circuit WCS has a function of obtaining the first data, which is digital data, from the outside of the arithmetic circuit CDV, converting the first data into analog data (current), and further supplying the first data converted into the analog data to the arithmetic cells included in the arithmetic cell array MACA1 or the arithmetic cells included in the arithmetic cell array MACA2, for example. In the case where the circuit WCS writes the first data to the arithmetic cells in the k-th column in the arithmetic cell array MACA1, for example, the circuit WCS supplies the first data to the arithmetic cells in the k-th column in the arithmetic cell array MACA1 through the wiring WCL1[k]. In the case where the circuit WCS writes the first data to the arithmetic cells in the k-th column in the arithmetic cell array MACA2, the circuit WCS supplies the first data to the arithmetic cells in the k-th column in the arithmetic cell array MACA2 through the wiring WCL1[k] and the wiring WCL2[k].

The circuit WCS includes a circuit SWCA and a circuit WCSa[1] to a circuit WCSa[s], for example.

The circuit SWCA has a function of establishing a conduction state or a non-conduction state between the wiring WCL1[k] and the circuit WCSa[k].

The circuit SWCA includes a switch SA[1] to a switch SA[s], for example.

A first terminal of the switch SA[k] is electrically connected to the wiring WCL1[k], a second terminal of the switch SA[k] is electrically connected to the circuit WCSa[k], and a control terminal of the switch SA[k] is electrically connected to a wiring SWLA.

As the switch SA[k], an electrical switch such as an analog switch or a transistor can be used, for example. Specifically, as an electrical switch for the switch SA[k], the above-described transistor is preferably used, and in particular, an OS transistor is further preferably used. In the case where an electrical switch is used as the switch SA[k], the electrical switch can be a Si transistor other than an OS transistor, for example. For another example, a mechanical switch may be used as the switch SA[k].

In this specification and the like, the switch SA[k] illustrated in FIG. 2 in an on state when a high-level potential is supplied to the control terminal, and the switch SA[k] illustrated in FIG. 2 is in an off state when a low-level potential is supplied to the control terminal.

The wiring SWLA functions as a wiring for switching an on state and an off state of the switch SA[k], for example. Accordingly, the wiring SWLA is supplied with a high-level potential or a low-level potential.

As described above, the circuit SWCA functions as a circuit that establishes a conduction state or a non-conduction state between the circuit WCS and the wiring WCL1[k]. That is, the circuit SWCA switches a conduction state and a non-conduction state between the circuit WCS and the wiring WCL1[k] by using the switch SA[k].

The circuit WCSa[1] to the circuit WCSa[s] are electrically connected to a wiring IWL[1] to a wiring IWL[s], respectively.

The wiring IWL[1] to the wiring IWL[s] function as wirings for transmitting the first data, which is digital data, respectively to the circuit WCSa[1] to the circuit WCSa[s] from the outside of the arithmetic circuit CDV.

The circuit WCSa[k] has a function of obtaining the first data from the wiring IWL[k] and supplying a signal corresponding to the first data to the wiring WCL1[k], for example. Specifically, when the switch SA[k] is in an on state, the circuit WCSa[k] supplies the first data to be stored in the cells included in the arithmetic cell array MACA1 or the arithmetic cell array MACA2. Note that in the case of the arithmetic cell array MACA1 and the arithmetic cell array MACA2 in FIG. 2, the signal is preferably analog data (current).

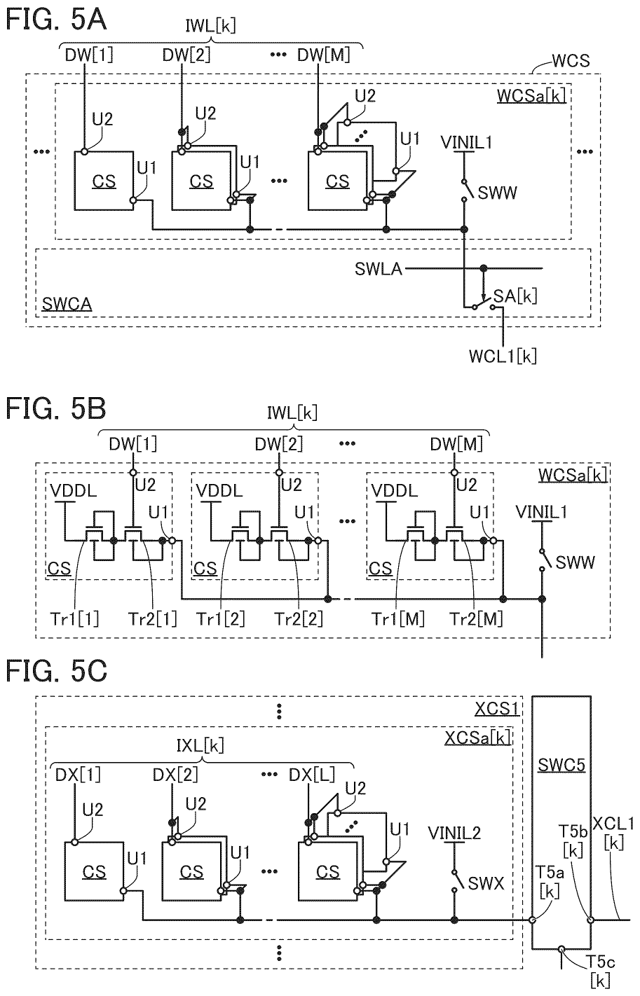

The circuit WCSa[k] can have a structure illustrated in FIG. 5A, for example. FIG. 5A also shows the circuit SWCA, the switch SA[k], the wiring SWLA, and the wiring WCL1[k] to illustrate electrical connection between the circuit WCSa[k] and its peripheral circuits.

Thus, the switch SA[k] illustrated in FIG. 5A can be any one of the switch SA[1] to the switch SA[s] included in the circuit SWCA in FIG. 2. Similarly, the wiring WCL1[k] can be any one of the wiring WCL1[1] to the wiring WCL1[s] extending in the arithmetic cell array MACA1 in FIG. 2.

Accordingly, the circuit WCSa[k] is electrically connected to the wiring WCL1[k] through the switch SA[k].

The circuit WCSa[k] illustrated in FIG. 5A includes a switch SWW, for example. A first terminal of the switch SWW is electrically connected to the second terminal of the switch SA[k], and a second terminal of the switch SWW is electrically connected to a wiring VINIL1. The wiring VINIL1 functions as a wiring for supplying an initialization potential to the wiring WCL, and the initialization potential can be set to the ground potential (GND), a low-level potential, or a high-level potential. Note that the switch SWW is in an on state only when the initialization potential is supplied to the wiring WCL1[k]; otherwise, the switch is in an off state.

As the switch SWW, an electrical switch such as an analog switch or a transistor can be used, for example. When a transistor is used as the switch SWW, for example, the transistor can be a transistor having a structure similar to that of the transistor F1 or the transistor F2. Other than the electrical switch, a mechanical switch may be used.

The circuit WCSa[k] in FIG. 5A includes a plurality of current sources CS, for example. Specifically, the circuit WCSa[k] has a function of outputting M-bit first data (2^{M} values) (M is an integer greater than or equal to 1) as a current amount; in this case, the circuit WCSa[k] includes 2^{M}−1 current sources CS. The circuit WCSa[k] includes one current source CS that outputs information corresponding to the first bit value as a current, two current sources CS that output information corresponding to the second bit value as a current, and 2^{M-1} current sources CS that output information corresponding to the M-th bit value as a current, for example.

Each of the current sources CS in FIG. 5A includes a terminal U1 and a terminal U2. The terminal U1 of each of the current sources CS is electrically connected to the second terminal of the switch SA included in the circuit SWCA. The terminal U2 of the one current source CS is electrically connected to a wiring DW[1], the terminals U2 of the two current sources CS are electrically connected to a wiring DW[2], and the terminals U2 of the 2^{K-1} current sources CS are electrically connected to a wiring DW[M].

The plurality of current sources CS included in the circuit WCSa[k] have a function of outputting the same constant current I_{Wut} from the terminals U1. In practice, at the manufacturing stage of the arithmetic circuit CDV, the transistors included in the current sources CS may have different electrical characteristics; this may yield an error. The error in constant currents I_{Wut} output from the terminals U1 of the plurality of current sources CS is thus preferably within 10%, further preferably within 5%, still further preferably within 1%. In this embodiment, the description is made on the assumption that there is no error in constant currents I_{Wut} output from the terminals U1 of the plurality of current sources CS included in the circuit WCSa[k].

The wiring DW[1] to the wiring DW[M] correspond to the wiring IWL[k] described above and function as wirings for obtaining the first data, which is digital data from the outside. Specifically, the wiring DW[1] to the wiring DW[M] function as wirings for transmitting signals to make the current sources CS electrically connected to the wiring DW[1] to the wiring DW[M] output constant currents I_{Wut}. For example, when a high-level potential is supplied to the wiring DW[1], the current source CS electrically connected to the wiring DW[1] supplies Wut as a constant current to the second terminal of the switch SA[k], and when a low-level potential is supplied to the wiring DW[1], the current source CS electrically connected to the wiring DW[1] does not output I_{Wut}. For example, when a high-level potential is supplied to the wiring DW[2], the two current sources CS electrically connected to the wiring DW[2] supply a constant current of 2I_{Wut} in total to the second terminal of the switch SA[k], and when a low-level potential is supplied to the wiring DW[2], the current sources CS electrically connected to the wiring DW[2] do not output a constant current of 2I_{Wut} in total. For example, when a high-level potential is supplied to the wiring DW[M], the 2^{M-1} current sources CS electrically connected to the wiring DW[M] supply a constant current of 2^{M-1} I_{Wut} in total to the second terminal of the switch SA[k], and when a low-level potential is supplied to the wiring DW[M], the current sources CS electrically connected to the wiring DW[M] do not output a constant current of 2^{M-1} I_{Wut} in total.

The current flowing from the one current source CS electrically connected to the wiring DW[1] corresponds to the value of the first bit, the current flowing from the two current sources CS electrically connected to the wiring DW[2] corresponds to the value of the second bit, and the amount of the current flowing from the 2^{M-1} current sources CS electrically connected to the wiring DW[M] corresponds to the value of the M-th bit. The circuit WCSa with M of 2 is considered here. For example, when the value of the first bit is “1” and the value of the second bit is “0”, a high-level potential is supplied to the wiring DW[1], and a low-level potential is supplied to the wiring DW[2]. In this case, I_{Wut} flows as a constant current to the second terminal of the switch SA[k] of the circuit SWCA from the circuit WCSa. For example, when the value of the first bit is “0” and the value of the second bit is “1”, a low-level potential is supplied to the wiring DW[1], and a high-level potential is supplied to the wiring DW[2]. In this case, 2I_{Wut} flows as a constant current to the second terminal of the switch SA[k] of the circuit SWCA from the circuit WCSa. For example, when the value of the first bit is “1” and the value of the second bit is “1”, a high-level potential is supplied to each of the wiring DW[1] and the wiring DW[2]. In this case, 3I_{Wut} flows as a constant current to the second terminal of the switch SA[k] of the circuit SWCA from the circuit WCSa. For example, when the value of the first bit is “0” and the value of the second bit is “0”, a low-level potential is supplied to each of the wiring DW[1] and the wiring DW[2]. In this case, no constant current flows from the circuit WCSa to the second terminal of the switch SA[k] of the circuit SWCA.

FIG. 5A illustrates the circuit WCSa[k] where M is an integer greater than or equal to 3; when M is 1, the current sources CS electrically connected to the wiring DW[2] to the wiring DW[M] are not provided in the circuit WCSa in FIG. 3A. When M is 2, the current sources CS electrically connected to the wiring DW[3] (not shown) to the wiring DW[M] are not provided in the circuit WCSa in FIG. 3A.

Next, a specific structure example of the current source CS is described.

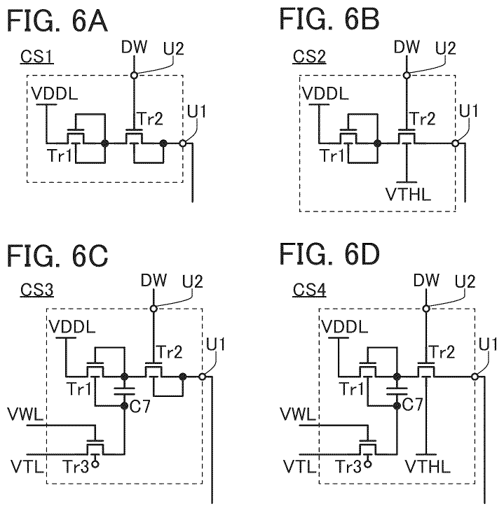

A current source CS1 illustrated in FIG. 6A is a circuit that can be used as the current source CS included in the circuit WCSa in FIG. 5A, and the current source CS1 includes a transistor Tr1 and a transistor Tr2.

A first terminal of the transistor Tr1 is electrically connected to a wiring VDDL, and a second terminal of the transistor Tr1 is electrically connected to a gate of the transistor Tr1, a back gate of the transistor Tr1, and a first terminal of the transistor Tr2. A second terminal of the transistor Tr2 is electrically connected to the terminal U1, and a gate of the transistor Tr2 is electrically connected to the terminal U2. The terminal U2 is electrically connected to the wiring DW.

The wiring DW is any one of the wiring DW[1] to the wiring DW[M] in FIG. 5A.

The wiring VDDL functions as a wiring for supplying a constant potential. The constant potential can be a high-level potential, for example.

When the constant potential supplied from the wiring VDDL is a high-level potential, a high-level potential is input to the first terminal of the transistor Tr1. The potential of the second terminal of the transistor Tr1 is lower than the high-level potential. At this time, the first terminal of the transistor Tr1 functions as a drain, and the second terminal of the transistor Tr1 functions as a source. Since the gate of the transistor Tr1 is electrically connected to the second terminal of the transistor Tr1, the gate-source voltage of the transistor Tr1 is 0 V. Thus, when the threshold voltage of the transistor Tr1 is within an appropriate range, a current in the current range of the subthreshold region (drain current) flows between the first terminal and the second terminal of the transistor Tr1. The amount of the current is preferably smaller than or equal to 1.0×10⁻⁸ A, further preferably smaller than or equal to 1.0×10⁻¹² A, still further preferably smaller than or equal to 1.0×10⁻¹⁵ A, for example, when the transistor Tr1 is an OS transistor. For example, the current is further preferably within a range where the current exponentially increases with respect to the gate-source voltage. That is, the transistor Tr1 functions as a current source for supplying a current within a current range of the transistor Tr1 operating in the subthreshold region. The current corresponds to I_{Wut} described above or I_{Xut} described later.

The transistor Tr2 functions as a switching element. When the potential of the first terminal of the transistor Tr2 is higher than the potential of the second terminal of the transistor Tr2, the first terminal of the transistor Tr2 functions as a drain and the second terminal of the transistor Tr2 functions as a source. Since a back gate of the transistor Tr2 and the second terminal of the transistor Tr2 are electrically connected to each other, a back gate-source voltage becomes 0 V. Thus, when the threshold voltage of the transistor Tr2 is within an appropriate range and a high-level potential is input to the gate of the transistor Tr2, the transistor Tr2 is turned on; when a low-level potential is input to the gate of the transistor Tr2, the transistor Tr2 is turned off. Specifically, when the transistor Tr2 is in an on state, the current within the current range of the subthreshold region flows from the second terminal of the transistor Tr1 to the terminal U1, and when the transistor Tr2 is in an off state, the current does not flow from the second terminal of the transistor Tr1 to the terminal U1.

The circuit that can be used as the current source CS included in the circuit WCSa[k] in FIG. 5A is not limited to the current source CS1 in FIG. 6A. For example, the current source CS1 has a structure in which the back gate of the transistor Tr2 and the second terminal of the transistor Tr2 are electrically connected to each other; however, the back gate of the transistor Tr2 may be electrically connected to another wiring. Such a structure example is illustrated in FIG. 6B. In a current source CS2 illustrated in FIG. 6B, the back gate of the transistor Tr2 is electrically connected to a wiring VTHL. When the wiring VTHL of the current source CS2 is electrically connected to an external circuit or the like, the external circuit or the like supplies a predetermined potential to the wiring VTHL and the back gate of the transistor Tr2 can be supplied with the predetermined potential. This can change the threshold voltage of the transistor Tr2. In particular, the off-state current of the transistor Tr2 can be reduced by an increase in the threshold voltage of the transistor Tr2.

For example, the current source CS1 has a structure in which the back gate of the transistor Tr1 and the second terminal of the transistor Tr1 are electrically connected to each other; however, the voltage between the back gate and the second terminal of the transistor Tr2 may be retained with a capacitor. Such a structure example is illustrated in FIG. 6C. A current source CS3 illustrated in FIG. 6C includes a transistor Tr3 and a capacitor C7 in addition to the transistor Tr1 and the transistor Tr2. The current source CS3 is different from the current source CS1 in that the second terminal of the transistor Tr1 and the back gate of the transistor Tr1 are electrically connected to each other through the capacitor C7, and the back gate of the transistor Tr1 and a first terminal of the transistor Tr3 are electrically connected to each other. In the current source CS3, a second terminal of the transistor Tr3 is electrically connected to a wiring VTL, and a gate of the transistor Tr3 is electrically connected to a wiring VWL. In the current source CS3, the wiring VWL is supplied with a high-level potential to turn on the transistor Tr3, so that a conduction state is established between the wiring VTL and the back gate of the transistor Tr1. In this case, a predetermined potential can be input to the back gate of the transistor Tr1 from the wiring VTL. The wiring VWL is supplied with a low-level potential to turn off the transistor Tr3, so that the voltage between the second terminal of the transistor Tr1 and the back gate of the transistor Tr1 can be retained with the capacitor C7. The threshold voltage of the transistor Tr1 can be changed when the voltage supplied to the back gate of the transistor Tr1 is determined by the wiring VTL, and the threshold voltage of the transistor Tr1 can be fixed with the transistor Tr3 and the capacitor C7.

For example, as the circuit structure that can be used as the current source CS included in the circuit WCSa[k] in FIG. 5A, a current source CS4 illustrated in FIG. 6D may be used. The current source CS4 is different from the current source CS3 in FIG. 6C in that the back gate of the transistor Tr2 is electrically connected not to the second terminal of the transistor Tr2 but to the wiring VTHL. That is, in the current source CS4, the threshold voltage of the transistor Tr2 can be changed with the potential supplied from the wiring VTHL, as in the current source CS2 in FIG. 6B.

When a high current flows between the first terminal and the second terminal of the transistor Tr1 in the current source CS4, to supply the current from the terminal U1 to the outside of the current source CS4, the on-state current of the transistor Tr2 needs to be increased. In this case, in the current source CS4, the wiring VTHL is supplied with a high-level potential to reduce the threshold voltage of the transistor Tr2 and increase the on-state current of the transistor Tr2, whereby a high current flowing between the first terminal and the second terminal of the transistor Tr1 can be supplied from the terminal U1 to the outside of the current source CS4.

The use of any of the current source CS1 to the current source CS4 illustrated in FIG. 6A to FIG. 6D as the current sources CS included in the circuit WCSa[k] in FIG. 5A enables the circuit WCSa to output a current corresponding to the M-bit first data. The amount of the current can be the amount of a current flowing between the first terminal and the second terminal of the transistor F1 in the range where the transistor F1 operates in the subthreshold region, for example.

As the circuit WCSa[k] in FIG. 5A, the current source CS1 illustrated in FIG. 6A may be used. In the circuit WCSa[k] in FIG. 5B, one current source CS1 in FIG. 6A is connected to each of the wiring DW[1] to the wiring DW[M]. When the channel width of the transistor Tr1[1] is w[1], the channel width of the transistor Tr1[2] is w[2], and the channel width of the transistor Tr1[M] is w[M], the ratio between the channel widths is w[1]:w[2]:w[M]=1:2:2M−1. Since a current flowing between a source and a drain of a transistor that operates in the subthreshold region is proportional to the channel width, the circuit WCSa[k] illustrated in FIG. 5B can output a current corresponding to the M-bit first data like the circuit WCSa[k] in FIG. 5A.

As the transistor Tr1 (including the transistor Tr1[1] to the transistor Tr1[M]), the transistor Tr2 (including the transistor Tr2[1] to the transistor Tr2[M]), and the transistor Tr3, a transistor that can be used as the transistor F1 or the transistor F2 can be used, for example. In particular, as the transistor Tr1 (including the transistor Tr1[1] to the transistor Tr1[M]), the transistor Tr2 (including the transistor Tr2[1] to the transistor Tr2[M]), and the transistor Tr3, OS transistors are preferably used.

### [Circuit XCS1 and Circuit XCS2]

The circuit XCS1 has a function of obtaining the second data, which is digital data, from the outside of the arithmetic circuit CDV, converting the second data into analog data (current), and further supplying the second data to the arithmetic cells included in the arithmetic cell array MACA1, for example. In the case where the circuit XCS1 supplies the second data to the arithmetic cells in the k-th row in the arithmetic cell array MACA1, for example, the circuit XCS1 supplies the second data to the arithmetic cells in the k-th row in the arithmetic cell array MACA1 through the wiring XCL1[k].

Similarly, the circuit XCS2 has a function of supplying the second data to the arithmetic cells included in the arithmetic cell array MACA2, for example. In the case where the circuit XCS2 supplies the second data to the arithmetic cells in the k-th row in the arithmetic cell array MACA2, for example, the circuit XCS2 supplies the second data to the arithmetic cells in the k-th row in the arithmetic cell array MACA2 through the wiring XCL2[k].

Note that the circuit structure of the circuit XCS2 is the same as that of the circuit XCS1. Thus, for the circuit structure of the circuit XCS2, the following description of the circuit structure of the circuit XCS1 is to be referred to. In this case, the description of the circuit structure of the circuit XCS2 is made when, in the following description of the circuit structure of the circuit XCS1, the arithmetic cell array MACA1 is replaced with the arithmetic cell array MACA2, the wiring XCL1[1] to the wiring XCL1[s] are replaced with the wiring XCL2[1] to the wiring XCL2[s], and the terminal T5a[1] to the terminal T5a[s] of the switching circuit SWC5 are replaced with the terminal T6a[1] to the terminal T6a[s] of the switching circuit SWC6.

The circuit XCS1 includes a circuit XCSa[1] to a circuit XCSa[s], for example.

In FIG. 2, the circuit XCSa[1] is electrically connected to the terminal T5a[1] of the switching circuit SWC5, for example. The circuit XCSa[s] is electrically connected to the terminal T5a[s] of the switching circuit SWC5, for example.

The circuit XCSa[1] to the circuit XCSa[s] are electrically connected to a wiring IXL[1] to a wiring IXL[s], respectively.

The wiring IXL[1] to the wiring IXL[s] function as wirings for transmitting the second data, which is digital data, respectively to the circuit XCSa[1] to the circuit XCSa[s] from the outside of the arithmetic circuit CDV.

The circuit XCSa[1] to the circuit XCSa[s] have a function of obtaining the later-described reference data from the wiring IXL[1] to the wiring IXL[s] and supplying signals corresponding to the reference data to the wiring XCL1[1] to the wiring XCL1[s], for example. Alternatively, the circuit XCSa[1] to the circuit XCSa[s] have a function of obtaining the second data from the wiring IXL[1] to the wiring IXL[s] and supplying signals corresponding to the second data, for example. Note that in the case of the arithmetic cell array MACA1 in FIG. 2, the above signals are preferably analog data (current).

FIG. 5C is a block diagram illustrating an example of the circuit XCSa[k] included in the circuit XCS1 in FIG. 2. FIG. 5C selectively illustrates the circuit XCSa[k] corresponding to any one of the circuit XCSa[1] to the circuit XCSa[s]. FIG. 5C also illustrates the wiring XCL1[k], the selection circuit SWC5, the terminal T5a[k], the terminal T5b[k], and the terminal T5c[k] to show electrical connection between the circuit XCS and its peripheral circuits.

Accordingly, the circuit XCSa[k] is electrically connected to the wiring XCL1[k]. Since the switching circuit SWC5 is provided between the wiring XCL1[k] and the circuit XCSa[k], the switching circuit SWC5 can switch a conduction state and a non-conduction state between the circuit XCSa[k] and the wiring WCL1[k].

The circuit XCSa[k] illustrated in FIG. 5C includes a switch SWX, for example. A first terminal of the switch SWX is electrically connected to the wiring XCL1[k], and a second terminal of the switch SWX is electrically connected to a wiring VINIL2. The wiring VINIL2 functions as a wiring for supplying an initialization potential to the wiring XCL1[k], and the initialization potential can be set to the ground potential (GND), a low-level potential, or a high-level potential. The initialization potential supplied from the wiring VINIL2 may be the same as the potential supplied from the wiring VINIL1. The switch SWX is in an on state only when the initialization potential is supplied to the wiring XCL1[k]; otherwise, the switch is in an off state.

As the switch SWX, for example, a switch that can be used as the switch SWW can be used.

The circuit XCSa[k] in FIG. 5C can have substantially the same structure as the circuit WCSa[k] in FIG. 5A. Specifically, the circuit XCSa[k] has a function of outputting the reference data as a current amount, and a function of outputting L-bit second data (25 values) (L is an integer greater than or equal to 1) as a current amount; in this case, the circuit XCSa[k] includes 25-1 current sources CS. The circuit XCSa[k] includes one current source CS that outputs information corresponding to the first bit value as a current, two current sources CS that output information corresponding to the second bit value as a current, and 2^{L-1} current sources CS that output information corresponding to the L-th bit value as a current.

The reference data output from the circuit XCSa[k] as a current can be information in which the first bit value is “1” and the second and subsequent bit values are “0”, for example.

In FIG. 5C, the terminal U2 of the one current source CS is electrically connected to a wiring DX[1], the terminals U2 of the two current sources CS are electrically connected to a wiring DX[2], and the terminals U2 of the 2^{L-1} current sources CS are electrically connected to a wiring DX[Z].

A plurality of the current sources CS included in the circuit XCSa[k] have a function of outputting the same constant current I_{Xut} from the terminals U1. The wiring DX[1] to the wiring DX[L] correspond to the wiring IXL[k] described above and function as wirings for obtaining the reference data, which is digital data from the outside, or the second data. Specifically, the wiring DX[1] to the wiring DX[Z] function as wirings for transmitting control signals to make the current sources CS electrically connected to the wiring DX[1] to the wiring DX[L] output I_{Xut}. In other words, the circuit XCSa[k] has a function of making a current with the amount corresponding to the L-bit information transmitted from the wiring DX[1] to the wiring DX[L] flow to the wiring XCL1[k].

Specifically, the circuit XCSa[k] with L of 2 is considered here. For example, when the value of the first bit is “1” and the value of the second bit is “0”, a high-level potential is supplied to the wiring DX[1], and a low-level potential is supplied to the wiring DX[2]. In this case, I_{Xut} flows as a constant current from the circuit XCSa[k] to the wiring XCL. For example, when the value of the first bit is “0” and the value of the second bit is “1”, a low-level potential is supplied to the wiring DX[1], and a high-level potential is supplied to the wiring DX[2]. In this case, 2I_{Xut} flows as a constant current from the circuit XCSa[k] to the wiring XCL1[k]. For example, when the value of the first bit is “1” and the value of the second bit is “1”, a high-level potential is supplied to each of the wiring DX[1] and the wiring DX[2]. In this case, 3I_{Xut} flows as a constant current from the circuit XCSa[k] to the wiring XCL1[k]. For example, when the value of the first bit is “O” and the value of the second bit is “0”, a low-level potential is supplied to each of the wiring DX[1] and the wiring DX[2]. In this case, no constant current flows from the circuit XCSa[k] to the wiring XCL1[k]. In this specification and the like, this case is sometimes rephrased as “a current with an amount of 0 flows from the circuit XCSa[k] to the wiring XCL[k]”. A current amount 0, I_{Xut}, 2I_{Xut}, 3I_{Xut}, or the like output from the circuit XCSa[k] can be the second data output from the circuit XCSa[k]; specifically, a current amount I_{Xut} output from the circuit XCSa[k] can be the reference data output from the circuit XCSa[k].

When the transistors in the current sources CS included in the circuit XCSa[k] have different electrical characteristics and this yields errors, the errors in constant currents I_{Xut} output from the terminals U1 of the plurality of current sources CS are preferably within 10%, further preferably within 5%, still further preferably within 1%. In this embodiment, the description is made on the assumption that there is no error in constant currents I_{Xut} output from the terminals U1 of the plurality of current sources CS included in the circuit XCSa[k].

As the current source CS of the circuit XCSa[k], any of the current source CS1 to the current source CS4 in FIG. 6A to FIG. 6D can be used in a manner similar to that of the current source CS of the circuit WCSa[k]. In that case, the wiring DW illustrated in FIG. 6A to FIG. 6D is replaced with the wiring DX. This allows the circuit XCSa[k] to make a current within the current range of the subthreshold region flow through the wiring XCL[k] as the reference data or the L-bit second data.

The circuit XCSa[k] in FIG. 5C can have a circuit structure similar to that of the circuit WCSa[k] illustrated in FIG. 5B. In that case, the circuit WCSa[k] illustrated in FIG. 5B is replaced with the circuit XCSa[k], the wiring IWL[k] is replaced with the wiring IXL[k], the wiring DW[1] is replaced with the wiring DX[1], the wiring DW[2] is replaced with the wiring DX[2], the wiring DW[M] is replaced with the wiring DX[Z], the switch SWW is replaced with the switch SWX, and the wiring VINIL1 is replaced with the wiring VINIL2.

### [Memory Cell Array MEMA1 and Memory Cell Array MEMA2]

The memory cell array MEMA1 has a function of storing a result of an arithmetic operation performed in the arithmetic cell array MACA1, for example. Specifically, the result of the arithmetic operation is stored in the memory cell included in the memory cell array MEMA1. Note that depending on circumstances, the memory cell array MEMA1 may store a result of an arithmetic operation performed in the arithmetic cell array MACA2.

Similarly, the memory cell array MEMA2 has a function of storing a result of an arithmetic operation performed in the arithmetic cell array MACA2, for example. Specifically, the result of the arithmetic operation is stored in the memory cell included in the memory cell array MEMA2. Note that depending on circumstances, the memory cell array MEMA2 may store a result of an arithmetic operation performed in the arithmetic cell array MACA1.

The memory cell array MEMA1 includes a cell MC1[1,1] to a cell MC1[s,s], for example. The memory cell array MEMA2 includes a cell MC2[1,1] to a cell MC2[s,s], for example.

Note that the structure of the memory cell array MEMA2 is the same as that of the memory cell array MEMA1. That is, the structures of the cell MC2[1,1] to the cell MC2[s,s] are the same as those of the cell MC1[1,1] to the cell MC1[s,s], respectively. Thus, for the structures of the cell MC2[1,1] to the cell MC2[s,s], the following description of the structures of the cell MC1[1,1] to the cell MC1[s,s] is to be referred to. In this case, the description of the structures of the cell MC2[1,1] to the cell MC2[s,s] is made when, in the following description of the structures of the cell MC1[1,1] to the cell MC1[s,s], the memory cell array MEMA1 is replaced with the memory cell array MEMA2, the wiring WWL1[1] to the wiring WWL1[s] are replaced with the wiring WWL2[1] to the wiring WWL2[s], the wiring RWL1[1] to the wiring RWL1[s] are replaced with the wiring RWL2[1] to the wiring RWL2[s], and the wiring BL1[1] to the wiring BL1[s] are replaced with the wiring BL2[1] to the wiring BL2[s].

The cell MC1[1,1] to the cell MC1[s,s] function as memory cells, for example.

The cell MC1[1,1] to the cell MC1[s,s] each include a transistor F7, a transistor F8, a transistor F9, and a capacitor C6, for example.

In particular, the structures (including the channel lengths and the channel widths) of the transistors F7 included in the cell MC1[1,1] to the cell MC1[s,s] are preferably the same, the structures of the transistors F8 included in the cell MC1[1,1] to the cell MC1[s,s] are preferably the same, and the structures of the transistors F9 included in the cell MC1[1,1] to the cell MC1[s,s] are preferably the same. For the advantages of employing the same transistor structure, the description of the transistor F1, the transistor F2, and the transistor F5 is to be referred to.

Note that the transistor F7 and the transistor F9 may function as switching elements unless otherwise specified. In other words, the gate voltage, the source voltage, and the drain voltage of each of the above transistors may be appropriately biased to voltages in the range where the transistor operates as switching elements. However, one embodiment of the present invention is not limited thereto. For example, the transistor F7 and the transistor F9 in an on state may operate in a linear region or a saturation region or may operate both in a linear region and a saturation region.

Unless otherwise specified, the transistor F8 may operate in the subthreshold region (i.e., the gate-source voltage may be lower than the threshold voltage in the transistor F8, further preferably, the drain current increases exponentially with respect to the gate-source voltage). In other words, the gate voltage, the source voltage, and the drain voltage of the transistor F8 may be appropriately biased to voltages in the range where the transistor operates in the subthreshold region. Thus, the transistor F8 may operate such that an off-state current flows between the source and the drain.

Note that as each of the transistors F7 to the transistor F9, a transistor that can be used as the transistor F1, the transistor F2, or the transistor F5 can be used, for example.

In each of the cell MC1[1,1] to the cell MC1[s,s], a first terminal of the transistor F7 is electrically connected to a gate of the transistor F8. A first terminal of the transistor F8 is electrically connected to a wiring VE2. A first terminal of the capacitor C6 is electrically connected to the gate of the transistor F8. A second terminal of the transistor F8 is electrically connected to a first terminal of the transistor F9. A second terminal of the transistor F9 is electrically connected to a second terminal of the transistor F7, and a second terminal of the capacitor C6 is electrically connected to a wiring VE3.

For back gates of the transistor F7 to the transistor F9 in FIG. 4A or FIG. 4B, the above description of the back gates of the transistor F1, the transistor F2, the transistor F5, the transistor F1d, the transistor F2d, and the transistor F5d is to be referred to.

The wiring VE2 functions as a wiring for making a current flow between the first terminal and the second terminal of the transistor F8 in each of the cell MC1[1,1] to the cell MC1[s,s]. The wiring VE2 functions as a wiring for supplying a constant potential, for example. The constant potential can be, for example, a low-level potential or the ground potential.

The wiring VE3 functions as a wiring for applying a potential to the second terminal of the capacitor C6 in each of the cell MC1[1,1] to the cell MC1[s,s]. The potential can be, for example, a low-level potential or the ground potential.

In the cell MC1[1,1], the second terminal of the transistor F7 and the second terminal of the transistor F9 are electrically connected to the wiring BL1[1], and a gate of the transistor F7 is electrically connected to the wiring WWL1[1]. A gate of the transistor F9 is electrically connected to the wiring RWL1[1].

In the cell MC1[s, 1], the second terminal of the transistor F7 and the second terminal of the transistor F9 are electrically connected to the wiring BL1[1], and the gate of the transistor F7 is electrically connected to the wiring WWL1[s]. The gate of the transistor F9 is electrically connected to the wiring RWL1[s].

In the cell MC1[1,s], the second terminal of the transistor F7 and the second terminal of the transistor F9 are electrically connected to the wiring BL1[s], and the gate of the transistor F7 is electrically connected to the wiring WWL1[1]. The gate of the transistor F9 is electrically connected to the wiring RWL1[1].

In the cell MC1[s,s], the second terminal of the transistor F7 and the second terminal of the transistor F9 are electrically connected to the wiring BL1[s], and the gate of the transistor F7 is electrically connected to the wiring WWL1[s]. The gate of the transistor F9 is electrically connected to the wiring RWL1[s].

Note that the first terminals of the capacitors C6 in the cell IM1[1,1] to the cell IM1[s,s] function as retention nodes of their respective cells.

Next, a writing operation for the cell MC1[1,1] to the cell MC1[s,s] will be described. For example, when the transistor F7 and the transistor F9 are in an on state, a conduction state is established between the gate and the second terminal of the transistor F8. When a constant potential applied from the wiring VE2 is the ground potential (GND), the transistor F7 is in an on state, and a current with a current amount I flows from the wiring BL1 to the second terminal of the transistor F8, the potential of the gate of the transistor F8 (the node N) is determined in accordance with a current amount I. Since the transistor F7 is in an on state, the potential of the second terminal of the transistor F8 is ideally equal to that of the gate of the transistor F8 (the node N). Here, by turning off the transistor F7, the potential of the gate of the transistor F8 (the node N) is retained by the capacitor C6. After that, the transistor F9 is turned off, whereby the writing operation is completed.

By the above writing operation, the amount of a current flowing between the source and the drain of the transistor F8 in the cell MC1 is set to I. When the transistor F9 is in an off state, no current flows between the source and the drain of the transistor F8.

To read the written data from the cell MC1[1,1] to the cell MC1[s,s], the transistor F9 is turned on to make a current with a current amount/set in the transistor F8 flow to the wiring BL1.

### [Switching Circuit SWC1 to Switching Circuit SWC3, Switching Circuit SWC5, and Switching Circuit SWC6]

The switching circuit SWC1 has a function of establishing a conduction state or a non-conduction state between the terminal T1a[k] and the terminal T1b[k], a function of establishing a conduction state or a non-conduction state between the terminal T1c[k] and the terminal T1d[k], and a function of establishing a conduction state or a non-conduction state between the terminal T1a[k] and the terminal T1c[k], for example.

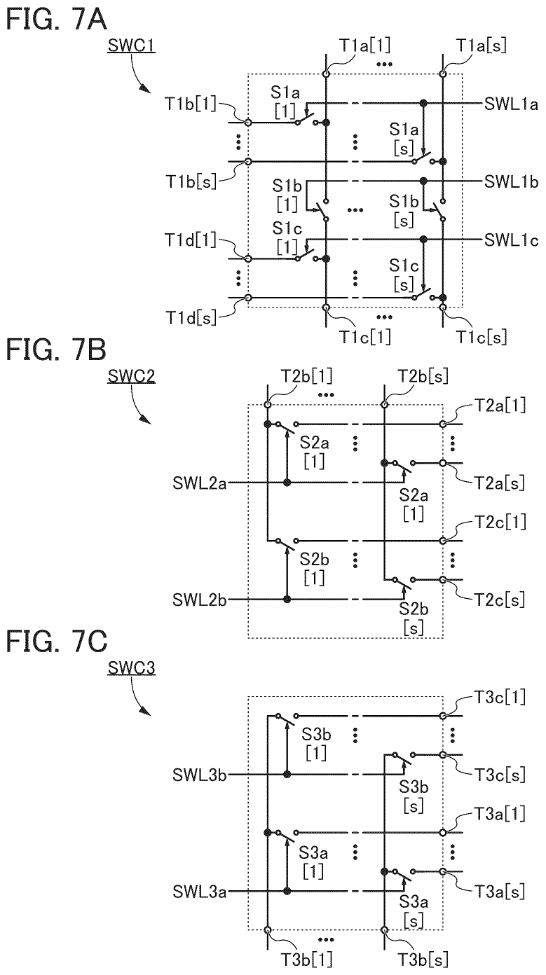

FIG. 7A illustrates a structure example of the switching circuit SWC1. The switching circuit SWC1 in FIG. 7A includes a switch Sla[1] to a switch Sla[s], a switch S1b[1] to a switch S1b[s], and a switch S1c[1] to a switch S1c[s], for example.

A first terminal of the switch Sla[k] is electrically connected to the terminal T1a[k], and a second terminal of the switch Sla[k] is electrically connected to the terminal T1b[k]. A first terminal of the switch S1b[k] is electrically connected to the terminal T1a[k], and a second terminal of the switch S1b[k] is electrically connected to the terminal T1c[k]. A first terminal of the switch S1c[k] is electrically connected to the terminal T1d[k], and a second terminal of the switch S1c[k] is electrically connected to the terminal T1c[k].

Control terminals of the switch Sla[1] to the switch Sla[s] are electrically connected to a wiring SWL1a. Control terminals of the switch S1b[1] to the switch S1b[s] are electrically connected to a wiring SWL1b. Control terminals of the switch S1c[1] to the switch S1c[s] are electrically connected to a wiring SWL1c.

The switching circuit SWC2 has a function of establishing a conduction state or a non-conduction state between the terminal T2a[k] and the terminal T2b[k] and a function of establishing a conduction state or a non-conduction state between the terminal T2b[k] and the terminal T2c[k], for example.

FIG. 7B illustrates a structure example of the switching circuit SWC2. The switching circuit SWC2 in FIG. 7B includes a switch S2a[1] to a switch S2a[s] and a switch S2b[1] to a switch S2b[s], for example.

A first terminal of the switch S2a[k] is electrically connected to the terminal T2a[k], and a second terminal of the switch S2a[k] is electrically connected to the terminal T2b[k]. A first terminal of the switch S2b[k] is electrically connected to the terminal T2b[k], and a second terminal of the switch S2b[k] is electrically connected to the terminal T2c[k].

Control terminals of the switch S2a[1] to the switch S2a[s] are electrically connected to a wiring SWL2a. Control terminals of the switch S2b[1] to the switch S2b[s] are electrically connected to a wiring SWL2b.

The switching circuit SWC3 has a function of establishing a conduction state or a non-conduction state between the terminal T3a[k] and the terminal T3b[k] and a function of establishing a conduction state or a non-conduction state between the terminal T3b[k] and the terminal T3c[k], for example.

FIG. 7C illustrates a structure example of the switching circuit SWC3. The switching circuit SWC3 in FIG. 7C includes a switch S3a[1] to a switch S3a[s] and a switch S3b[1] to a switch S3b[s], for example.

A first terminal of the switch S3a[k] is electrically connected to the terminal T3a[k], and a second terminal of the switch S3a[k] is electrically connected to the terminal T3b[k]. A first terminal of the switch S3b[k] is electrically connected to the terminal T3b[k], and a second terminal of the switch S3b[k] is electrically connected to the terminal T3c[k].

Control terminals of the switch S3a[1] to the switch S3a[s] are electrically connected to a wiring SWL3a. Control terminals of the switch S3b[1] to the switch S3b[s] are electrically connected to a wiring SWL3b.

The switching circuit SWC5 has a function of establishing a conduction state or a non-conduction state between the terminal Ta[k] and the terminal T5b[k] and a function of establishing a conduction state or a non-conduction state between the terminal T5b[k] and the terminal T5c[k], for example.

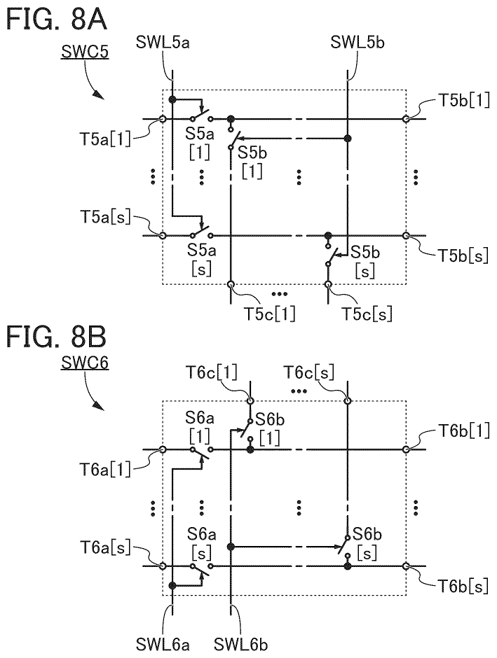

FIG. 8A illustrates a structure example of the switching circuit SWC5. The switching circuit SWC5 in FIG. 8A includes a switch S5a[1] to a switch S5a[s] and a switch S5b[1] to a switch S5b[s], for example.

A first terminal of the switch S5a[k] is electrically connected to the terminal T5a[k], and a second terminal of the switch S5a[k] is electrically connected to the terminal T5b[k]. A first terminal of the switch S5b[k] is electrically connected to the terminal T5b[k], and a second terminal of the switch S5b[k] is electrically connected to the terminal T5c[k].

Control terminals of the switch S5a[1] to the switch S5a[s] are electrically connected to a wiring SWL5a. Control terminals of the switch S5b[1] to the switch S5b[s] are electrically connected to a wiring SWL5b.

The switching circuit SWC6 has a function of establishing a conduction state or a non-conduction state between the terminal T6a[k] and the terminal T6b[k] and a function of establishing a conduction state or a non-conduction state between the terminal T6b[k] and the terminal T6c[k], for example.

FIG. 8B illustrates a structure example of the switching circuit SWC6. The switching circuit SWC6 in FIG. 8B includes a switch S6a[1] to a switch S6a[s] and a switch S6b[1] to a switch S6b[s], for example.

A first terminal of the switch S6a[k] is electrically connected to the terminal T6a[k], and a second terminal of the switch S6a[k] is electrically connected to the terminal T6b[k]. A first terminal of the switch S6b[k] is electrically connected to the terminal T6b[k], and a second terminal of the switch S6b[k] is electrically connected to the terminal T6c[k].

Control terminals of the switch S6a[1] to the switch S6a[s] are electrically connected to a wiring SWL6a. Control terminals of the switch S6b[1] to the switch S6b[s] are electrically connected to a wiring SWL6b.

As each of the switch Sla[1] to the switch Sla[s], the switch S1b[1] to the switch S1b[s], the switch S1c[1] to the switch S1c[s], the switch S2a[1] to the switch S2a[s], the switch S2b[1] to the switch S2b[s], the switch S3a[1] to the switch S3a[s], the switch S3b[1] to the switch S3b[s], the switch S5a[1] to the switch S5a[s], the switch S5b[1] to the switch S5b[s], the switch S6a[1] to the switch S6a[s], and the switch S6b[1] to the switch S6b[s], a switch that can be used as the switch SA[k] can be used, for example.

In this specification and the like, each of the above-described switches is in an on state when a high-level potential is supplied to the control terminal, and each of the above-described switches is in an off state when a low-level potential is supplied to the control terminal.

The wiring S1La, the wiring S1Lb, the wiring S1Lc, the wiring S2La, the wiring S2Lb, the wiring S3La, the wiring S3Lb, the wiring S5La, the wiring S5Lb, the wiring S6La, and the wiring S6Lb described above each function as a wiring for switching an on state and an off state of a switch including a control terminal electrically connected to the wiring. Accordingly, the above-described wirings are each supplied with a high-level potential or a low-level potential, for example.

With the use of the switching circuit SWC1 to the switching circuit SWC3, the switching circuit SWC5, and the switching circuit SWC6, an input terminal for inputting a signal to the inside of the switching circuit and an output terminal for outputting the signal to the outside can be selected.

### [Current Generation Circuit CM1 and Current Generation Circuit CM2]

The current generation circuit CM1 has a function of outputting, to the terminal C1To[k], the amount of a current equal to the amount of a current output to the terminal C1Ti[k], for example. Like the current generation circuit CM1, the circuit current generation CM2 has a function of outputting, to the terminal C2To[k], the amount of a current equal to the amount of a current output to the terminal C2Ti[k], for example.

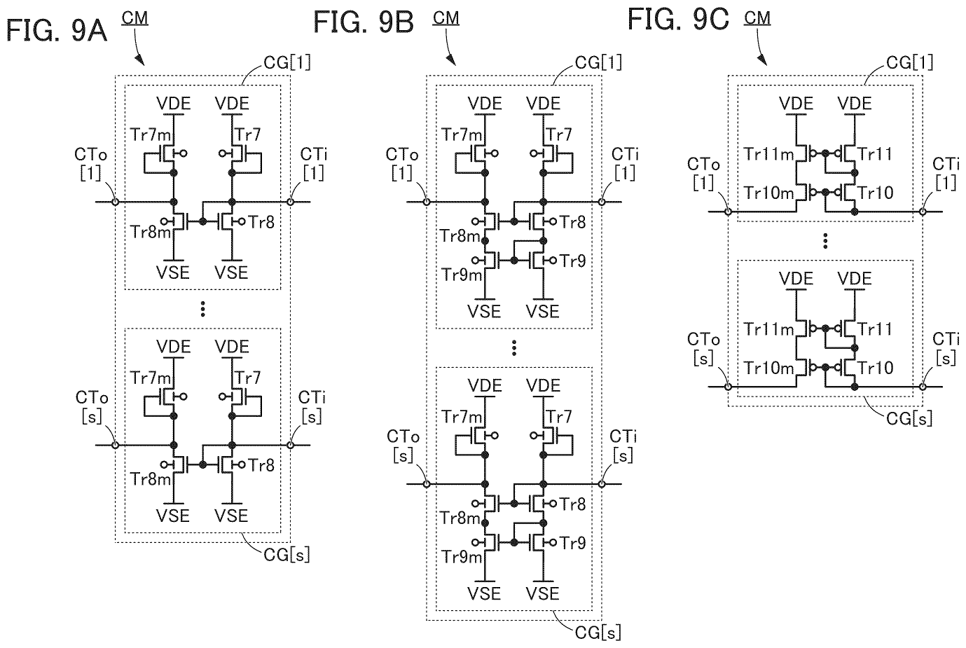

FIG. 9A illustrates a specific circuit structure example of the current generation circuit CM1 and the current generation circuit CM2. The current generation circuit CM illustrated in FIG. 9A has a circuit structure applicable to the current generation circuit CM1 and the current generation circuit CM2 and includes a circuit CG[1] to a circuit CG[s].

The circuit CG[1] to the circuit CG[s] can have the same structure. In this embodiment, the circuit CG[1] to the circuit CG[s] are described as having the same structure.

When the current generation circuit CM in FIG. 9A is used as the current generation circuit CM1 in the arithmetic circuit CDV in FIG. 1, a terminal CTi[1] to a terminal CTi[s] of the current generation circuit CM in FIG. 9A correspond to the terminal C1Ti[1] to the terminal C1Ti[s] of the current generation circuit CM1 in FIG. 1, and a terminal CTo[1] to a terminal CTo[s] of the current generation circuit CM in FIG. 9A correspond to the terminal C1To[1] to the terminal C1To[s] of the current generation circuit CM1 in FIG. 1. When the current generation circuit CM in FIG. 9A is used as the current generation circuit CM2 in the arithmetic circuit CDV in FIG. 1, the terminal CTi[1] to the terminal CTi[s] of the current generation circuit CM in FIG. 9A correspond to the terminal C2Ti[1] to the terminal C2Ti[s] of the current generation circuit CM2 in FIG. 1, and the terminal CTo[1] to the terminal CTo[s] of the current generation circuit CM in FIG. 9A correspond to the terminal C2To[1] to the terminal C2To[s] of the current generation circuit CM2 in FIG. 1.

The circuit CG[k] (not shown) includes a transistor Tr7, a transistor Tr7m, a transistor Tr8, and a transistor Tr8m. Note that in FIG. 9, the transistor Tr7, the transistor Tr7m, the transistor Tr8, and the transistor Tr8m are n-channel transistors.

In the circuit CG[k], a first terminal of the transistor Tr7 is electrically connected to a wiring VDE, and a second terminal of the transistor Tr7 is electrically connected to a gate of the transistor Tr7, a first terminal of the transistor Tr8, a gate of the transistor Tr8, a gate of the transistor Tr8m, and the terminal CTi[k] (not shown). A second terminal of the transistor Tr8 is electrically connected to a wiring VSE.

A first terminal of the transistor Tr7m is electrically connected to the wiring VDE, and a second terminal of the transistor Tr7m is electrically connected to a gate of the transistor Tr7m, a first terminal of the transistor Tr8m, and the terminal CTo[k] (not shown). A second terminal of the transistor Tr8m is electrically connected to the wiring VSE.

The wiring VDE functions as a wiring for supplying a potential to the first terminal of each of the transistors Tr7 and the transistors Tr7m in the circuit CG[1] to the circuit CG[s]. The constant potential can be a high-level potential, for example.

The wiring VSE functions as a wiring for supplying a potential to the second terminal of each of the transistors Tr8 and the transistors Tr8m in the circuit CG[1] to the circuit CG[s]. The constant potential can be, for example, the ground potential, a low-level potential, or a negative potential.

In FIG. 9A, when the constant potential supplied from the wiring VDE is a high-level potential, a high-level potential is input to the first terminal of the transistor Tr7. The potential of the second terminal of the transistor Tr7 is lower than the high-level potential. At this time, the first terminal of the transistor Tr7 functions as a drain, and the second terminal of the transistor Tr7 functions as a source. Since the gate of the transistor Tr7 is electrically connected to the second terminal of the transistor Tr7, the gate-source voltage of the transistor Tr7 is 0 V. Thus, when the threshold voltage of the transistor Tr7 is within an appropriate range, a current in the current range of the subthreshold region (drain current) flows between the first terminal and the second terminal of the transistor Tr7. The amount of the current is preferably smaller than or equal to 1.0×10⁻⁸ A, further preferably smaller than or equal to 1.0×10⁻¹² A, still further preferably smaller than or equal to 1.0×10⁻¹⁵ A, for example, when the transistor Tr7 is an OS transistor. For example, the current is further preferably within a range where the current exponentially increases with respect to the gate-source voltage. That is, the transistor Tr7 functions as a current source for supplying a current within a current range of the transistor Tr7 operating in the subthreshold region. Note that the same applies to the transistor Tr7m.

In FIG. 9A, the first terminal of the transistor Tr8 is electrically connected to the gate of the transistor Tr8 and the gate of the transistor Tr8m; thus, the connection structure between the transistor Tr8 and the transistor Tr8m forms a current mirror circuit. In other words, ideally, the amount of a current flowing between a source and a drain of the transistor Tr8 is equal to the amount of a current flowing between a source and a drain of the transistor Tr8m.

The amount of a current flowing between the source and the drain of the transistor Tr8 is I_{SC}-I_{OP}, where I_{SC} is the amount of a current flowing between a source and a drain of each of the transistor Tr7 and the transistor Tr7m and I_{OP} is the current amount output from the circuit CG[k] to the terminal CTi[k]. Accordingly, the amount of a current flowing between the source and the drain of the transistor Tr8m is also I_{SC}−I_{OP}. Thus, the current amount output from the circuit CG[k] to the terminal CTo[k] is I_{SC}−(I_{SC}−I_{OP})=I_{OP}. Accordingly, the circuit CG[k] can output, to the terminal CTo[k], the amount of a current equal to the amount of a current output to the terminal CTi[k].

The structures of the circuit CG[1] to the circuit CG[s] according to the semiconductor device of one embodiment of the present invention are not limited to the structures illustrated in FIG. 9A. The structures illustrated in FIG. 9A may be changed depending on circumstances and applied to the structures of the circuit CG[1] to the circuit CG[s] according to the semiconductor device of one embodiment of the present invention.

For example, the structures of the circuit CG[1] to the circuit CG[s] illustrated in FIG. 9A may be changed to the structures of the circuit CG[1] to the circuit CG[s] illustrated in FIG. 9B. The circuit CG[k] (not shown) in FIG. 9B has a structure in which the circuit CG[k] in FIG. 9A is further provided with a transistor Tr9 and a transistor Tr9m, which are n-channel transistors, the transistor Tr8 and the transistor Tr9 are cascode-connected to each other, and the transistor Tr8m and the transistor Tr9m are cascode-connected to each other. When the transistors included in the current mirror circuit are cascode-connected as illustrated in FIG. 9B, the operation of the current mirror circuit can be more stable.

For example, the structures of the current generation circuit CM1 and the current generation circuit CM2 illustrated in FIG. 1 may each be the structure of the current generation circuit CM illustrated in FIG. 9C.

The circuit CG[1] to the circuit CG[s] included in the current generation circuit CM in FIG. 9C each include a transistor Tr10, a transistor Tr10m, a transistor Tr11, and a transistor Tr11m. Note that the transistor Tr10, the transistor Tr10m, the transistor Tr11, and the transistor Tr11m are p-channel transistors.

In the circuit CG[k] in FIG. 9C, a first terminal of the transistor Tr11 is electrically connected to the wiring VDE, and a second terminal of the transistor Tr11 is electrically connected to a gate of the transistor Tr11, a gate of the transistor Tr11m, and a first terminal of the transistor Tr10. A second terminal of the transistor Tr10 is electrically connected to a gate of the transistor

Tr10, a gate of the transistor Tr10m, and the terminal CTi[k]. A first terminal of the transistor Tr11m is electrically connected to the wiring VDE, and a second terminal of the transistor Tr11m is electrically connected to a first terminal of the transistor Tr10m. A second terminal of the transistor Tr10m is electrically connected to the terminal CTo[k].

The circuit CG[k] in FIG. 9C has a structure of a current mirror circuit in which the transistor Tr10 and the transistor Tr11 are cascode-connected to each other and the transistor Tr10m and the transistor Tr11m are cascode-connected to each other. Thus, the circuit CG[k] can output, to the terminal CTo[k], the amount of a current equal to the amount of a current output to the terminal CTi[k]. Note that the circuit CG[k] in FIG. 9C may be a current mirror circuit having a structure in which the transistor Tr11 and the transistor Tr11m are not provided (cascode connection is not performed), for example.

### [Current Generation Circuit RL1 and Current Generation Circuit RL2]

The current generation circuit RL1 includes an arithmetic circuit of a function system, for example. Specifically, for example, the current generation circuit RL1 has a function of performing an arithmetic operation of a function system with the use of a value corresponding to the amount of a current output to the terminal R1Ti[k] as an input value and outputting a current with an amount corresponding to the result of the arithmetic operation to the terminal R1To[k].

The current generation circuit RL2 may include, for example, an arithmetic circuit of a function system similar to the arithmetic circuit in the current generation circuit RL1.

The arithmetic circuit of a function system included in each of the current generation circuit RL1 and the current generation circuit RL2 can be, for example, an arithmetic circuit of a sigmoid function, a tanh function, a softmax function, a ReLU function, or a threshold function. The current generation circuit RL1 and the current generation circuit RL2 may each include a circuit performing pooling processing, instead of the arithmetic circuit of a function system.

Here, a circuit structure in which the current generation circuit RL1 and the current generation circuit RL2 each include an arithmetic circuit of a ReLU function is described as an example.

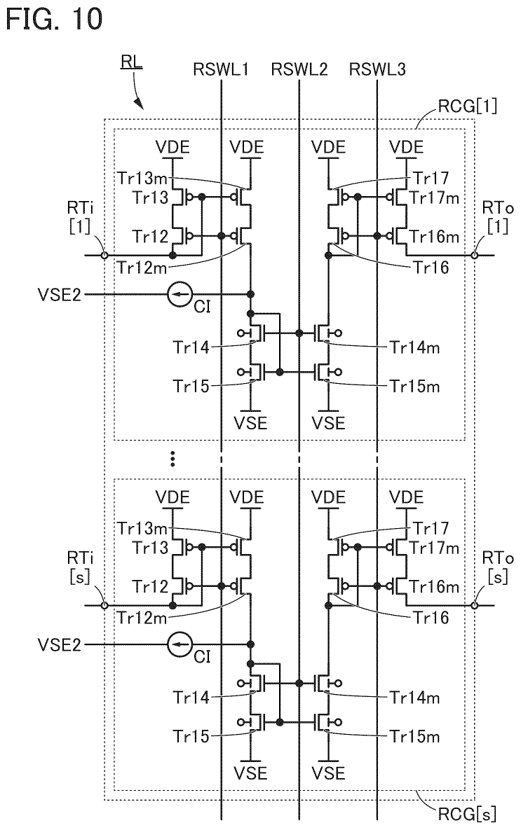

The current generation circuit RL illustrated in FIG. 10 is an example of a circuit structure of the current generation circuit RL1 or the current generation circuit RL2 that includes an arithmetic circuit of a ReLU function. The current generation circuit RL illustrated in FIG. 10 includes a circuit RCG[1] to a circuit RCG[s], for example.

The circuit RCG[1] to the circuit RCG[s] can have the same structure. Note that in this embodiment, the circuit RCG[1] to the circuit RCG[s] are described as having the same structure.

When the current generation circuit RL in FIG. 10 is used as the current generation circuit RL1 in the arithmetic circuit CDV in FIG. 1, a terminal RTi[1] to a terminal RTi[s] of the current generation circuit RL in FIG. 10 correspond to the terminal R1Ti[1] to the terminal R1Ti[s] of the current generation circuit RL1 in FIG. 1, and a terminal RTo[1] to a terminal RTo[s] of the current generation circuit RL in FIG. 10 correspond to the terminal R1To[1] to the terminal R1To[s] of the current generation circuit RL1 in FIG. 1. When the current generation circuit RL in FIG. 10 is used as the current generation circuit RL2 in the arithmetic circuit CDV in FIG. 1, the terminal RTi[1] to the terminal RTi[s] of the current generation circuit RL in FIG. 10 correspond to the terminal R2Ti[1] to the terminal R2Ti[s] of the current generation circuit RL2 in FIG. 1, and the terminal RTo[1] to the terminal RTo[s] of the current generation circuit RL in FIG. 10 correspond to the terminal R2To[1] to the terminal R2To[s] of the current generation circuit RL2 in FIG. 1.

The circuit RCG[k] (not shown) includes, for example, a transistor Tr12, a transistor Tr12m, a transistor Tr13, a transistor Tr13m, a transistor Tr14, a transistor Tr14m, a transistor Tr15, a transistor Tr15m, a transistor Tr16, a transistor Tr16m, a transistor Tr17, and a transistor Tr17m. Note that in FIG. 10, the transistor Tr12, the transistor Tr12m, the transistor Tr13, the transistor Tr13m, the transistor Tr16, the transistor Tr16m, the transistor Tr17, and the transistor Tr17m are p-channel transistors. In FIG. 10, the transistor Tr14, the transistor Tr14m, the transistor Tr15, and the transistor Tr15m are n-channel transistors.

In the circuit RCG[k], a first terminal of the transistor Tr13 is electrically connected to the wiring VDE, a second terminal of the transistor Tr13 is electrically connected to a first terminal of the transistor Tr12, and a gate of the transistor Tr13 is electrically connected to a gate of the transistor Tr13m, a second terminal of the transistor Tr12, and the terminal RTi[k]. A gate of the transistor Tr12 is electrically connected to a wiring RSWL1 and a gate of the transistor Tr12m. A first terminal of the transistor Tr13m is electrically connected to the wiring VDE, and a second terminal of the transistor Tr13m is electrically connected to a first terminal of the transistor Tr12m.

A second terminal of the transistor Tr12m is electrically connected to an input terminal of a constant current source CI, a first terminal of the transistor Tr14, a gate of the transistor Tr15, and a gate of the transistor Tr15m. A second terminal of the transistor Tr14 is electrically connected to a first terminal of the transistor Tr15, and a gate of the transistor Tr14 is electrically connected to a wiring RSWL2 and a gate of the transistor Tr14m. A second terminal of the transistor Tr15 is electrically connected to the wiring VSE.

An output terminal of the constant current source CI is electrically connected to a wiring VSE2.

A first terminal of the transistor Tr17 is electrically connected to the wiring VDE, and a second terminal of the transistor Tr17 is electrically connected to a first terminal of the transistor Tr16. A second terminal of the transistor Tr16 is electrically connected to a gate of the transistor Tr17, a gate of the transistor Tr17m, and a first terminal of the transistor Tr14m. A second terminal of the transistor Tr14m is electrically connected to a first terminal of the transistor Tr15m, and a second terminal of the transistor Tr15m is electrically connected to the wiring VSE.

A gate of the transistor Tr16 is electrically connected to a wiring RSWL3 and a gate of the transistor Tr16m. A first terminal of the transistor Tr17m is electrically connected to the wiring VDE, and a second terminal of the transistor Tr17m is electrically connected to a first terminal of the transistor Tr16m. A second terminal of the transistor Tr16m is electrically connected to the terminal RTo[k].

The description of the wiring VDE in the description of the current generation circuit CM is to be referred to for the wiring VDE. The description of the wiring VSE in the description of the current generation circuit CM is to be referred to for the wiring VSE.

The wiring VSE2 functions as a wiring for supplying a constant potential to the output terminal of the constant current source CI. The constant potential can be, for example, a low-level potential, the ground potential, or a negative potential. The constant potential supplied from the wiring VSE2 may be equal to the constant potential supplied from the wiring VSE.

In FIG. 10, the transistor Tr12, the transistor Tr12m, the transistor Tr14, the transistor Tr14m, the transistor Tr16, and the transistor Tr16m each function as a transistor for cascode connection, for example. Thus, the wiring RSWL1 has a function of a wiring supplying a bias potential to the gates of the transistor Tr12 and the transistor Tr12m, for example. The wiring RSWL2 has a function of a wiring supplying a bias potential to the gates of the transistor Tr14 and the transistor Tr14m, for example. The wiring RSWL3 has a function of a wiring supplying a bias potential to the gates of the transistor Tr16 and the transistor Tr16m, for example.

Note that the transistor Tr12, the transistor Tr12m, the transistor Tr14, the transistor Tr14m, the transistor Tr16, and the transistor Tr16m may each operate as a switching transistor. For example, supplying a high-level potential to the wiring RSWL1 can turn off the transistor Tr12 and the transistor Tr12m. Furthermore, supplying a low-level potential to the wiring RSWL2 can turn off the transistor Tr15 and the transistor Tr15m. Furthermore, supplying a high-level potential to the wiring RSWL3 can turn off the transistor Tr16 and the transistor Tr16m.

In FIG. 10, the gate of the transistor Tr13 is electrically connected to the terminal RTi[k] and the gate of the transistor Tr13m; thus, the connection structure between the transistor Tr13 and the transistor Tr13m forms a current mirror circuit. In other words, ideally, the amount of a current flowing between a source and a drain of the transistor Tr13 is equal to the amount of a current flowing between a source and a drain of the transistor Tr13m.

Similarly, in FIG. 10, the first terminal of the transistor Tr15 is electrically connected to the gate of the transistor Tr15 and the gate of the transistor Tr15m through the transistor Tr14; thus, the connection structure between the transistor Tr15 and the transistor Tr15m forms a current mirror circuit. In other words, ideally, the amount of a current flowing between a source and a drain of the transistor Tr15 is equal to the amount of a current flowing between a source and a drain of the transistor Tr15m. Similarly, the gate of the transistor Tr17 is electrically connected to the gate of the transistor Tr17m and the second terminal of the transistor Tr16; thus, the connection structure between the transistor Tr17 and the transistor Tr17m forms a current mirror circuit. In other words, ideally, the amount of a current flowing between a source and a drain of the transistor Tr17 is equal to the amount of a current flowing between a source and a drain of the transistor Tr17m.

The constant current source CI outputs a constant current with a current amount I_{STD} to the wiring VSE2, for example. I_{STD} corresponds to a reference value of a ReLU function in the circuit RCG[k].

Upon output of a current with a current amount I_{OP} from the terminal RTi[k], the circuit RCG[k] outputs a current with a current amount I_{OP}−I_{STD} from the terminal RTo[k] when I_{OP}>I_{STD}. When I_{OP}≤I_{STD}, the circuit RCG[k] outputs no current from the terminal RTo[k].

### [Circuit ITRZ]

The circuit ITRZ includes, for example, an arithmetic circuit of a function system and an analog-digital converter circuit. In particular, the arithmetic circuit of a function system preferably has a function of performing an arithmetic operation of a function system using a value corresponding to the amount of an input current as an input value and outputting digital data (voltage) corresponding to the result of the arithmetic operation, for example.

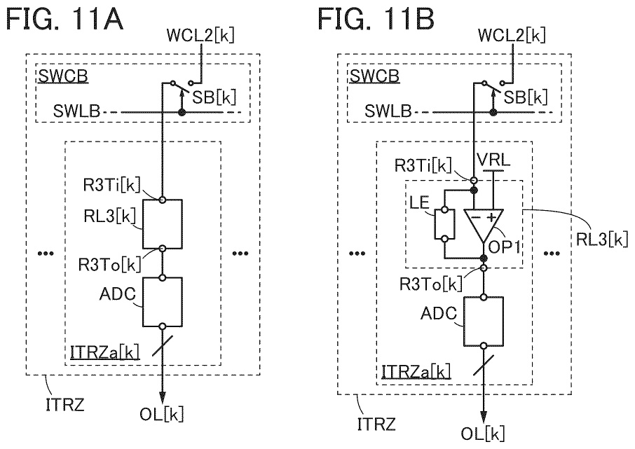

FIG. 11A illustrates a circuit structure example of the circuit ITRZ. The circuit ITRZ illustrated in FIG. 11A is an example of a circuit that can be used as the circuit ITRZ illustrated in FIG. 1 and FIG. 3. FIG. 11A also shows the wiring WCL2[k] to illustrate electrical connection between the circuit ITRZ and its peripheral circuit. The wiring WCL2[k] is any one of the wiring WCL2[1] to the wiring WCL2[n] included in the arithmetic circuit CDV in FIG. 1 and FIG. 3, and a switch SB[k] is any one of a switch SB[1] to a switch SB[s] included in a circuit SWCB illustrated in FIG. 3.

As the switch SB[k], for example, a switch that can be used as the switch SA[k] can be used. For example, a mechanical switch or an electrical switch such as an analog switch can be used as the switch SB[k].

The circuit ITRZ in FIG. 11A includes the circuit SWCB and a circuit ITRZa[1] to a circuit ITRZa[s]. Note that FIG. 11A selectively illustrates the circuit ITRZa[k], which is any one of the circuit ITRZa[1] to the circuit ITRZa[s]. The circuit ITRZa[k] includes a converter circuit RL3[k] and an analog-digital converter circuit ADC.

The converter circuit RL3[k] includes a terminal R3Ti[k] and a terminal R3To[k].

A first terminal of the switch SB[k] is electrically connected to the wiring WCL2[k], and a second terminal of the switch SB[k] is electrically connected to the terminal R3Ti[k] of the converter circuit RL3[k]. The terminal R3To[k] of the converter circuit RL3[k] is electrically connected to an input terminal of the analog-digital converter circuit ADC, and an output terminal of the analog-digital converter circuit ADC is electrically connected to a wiring OL[k].

The wiring OL[k] (a wiring OL[1] to a wiring OL[s] in FIG. 1) functions as a wiring for outputting a result of an arithmetic operation performed in the arithmetic circuit CDV, as digital data, to the outside of the arithmetic circuit CDV.

The converter circuit RL3[k] can be the above-described arithmetic circuit of a function system. The arithmetic circuit of a function system can be, for example, an arithmetic circuit of a sigmoid function, a tanh function, a softmax function, a ReLU function, or a threshold function. The converter circuit RL3 may include a circuit performing pooling processing, instead of the arithmetic circuit of a function system. The converter circuit RL3[k] preferably outputs a voltage from the terminal R3To[k].

The converter circuit RL3[k] may be a current-voltage converter circuit.

In the case where the converter circuit RL3[k] is a current-voltage converter circuit, for example, the converter circuit RL3[k] preferably generates an analog voltage corresponding to a current input from the wiring WCL2[k] to the terminal R3Ti[k] of the converter circuit RL3[k] through the switch SB[k] and outputs the analog voltage to the terminal R3To[k] of the converter circuit RL3[k].

The analog-digital converter circuit ADC preferably converts an analog voltage supplied from the terminal R3To[k] of the converter circuit RL3[k] into a digital signal and outputs the digital signal to the wiring OL[k].

FIG. 11B illustrates a structure example of the circuit ITRZ in which the converter circuit RL3[k] is a current-voltage converter circuit. The converter circuit RL3[k] illustrated in FIG. 11B includes a load LE and an operational amplifier OP1, for example.

An inverting input terminal of the operational amplifier OP1 is electrically connected to a first terminal of the load LE and the second terminal of the switch SB[k]. A non-inverting input terminal of the operational amplifier OP1 is electrically connected to a wiring VRL. An output terminal of the operational amplifier OP1 is electrically connected to a second terminal of the load LE and the terminal R3To[k].

The wiring VRL functions as a wiring for supplying a constant potential. The constant potential can be the ground potential (GND), a low-level potential, or the like, for example.

In particular, by setting the constant potential supplied from the wiring VRL to the ground potential (GND), the inverting input terminal of the operational amplifier OP1 is virtually grounded, and the analog voltage output to the wiring OL[k] can be a voltage with reference to the ground potential (GND).

By having the structure in FIG. 11A, the circuit ITRZ can output a value corresponding to the amount of a current flowing from the wiring WCL2[k] to the terminal R3Ti[k] of the converter circuit RL3[k] through the switch SB[k], as an analog voltage, to the terminal R3To[k]. The analog voltage can be converted into a digital signal by the analog-digital converter circuit ADC, and the digital signal can be output to the wiring OL[k].

### <Arithmetic Operation in Arithmetic Cell Array MACA1>

Next, an example of an arithmetic operation of the arithmetic cell array MACA1 is described. Although an example of an arithmetic operation of the arithmetic cell array MACA1 is described below, a similar arithmetic operation can be performed also by the arithmetic cell array MACA2.

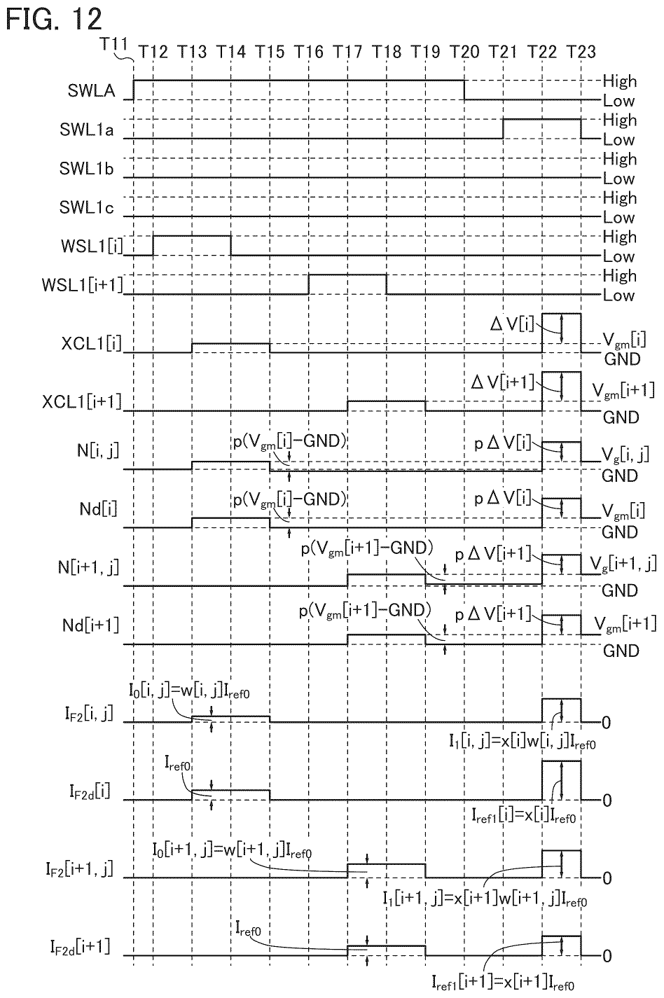

FIG. 12 is a timing chart showing an operation example of the arithmetic cell array MACA1, the circuit WCS, the circuit XCS1, and the switching circuit SWC1. The timing chart in FIG. 12 shows changes in the potentials of the wiring SWLA, the wiring SWL1a, the wiring SWL1b, the wiring SWL1c, the wiring WSL[i] (here, i is an integer greater than or equal to 1 and less than or equal to s−1), the wiring WSL1[i+1], the wiring XCL1[i], the wiring XCL1[i+1], the node N[i,j] (here, j is an integer greater than or equal to 1 and less than or equal to s−1), the node N[i+1,j], the node Nd[i], and the node Nd[i+1] in the period from Time T11 to Time T23 and the vicinity thereof. The timing chart in FIG. 12 also shows changes in an amount I_{F2}[i,j] of a current flowing between the first terminal and the second terminal of the transistor F2 included in the cell IM1[i,j]; an amount I_{F2d}[i] of a current flowing between the first terminal and the second terminal of the transistor F2d included in the cell IMD1[i]; an amount I_{F2}[i+1,j] of a current flowing between the first terminal and the second terminal of the transistor F2 included in the cell IM1[i+1,j]; and an amount I_{F2d}[i+1] of a current flowing between the first terminal and the second terminal of the transistor F2d included in the cell IMD1[i+1].

The circuit WCS in FIG. 5A is used as the circuit WCS, and the circuit XCS1 in FIG. 5C is used as the circuit XCS1.

Note that in this operation example, the potential of the wiring VE0 is the ground potential GND. Before Time T11, as an initial setting, the potential of each of the node N[i,j], the node N[i+1,j], the node Nd[i], and the node Nd[i+1] is the ground potential GND. Specifically, for example, the potential of each of the node N[i,j] and the node N[i+1,j] can be set to the ground potential GND when the initialization potential of the wiring VINIL1 in FIG. 5A is set to the ground potential GND and the switch SWW, the switch S3, and the transistors F1 included in the cell IM1[i,j] and the cell IM1[i+1,j] are turned on. For example, the potentials of the node Nd[i] and the node Nd[i+1] can be set to the ground potential GND when the initialization potential of the wiring VINIL2 in FIG. 5C is set to the ground potential GND and the switch SWX and the transistors F1d included in the cell IMD1[i] and the cell IMD1[i+1] are turned on.

In this operation example, the switch S5a[1] to the switch S5a[s] of the switching circuit SWC5 are always in an on state, and the switch S5b[1] to the switch S5b[s] are always in an off state. That is, a current from the circuit XCS1 flows to the wiring XCL1[1] to the wiring XCL1[s].

### [From Time T11 to Time T12]

In the period from Time T11 to Time T12, a high-level potential (shown as High in FIG. 12) is applied to the wiring SWLA, a low-level potential (shown as Low in FIG. 12) is applied to the wiring SWL1a, a low-level potential is applied to the wiring SWL1b, and a low-level potential is applied to the wiring SWL1c. Accordingly, in the circuit WCS, a high-level potential is applied to each of the control terminals of the switch SA[1] to the switch SA[s], whereby the switch SA[1] to the switch SA[s] are turned on. In the switching circuit SWC1, a low-level potential is applied to each of the control terminals of the switch S1a[1] to the switch S1a[s], the switch S1b[1] to the switch S1b[s], and the switch S1c[1] to the switch S1c[s], whereby the switch S1a[1] to the switch S1a[s], the switch S1b[1] to the switch S1b[s], and the switch S1c[1] to the switch S1c[s] are turned off.

In the period from Time T11 to Time T12, a low-level potential is applied to each of the wiring WSL1[i] and the wiring WSL1[i+1]. Accordingly, in the i-th row in the arithmetic cell array MACA1, a low-level potential is applied to each of the gates of the transistors F1 included in the cell IM1[i,1] to the cell IM1[i,s] and the gate of the transistor F1d included in the cell IMD1[i], so that the transistors F1 and the transistor F1d are turned off. In addition, in the i+1-th row in the arithmetic cell array MACA1, a low-level potential is applied to each of the gates of the transistors F1 included in the cell IM1[i+1,1] to the cell IM1[i+1,s] and the gate of the transistor F1d included in the cell IMD1[i+1], so that the transistors F1 and the transistor F1d are turned off.

In the period from Time T11 to Time T12, the ground potential GND is applied to the wiring XCL1[i] and the wiring XCL1[i+1]. Specifically, for example, when the wiring XCL1[k] illustrated in FIG. 5C is the wiring XCL1[i] and the wiring XCL1[i+1], the potentials of the wiring XCL1[i] and the wiring XCL1[i+1] can be set to the ground potential GND by setting the initialization potential of the wiring VINIL2 to the ground potential GND and turning on the switch SWX.

In the period from Time T11 to Time T12, the first data is not input to the wiring DW[1] to the wiring DW[M] in the circuit WCSa[1] to the circuit WCSa[s] in FIG. 5A, which are electrically connected to the wiring WCL1[1] to the wiring WCL1[s] through the respective switches SA. In that case, a low-level potential is input to each of the wiring DW[1] to the wiring DW[M] in the circuit WCSa[1] to the circuit WCSa[s] in FIG. 5A. In the period from Time T11 to Time T12, the second data is not input to the wiring DX[1] to the wiring DX[Z] in the circuit XCSa[1] to the circuit WCSa[s] in FIG. 5C, which are electrically connected to the wiring XCL1[1] to the wiring XCL1[s]. In that case, a low-level potential is input to each of the wiring DX[1] to the wiring DX[L] in the circuit XCSa[1] to the circuit WCSa[s] in FIG. 5C.

In the period from Time T11 to Time T12, no current flows through the wiring WCL1[j], the wiring XCL1[i], or the wiring XCL1[i+1]. Therefore, I_{F2}[i,j], I_{F2d}[i], I_{F2}[i+1,j], and I_{F2d}[i+1] are each 0.

### [From Time T12 to Time T13]

In the period from Time T12 to Time T13, a high-level potential is applied to the wiring WSL1[i]. Accordingly, in the i-th row in the arithmetic cell array MACA1, a high-level potential is applied to each of the gates of the transistors F1 included in the cell IM1[i, 1] to the cell IM1[i,s] and the gate of the transistor F1d included in the cell IMD1[i], so that the transistors F1 and the transistor F1d are turned on. Furthermore, in the period from Time T12 to Time T13, a low-level potential is applied to each of the wiring WSL1[1] to the wiring WSL1[s] other than the wiring WSL1[i], so that in the rows other than the i-th row of the arithmetic cell array MACA1, the transistors F1 included in the cell IM1[1,1] to the cell IM1[s,s] and the transistors F1d included in the cell IMD1[1] to the cell IMD1[s] are in an off state.

The ground potential GND has been applied to the wiring XCL1[1] to the wiring XCL1[s] since before Time T12.

### [From Time T13 to Time T14]

In the period from Time T13 to Time T14, a current with a current amount I₀[i,j] flows as the first data from the circuit WCSa[j] to the arithmetic cell array MACA1 through the switch SA[j]. Specifically, when the wiring WCL1[k] illustrated in FIG. 5A is the wiring WCL1[j], signals corresponding to the first data are input to the wiring DW[1] to the wiring DW[M], whereby a current I₀[i,j] flows from the circuit WCSa[j] to the second terminal of the switch SA[j]. That is, when the value of the M-bit signal input as the first data is α[i,j] (α[i,j] is an integer greater than or equal to 0 and less than or equal to 2^{K}−1), I₀[i,j]=α[i,j]×I_{Wut}.

Since I₀[i,j]=0 when α[i,j] is 0, no current flows from the circuit WCSa to the arithmetic cell array MACA1 through the switch SA[j] in a strict sense, but in this specification and the like, an expression such as “a current such that I₀[i,j]=0 flows” is sometimes used.

In the period from Time T13 to Time T14, a conduction state is established between the wiring WCL1[j] and the first terminal of the transistor F1 included in the cell IM1[i,j] in the i-th row of the arithmetic cell array MACA1, and a non-conduction state is established between the wiring WCL1[j] and the first terminals of the transistors F1 included in the cell IM1[1,j] to the cell IM1[s,j] in the rows other than the i-th row of the arithmetic cell array MACA1; accordingly, a current with a current amount I₀[i,j] flows from the wiring WCL1[j] to the cell IM1[i,j].

When the transistor F1 included in the cell IM1[i,j] is turned on, a conduction state is established between the gate and the drain of the transistor F2 included in the cell IM1[i,j] (diode-connected structure). Therefore, when a current flows from the wiring WCL1[j] to the cell IM1[i,j], the potentials of the gate of the transistor F2 and the second terminal of the transistor F2 are substantially equal to each other. The potentials are determined by the amount of a current flowing from the wiring WCL1[j] to the cell IM1[i,j], the potential of the first terminal of the transistor F2 (here, GND), and the like. In this operation example, a current with a current amount I₀[i,j] flows from the wiring WCL1[j] to the cell IM1[i,j], whereby the potential of the gate of the transistor F2 (the node N[i,j]) becomes V_{g}[i,j]. That is, the gate-source voltage of the transistor F2 is V_{g}[i,j]-GND, and a current amount I₀[i,j] is set as a current flowing between the first terminal and the second terminal of the transistor F2.

Here, a current amount I₀[i,j] of the case where the transistor F2 operates in the subthreshold region can be expressed by the following formula, where Vₜₕ[i,j] is the threshold voltage of the transistor F2.

$$\begin{matrix}[ Formula 1 ] & \\ {I}_{0} [ i , j ] = {I}_{a} exp \{ J ( {V}_{g} [ i , j ] - {V}_{t h} [ i , j ] ) \} & ( 1.1 )\end{matrix}$$

Note that Iₐ is a drain current for the case where V_{g}[i,j] is Vₜₕ[i,j], and J is a correction coefficient determined with the temperature, the device structure, and the like.

In the period from Time T13 to Time T14, a current with a current amount I_{ref0} flows as the reference data from the circuit XCS1 to the wiring XCL1[i]. Specifically, when the wiring XCL1[k] illustrated in FIG. 6C is the wiring XCL1[i], a high-level potential is input to the wiring DX[1] and a low-level potential is input to each of the wiring DX[2] to the wiring DX[L], so that a current I_{ref0} flows from the circuit XCSa[i] to the wiring XCL1[i]. In other words, I_{ref0}=I_{Xut}.

In the period from Time T13 to Time T14, since a conduction state is established between the first terminal of the transistor F1d included in the cell IMD1[i] and the wiring XCL1[i], a current with a current amount I_{ref0} flows from the wiring XCL1[i] to the cell IMD1[i].

As in the cell IM1[i,j], when the transistor F1d included in the cell IMD1[i] is turned on, a conduction state is established between the gate and the drain of the transistor F2d included in the cell IMD1[i] (diode-connected structure). Therefore, when a current flows from the wiring XCL1[i] to the cell IMD1[i], the potentials of the gate of the transistor F2d and the second terminal of the transistor F2d are substantially equal to each other. The potentials are determined by the amount of a current flowing from the wiring XCL1[i] to the cell IMD1[i], the potential of the first terminal of the transistor F2d (here, GND), and the like. In this operation example, a current with a current amount I_{ref0} flows from the wiring XCL1[i] to the cell IMD1[i], whereby the gate of the transistor F2d (the node Nd[i]) becomes V_{gm}[i]; at this time, the potential of the wiring XCL1[i] is also V_{gm}[i]. That is, the gate-source voltage of the transistor F2d is V_{gm}[i]-GND, and a current amount I_{ref0} is set as a current flowing between the first terminal and the second terminal of the transistor F2d.

Here, a current amount I_{ref0} of the case where the transistor F2d operates in the subthreshold region can be expressed by the following formula, where Vₜₕₘ[i] is the threshold voltage of the transistor F2d.

$$\begin{matrix}[ Formula 2 ] & \\ {I}_{ref 0} = {I}_{a} exp \{ J ( {V}_{g m} [ i ] - {V}_{thm} [ i ] ) \} & ( 1.2 )\end{matrix}$$

Note that the correction coefficient J is the same as that for the transistor F2 included in the cell IM1[i,j]. For example, the same device structure (including the channel length and the channel width) is used for the transistors. Furthermore, although variations in manufacturing cause variations in the correction coefficient J among the transistors, the variations are suppressed to the extent that the argument described later can be made with sufficient precision for practical purposes.

Here, a weight coefficient w[i,j] that is the first data is defined as follows.

$$\begin{matrix}[ Formula 3 ] & \\ w [ i , j ] = exp \{ J ( {V}_{g} [ i , j ] - {V}_{t h} [ i , j ] - {V}_{g m} [ i ] + {V}_{t h m} [ i ] ) \} & ( 1.3 )\end{matrix}$$

Therefore, Formula (1.1) can be rewritten into the following formula with use of Formula (1.3), Formula (1.4), I₀[i,j]=α[i,j]×I_{Wut}, and I_{ref0}=I_{Xut}.

$$\begin{matrix}[ Formula 4 ] & \\ {I}_{0} [ i , j ] = w [ i , j ] {I}_{ref 0} & ( 1.4 )\end{matrix}$$

$$↔ α [ i , j ] {I}_{Wut} = w [ i , j ] {I}_{Xut}$$

When a current I_{Wut} output from the current source CS of the circuit WCSa[j] in FIG. 5A is equal to a current I_{Xut} output from the current source CS of the circuit XCSa[i] in FIG. 5C, w[i,j]=α[i,j]. That is, when I_{Wut} is equal to I_{Xut}, α[i,j] corresponds to the value of the first data; thus, I_{Wut} and I_{Xut} are preferably equal to each other. Description of this operation example is made on the assumption that I_{Wut} is equal to I_{Xut}.

### [From Time T14 to Time T15]

In the period from Time T14 to Time T15, a low-level potential is applied to the wiring WSL1[i]. Accordingly, in the i-th row in the arithmetic cell array MACA1, a low-level potential is applied to each of the gates of the transistors F1 included in the cell IM1[i,1] to the cell IM1[i,s] and the gate of the transistor F1d included in the cell IMD1[i], so that the transistors F1 and the transistor F1d are turned off.

When the transistor F1 included in the cell IM1[i,j] is turned off, V_{g}[i,j]-V_{gm}[i], which is the difference between the potential of the gate of the transistor F2 (the node N[i,j]) and the potential of the wiring XCL1[i], is retained in the capacitor C5. When the transistor F1 included in the cell IMD1[i] is turned off, 0, which is the difference between the potential of the gate of the transistor F2d (the node Nd[i]) and the potential of the wiring XCL1[i], is retained in the capacitor C5d. In the operation from Time T13 to Time T14, the voltage retained in the capacitor C5d might be a voltage that is not 0 (e.g., V_{ds} here) depending on the transistor characteristics or the like of one or the other of the transistor F1d and the transistor F2d. In this case, the node Nd[i] can be regarded as having a potential obtained by adding V_{ds} to the potential of the wiring XCL1[i].

### [From Time T15 to Time T16]

In the period from Time T15 to Time T16, GND is applied to the wiring XCL1[i]. Specifically, for example, when the wiring XCL1[k] illustrated in FIG. 5C is the wiring XCL1[i], the potential of the wiring XCL1[i] can be set to the ground potential GND by setting the initialization potential of the wiring VINIL2 to the ground potential GND and turning on the switch SWX.

Thus, the potentials of the node N[i, 1] to the node N[i,n] change because of capacitive coupling of the capacitors C5 included in the cell IM1[i,1] to the cell IM1[i,s] in the i-th row in the arithmetic cell array MACA1, and the potential of the node Nd[i] changes because of capacitive coupling of the capacitor C5d included in the cell IMD1[i].

The amount of change in the potentials of the node N[i,1] to the node N[i,s] is a potential obtained by multiplying the amount of change in the potential of the wiring XCL1[i] by the capacitive coupling coefficient that is determined by the structures of the cell IM1[i, 1] to the cell IM1[i,s] included in the arithmetic cell array MACA1. The capacitive coupling coefficient is calculated using the capacitance of the capacitor C5, the gate capacitance of the transistor F2, the parasitic capacitance, and the like. When the capacitive coupling coefficient due to the capacitor C5 in each of the cell IM1[i, 1] to the cell IM1[i,s] is p, the potential of the node N[i,j] in the cell IM1[i,j] decreases by p(V_{gm}[i]-GND) from the potential in the period from Time T14 to Time T15.

Similarly, when the potential of the wiring XCL1[i] changes, the potential of the node Nd[i] also changes because of capacitive coupling of the capacitor C5d included in the cell IMD1[i]. In the case where the capacitive coupling coefficient due to the capacitor C5d is p like that due to the capacitor C5, the potential of the node Nd[i] in the cell IMD1[i] decreases by p(V_{gm}[i]-GND) from the potential in the period from Time T14 to Time T15.

In the timing chart in FIG. 12, p=1, for example. Thus, the potential of the node Nd[i] is GND in the period from Time T15 to Time T16.

Accordingly, the potential of the node N[i,j] in the cell IM1[i,j] decreases, so that the transistor F2 is turned off; similarly, the potential of the node Nd[i] in the cell IMD1[i] decreases, so that the transistor F2d is also turned off. Therefore, I_{F2}[i,j] and I_{F2d}[i] are each 0 in the period from Time T15 to Time T16.

### [From Time T16 to Time T17]

In the period from Time T16 to Time T17, a high-level potential is applied to the wiring WSL1[i+1]. Accordingly, in the i+1-th row of the arithmetic cell array MACA1, a high-level potential is applied to each of the gates of the transistors F1 included in the cell IM1[i+1,1] to the cell IM1[i+1,s] and the gate of the transistor F1d included in the cell IMD1[i+1], so that the transistors F1 and the transistor F1d are turned on. Furthermore, in the period from Time T16 to Time T17, a low-level potential is applied to each of the wiring WSL1[1] to the wiring WSL1[s] other than the wiring WSL1[i+1], so that in the rows other than the i+1-th row of the arithmetic cell array MACA1, the transistors F1 included in the cell IM1[1,1] to the cell IM1[s,s] and the transistors F1d included in the cell IMD1[1] to the cell IMD1[s] are in an off state.

The ground potential GND has been applied to the wiring XCL1[1] to the wiring XCL1[s] since before Time T16.

### [From Time T17 to Time T18]

In the period from Time T17 to Time T18, a current with a current amount I₀[i+1,j] flows as the first data from the circuit WCSa[j] to the arithmetic cell array MACA1 through the switch SA[j]. Specifically, when the wiring WCL1[k] illustrated in FIG. 5A is the wiring WCL1[j+1], signals corresponding to the first data are input to the wiring DW[1] to the wiring DW[M], whereby a current I₀[i+1,j] flows from the circuit WCSa[j] to the second terminal of the switch SA[j]. That is, when the value of the M-bit signal input as the first data is [i+1,j] (α[i+1,j] is an integer greater than or equal to 0 and less than or equal to 2^{K}−1), I₀[i+1,j]=α[i+1,j] x]I_{Wut}.

Since I₀[i+1,j]=0 when α[i+1,j] is 0, no current flows from the circuit WCSa[j] to the arithmetic cell array MACA1 through the switch SA[j] in a strict sense, but in this specification and the like, an expression such as “a current such that I₀[i+1,j]=0 flows” is sometimes used, as in the case of I₀[i,j]=0.

At this time, a conduction state is established between the wiring WCL1[j] and the first terminal of the transistor F1 included in the cell IM1[i+1,j] in the i+1-th row of the arithmetic cell array MACA1, and a non-conduction state is established between the wiring WCL1[j] and the first terminals of the transistors F1 included in the cell IM1[1,j] to the cell IM1[m,j] in the rows other than the i+1-th row of the arithmetic cell array MACA1; accordingly, a current with a current amount I₀[i+1,j] flows from the wiring WCL1[j] to the cell IM1[i+1,j].

When the transistor F1 included in the cell IM1[i+1,j] is turned on, a conduction state is established between the gate and the drain of the transistor F2 included in the cell IM1[i+1,j] (diode-connected structure). Therefore, when a current flows from the wiring WCL1[j] to the cell IM1[i+1,j], the potentials of the gate of the transistor F2 and the second terminal of the transistor F2 are substantially equal to each other. The potentials are determined by the amount of a current flowing from the wiring WCL1[j] to the cell IM1[i+1,j], the potential of the first terminal of the transistor F2 (here, GND), and the like. In this operation example, a current with a current amount I₀[i+1,j] flows from the wiring WCL1[j] to the cell IM1[i+1,j], whereby the potential of the gate of the transistor F2 (the node N[i+1,j]) becomes V_{g}[i+1,j]. That is, the gate-source voltage of the transistor F2 is V_{g}[i+1,j]-GND, and a current amount I₀[i+1,j] is set as a current flowing between the first terminal and the second terminal of the transistor F2.

Here, a current amount I₀[i+1,j] of the case where the transistor F2 operates in the subthreshold region can be expressed by the following formula, where Vₜₕ[i+1,j] is the threshold voltage of the transistor F2. Note that the correction coefficient is J, which is the same as those for the transistor F2 included in the cell IM1[i,j] and the transistor F2d included in the cell IMD1[i].

$$\begin{matrix}[ Formula 5 ] & \\ {I}_{0} [ i + 1 , j ] = {I}_{a} exp \{ J ( {V}_{g} [ i + 1 , j ] - {V}_{t h} [ i + 1 , j ] ) \} & ( 1.5 )\end{matrix}$$

In the period from Time T17 to Time T18, a current with a current amount I_{ref0} flows as the reference data from the circuit XCSa[i+1] to the wiring XCL1[i+1]. Specifically, as in the period from Time T13 to Time T14, when the wiring XCL1[k] illustrated in FIG. 5C is the wiring XCL1[i+1], a high-level potential is input to the wiring DX[1] and a low-level potential is input to each of the wiring DX[2] to the wiring DX[Z], so that a current I_{ref0}=I_{Xut} flows from the circuit XCSa[i+1] to the wiring XCL1[i+1].

In the period from Time T17 to Time T18, since a conduction state is established between the first terminal of the transistor F1d included in the cell IMD1[i+1] and the wiring XCL1[i+1], a current with a current amount I_{ref0} flows from the wiring XCL1[i+1] to the cell IMD1[i+1].

As in the cell IM1[i+1,j], when the transistor F1d included in the cell IMD1[i+1] is turned on, a conduction state is established between the gate and the drain of the transistor F2d included in the cell IMD1[i+1] (diode connection). Therefore, when a current flows from the wiring XCL1[i+1] to the cell IMD1[i+1], the potentials of the gate of the transistor F2d and the second terminal of the transistor F2d are substantially equal to each other. The potentials are determined by the amount of a current flowing from the wiring XCL1[i+1] to the cell IMD1[i+1], the potential of the first terminal of the transistor F2d (here, GND), and the like. In this operation example, a current with a current amount I_{ref0} flows from the wiring XCL1[i+1] to the cell IMD1[i+1], whereby the gate of the transistor F2 (the node Nd[i+1]) becomes V_{gm}[i+1]; at this time, the potential of the wiring XCL1[i+1] is also V_{gm}[i+1]. That is, the gate-source voltage of the transistor F2d is V_{gm}[i+1]-GND, and a current amount I_{ref0} is set as a current flowing between the first terminal and the second terminal of the transistor F2d.

Here, a current amount I_{ref0} of the case where the transistor F2d operates in the subthreshold region can be expressed by the following formula, where Vₜₕₘ[i+1,j] is the threshold voltage of the transistor F2d. Note that the correction coefficient J is the same as that for the transistor F2 included in the cell IM1[i+1,j].

$$\begin{matrix}[ Formula 6 ] & \\ {I}_{ref 0} = {I}_{a} exp \{ J ( {V}_{g m} [ i + 1 ] - {V}_{t h m} [ i + 1 ] ) \} & ( 1.6 )\end{matrix}$$

Here, a weight coefficient w[i+1,j] that is the first data is defined as follows.

$$\begin{matrix}[ Formula 7 ] & \\ w [ i + 1 , j ] = exp \{ J ( {V}_{g} [ i + 1 , j ] - {V}_{t h} [ i + 1 , j ] - {V}_{g m} [ i + 1 ] + {V}_{thm} [ i + 1 ] ) \} & ( 1.7 )\end{matrix}$$

Therefore, Formula (1.5) can be rewritten into the following formula with use of Formula (1.3), Formula (1.6), I₀ᵣ[i,j]=α[i,j]×I_{Wut}, and I_{ref0}=I_{Xut}.

$$\begin{matrix}[ Formula 8 ] & \\ {I}_{0} [ i + 1 , j ] = w [ i + 1 , j ] {I}_{ref 0} & ( 1.8 )\end{matrix}$$

$$↔ α [ i + 1 , j ] {I}_{Wut} = w [ i + 1 , j ] {I}_{Xut}$$

As described above, description of this operation example is made on the assumption that I_{Wut} is equal to I_{Xut}.

### [From Time T18 to Time T19]

In the period from Time T18 to Time T19, a low-level potential is applied to the wiring WSL1[i+1]. Accordingly, in the i+1-th row of the arithmetic cell array MACA1, a low-level potential is applied to each of the gates of the transistors F1 included in the cell IM1[i+1,1] to the cell IM[i+1,n] and the gate of the transistor F1d included in the cell IMD1[i+1], so that the transistors F1 and the transistor F1d are turned off.

When the transistor F1 included in the cell IM1[i+1,j] is turned off, V_{g}[i+1,j]-V_{gm}[i+1], which is the difference between the potential of the gate of the transistor F2 (the node N[i+1,j]) and the potential of the wiring XCL1[i+1], is retained in the capacitor C5. When the transistor F1 included in the cell IMD1[i+1] is turned off, 0, which is the difference between the potential of the gate of the transistor F2d (the node Nd[i+1]) and the potential of the wiring XCL1[i+1], is retained in the capacitor C5d. In the operation in the period from Time T18 to Time T19, the voltage retained in the capacitor C5d might be a voltage that is not 0 (e.g., V_{ds} here) depending on the transistor characteristics or the like of one or both of the transistor F1d and the transistor F2d. In this case, the node Nd[i+1] can be regarded as having a potential obtained by adding V_{ds} to the potential of the wiring XCL1[i+1].

### [From Time T19 to Time T20]

In the period from Time T19 to Time T20, the ground potential GND is applied to the wiring XCL1[i+1]. Specifically, for example, when the wiring XCL1[k] illustrated in FIG. 5C is the wiring XCL[i+1], the potential of the wiring XCL1[i+1] can be set to the ground potential GND by setting the initialization potential of the wiring VINIL2 to the ground potential GND and turning on the switch SWX.

Thus, the potentials of the node N[i,1] to the node N[i+1,s] change because of capacitive coupling of the capacitors C5 included in the cell IM1[i+1,1] to the cell IM1[i+1,n] in the i-th row in the arithmetic cell array MACA1, and the potential of the node Nd[i+1] changes because of capacitive coupling of the capacitor C5d included in the cell IMD1[i+1].

The amount of change in the potentials of the node N[i+1,1] to the node N[i+1,n] is a potential obtained by multiplying the amount of change in the potential of the wiring XCL1[i+1] by the capacitive coupling coefficient that is determined by the structures of the cell IM1[i+1,1] to the cell IM1[i+1,s] included in the arithmetic cell array MACA1. The capacitive coupling coefficient is calculated using the capacitance of the capacitor C5, the gate capacitance of the transistor F2, the parasitic capacitance, and the like. When the capacitive coupling coefficient due to the capacitor C5 in each of the cell IM1[i+1,1] to the cell IM1[i+1,s] is p, which is the same as the capacitive coupling coefficient due to the capacitor C5 in each of the cell IM1[i, 1] to the cell IM1[i,s], the potential of the node N[i+1,j] in the cell IM1[i+1,j] decreases by p(V_{gm}[i+1]-GND) from the potential in the period from Time T18 to Time T19.

Similarly, when the potential of the wiring XCL1[i+1] changes, the potential of the node Nd[i+1] also changes because of capacitive coupling of the capacitor C5d included in the cell IMD1[i+1]. In the case where the capacitive coupling coefficient due to the capacitor C5d is p like that due to the capacitor C5, the potential of the node Nd[i+1] in the cell IMD1[i+1] decreases by p(V_{gm}[i+1]-GND) from the potential in the period from Time T18 to Time T19.

In the timing chart in FIG. 12, p=1, for example. Thus, the potential of the node Nd[i+1] is GND in the period from Time T20 to Time T21.

Accordingly, the potential of the node N[i+1,j] in the cell IM1[i+1,j] decreases, so that the transistor F2 is turned off; similarly, the potential of the node Nd[i+1] in the cell IMD1[i+1] decreases, so that the transistor F2d is also turned off. Therefore, I_{F2}[i+1,j] and I_{F2d}[i+1] are each 0 in the period from Time T19 to Time T20.

### [From Time T20 to Time T21]

In the period from Time T20 to Time T21, a low-level potential is applied to the wiring SWLA. Accordingly, a low-level potential is applied to each of the control terminals of the switch SA[1] to the switch SA[s], whereby the switch SA[1] to the switch SA[s] are turned off.

### [From Time T21 to Time T22]

In the period from Time T21 to Time T22, a high-level potential is applied to the wiring SWL1a. Accordingly, a high-level potential is applied to each of the control terminals of the switch S1a[1] to the switch S1a[s] of the switching circuit SWC1, whereby the switch S1a[1] to the switch S1a[s] are turned on.

### [From Time T22 to Time T23]

In the period from Time T22 to Time T23, a current of x[i]I_{ref0}, i.e., x[i] times a current amount I_{ref0}, flows as the second data from the circuit XCS1 to the wiring XCL1[i]. Specifically, for example, when the wiring XCL1[k] illustrated in FIG. 5C is the wiring XCL1[i], a high-level potential or a low-level potential is input to each of the wiring DX[1] to the wiring DX[L] in accordance with the value of x[i], so that x[i]I_{ref0}=x[i]I_{Xut} flows as a current amount from the circuit XCSa[i] to the wiring XCL1[i]. In this operation example, x[i] corresponds to the value of the second data. At this time, the potential of the wiring XCL1[i] changes from 0 to V_{gm}[i]+ΔV[i].

When the potential of the wiring XCL1[i] changes, the potentials of the node N[i,1] to the node N[i,s] also change because of the capacitive coupling of the capacitors C5 included in the cell IM1[i,1] to the cell IM1[i,s] in the i-th row of the arithmetic cell array MACA1. Thus, the potential of the node N[i,j] in the cell IM1[i,j] becomes V_{g}[i,j]+pΔV[i].

Similarly, when the potential of the wiring XCL1[i] changes, the potential of the node Nd[i] also changes because of capacitive coupling of the capacitor C5d included in the cell IMD1[i]. Thus, the potential of the node Nd[i] in the cell IMD1[i] becomes V_{gm}[i]+pΔV[i].

Accordingly, an amount I₁[i,j] of a current flowing between the first terminal and the second terminal of the transistor F2 and an amount I_{ref1}[i,j] of a current flowing between the first terminal and the second terminal of the transistor F2d in the period from Time T22 to Time T23 can be expressed as follows.

$$\begin{matrix}[ Formula 9 ] & \\ \begin{matrix}{I}_{1} [ i , j ] = {I}_{a} exp \{ J ( {V}_{g} [ i , j ] + p Δ V [ i ] - {V}_{t h} [ i , j ] ) \} \\ = {I}_{0} [ i , j ] exp ( Jp Δ V [ i ] )\end{matrix} & ( 1.9 )\end{matrix}$$

$$\begin{matrix}[ Formula 10 ] & \\ \begin{matrix}{I}_{ref 1} [ i ] = {I}_{a} exp \{ J ( {V}_{g m} [ i ] + p Δ V [ i ] - {V}_{thm} [ i ] ) \} \\ = x [ i ] {I}_{ref 0}\end{matrix} & ( 1.1 )\end{matrix}$$

According to Formula (1.9) and Formula (1.10), x[i] can be expressed by the following formula.

$$\begin{matrix}[ Formula 11 ] & \\ x [ i ] = exp ( Jp Δ V [ i ] ) & ( 1.1 1 )\end{matrix}$$

Therefore, Formula (1.9) can be rewritten into the following formula.

$$\begin{matrix}[ Formula 12 ] & \\ {I}_{1} [ i , j ] = x [ i ] w [ i , j ] {I}_{ref 0} & ( 1.12 )\end{matrix}$$

That is, the amount of a current flowing between the first terminal and the second terminal of the transistor F2 included in the cell IM1[i,j] is proportional to the product of w[i,j] as the first data and x[i] as the second data.

In the period from Time T22 to Time T23, a current of x[i+1]I_{ref0}, i.e., x[i+1] times a current amount I_{ref0}, flows as the second data from the circuit XCS1 to the wiring XCL1[i+1]. Specifically, for example, when the wiring XCL1[k] illustrated in FIG. 5C is the wiring XCL1[i+1], a high-level potential or a low-level potential is input to each of the wiring DX[1] to the wiring DX[L] in accordance with the value of x[i+1], so that x[i+1]I_{ref}=x[i+1]Iₓᵤₜ flows as a current amount from the circuit XCSa[i+1] to the wiring XCL1[i+1]. In this operation example, x[i+1] corresponds to the value of the second data. At this time, the potential of the wiring XCL1[i+1] changes from 0 to V_{gm}[i+1]+ΔV[i+1].

When the potential of the wiring XCL1[i+1] changes, the potentials of the node N[i+1,1] to the node N[i+1,s] also change because of the capacitive coupling of the capacitors C5 included in the cell IM1[i+1,1] to the cell IM1[i+1,s] in the i+1-th row of the arithmetic cell array MACA1. Thus, the potential of the node N[i+1,j] in the cell IM1[i+1,j] becomes V_{g}[i+1,j]+pΔV[i+1].

Similarly, when the potential of the wiring XCL1[i+1] changes, the potential of the node Nd[i+1] also changes because of capacitive coupling of the capacitor C5d included in the cell IMD1[i+1]. Thus, the potential of the node Nd[i+1] in the cell IMD1[i+1] becomes V_{gm}[i+1]+pΔV[i+1].

Accordingly, an amount I₁[i+1,j] of a current flowing between the first terminal and the second terminal of the transistor F2 and an amount I_{ref1} [i+1,j] of a current flowing between the first terminal and the second terminal of the transistor F2d in the period from Time T22 to Time T23 can be expressed as follows.

$$\begin{matrix}[ Formula 13 ] & \\ \begin{matrix}{I}_{1} [ i + 1 , j ] = {I}_{a} exp \{ J ( {V}_{g} [ i + 1 , j ] + p Δ V [ i + 1 ] - {V}_{t h} [ i + 1 , j ] ) \} \\ = {I}_{0} [ i + 1 , j ] exp ( Jp Δ V [ i + 1 ] )\end{matrix} & ( 1.13 )\end{matrix}$$

$$\begin{matrix}[ Formula 14 ] & \\ \begin{matrix}{I}_{ref 1} [ i + 1 ] = {I}_{a} exp \{ J ( {V}_{g m} [ i + 1 ] + p Δ V [ i + 1 ] - {V}_{t h m} [ i + 1 ] ) \} \\ = x [ i + 1 ] {I}_{ref 0}\end{matrix} & ( 1.14 )\end{matrix}$$

According to Formula (1.13) and Formula (1.14), x[i+1] can be expressed by the following formula.

$$\begin{matrix}[ Formula 15 ] & \\ x [ i + 1 ] = exp ( Jp Δ V [ i + 1 ] ) & ( 1.15 )\end{matrix}$$

Therefore, Formula (1.13) can be rewritten into the following formula.

$$[ Formula 16 ]$$

$${I}_{1} [ i + 1 , j ] = x [ i + 1 ] w [ i + 1 , j ] {I}_{ref 0} \qquad ( 1.16 )$$

That is, the amount of a current flowing between the first terminal and the second terminal of the transistor F2 included in the cell IM1[i+1,j] is proportional to the product of w[i+1,j] that is the first data and x[i+1] that is the second data.

On another note, since the switch S1a[1] to the switch S1a[s] are in an on state and the switch S1b[1] to the switch S1b[s] are in an off state in the switching circuit SWC1 in the period from Time T22 to Time T23, a current I₁[i,j] (Formula (1.12)) flowing from the wiring WCL1[j] to the cell IM1[i,j] and a current I₁[i+1,j] (Formula (1.16)) flowing from the wiring WCL1[j] to the cell IM1[i+1,j] are supplied from the terminal C1Ti[j] (not shown) of the current generation circuit CM1 in FIG. 1. At this time, when the sum of the amounts of currents flowing from the terminal C1Ti[j] of the current generation circuit CM1 to the cell IM1[i,j] and the cell IM1[i+1,j] through the switching circuit SWC1 is I_{SUM}[j], I_{SUM}[j] can be expressed by the following formula according to Formula (1.12) and Formula (1.16).

$$[ Formula 17 ]$$

$$\begin{matrix}{I}_{SUM} [ j ] = {I}_{1} [ i , j ] + {I}_{1} [ i + 1 , j ] \\ = {I}_{ref 0} ( x [ i ] w [ i , j ] + x [ i + 1 ] w [ i + 1 , j ] )\end{matrix} \qquad ( 1.17 )$$

Thus, the current amount output from the terminal C1Ti[j] of the current generation circuit CM1 is proportional to the sum of products of w[i,j] and w[i+1,j], which are the first data, and x[i] and x[i+1], which are the second data.

Although in the above-described operation example, the sum of the amounts of currents flowing in the cell IM1[i,j] and the cell IM1[i+1,j] is described, the sum of the amounts of currents flowing in a plurality of cells, i.e., the cell IM1[1,j] to the cell IM1[s,j], may also be described. In that case, Formula (1.17) can be rewritten into the following formula.

$$[ Formula 18 ]$$

$${I}_{SUM} [ j ] = {I}_{ref 0} {\sum }_{i = 1}^{s} x [ i ] w [ i , j ] \qquad ( 1.18 )$$

Thus, even in the case of an arithmetic circuit MAC1 including the arithmetic cell array MACA1 having three or more rows and a plurality of columns, a product-sum operation can be performed in the above-described manner. In the arithmetic cell array MACA1 of this case, cells (the above-described cells IMD1) in one of a plurality of columns retain I_{ref0} and xI_{ref0} as current amounts, whereby product-sum processing, the number of which corresponds to the number of the rest of the columns among the plurality of columns, can be executed concurrently. That is, when the number of columns in a memory cell array is increased, a semiconductor device that achieves high-speed product-sum processing can be provided.

### Operation Method Example 1 of Arithmetic Circuit CDV

Next, an operation example of the arithmetic circuit CDV in FIG. 1 is described.

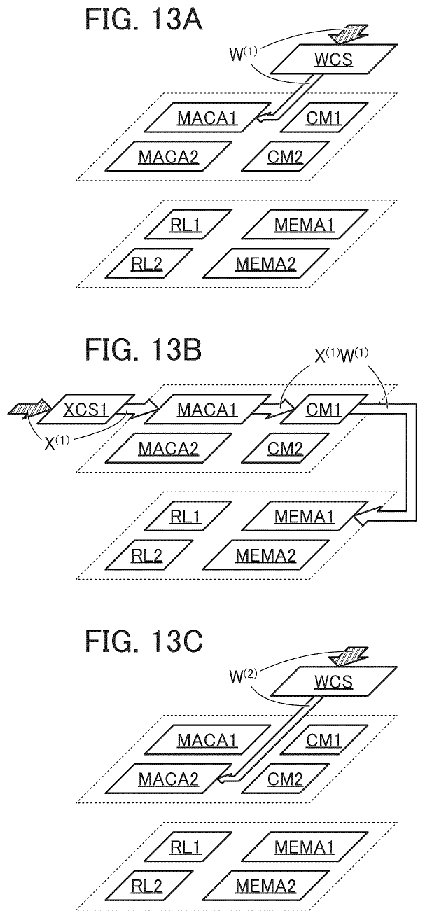

FIG. 13A to FIG. 15B are block diagrams illustrating an example of an operation method of the arithmetic circuit CDV in FIG. 1 by showing the flow of data input to the arithmetic circuit CDV, data output from the arithmetic circuit CDV, and data in the arithmetic circuit CDV. Note that in FIG. 13A to FIG. 15B, the arrows with hatching represent digital data, and the white arrows represent analog data.

FIG. 13A illustrates the following operation: W⁽¹⁾ as the first data, which is digital data, is input to the circuit WCS from the outside of the arithmetic circuit CDV, W⁽¹⁾ as the first data is converted into analog data (current) by the circuit WCS, and W⁽¹⁾ as the first data that is converted into the analog data (current) is written to the arithmetic cell array MACA1. Since the first data is written to each of the cell IM1[1,1] to the cell IM1[s,s] of the arithmetic cell array MACA1, W⁽¹⁾ as the first data can be used as a matrix of s rows and s columns (which will be described later in detail). W⁽¹⁾ as the first data is one of a multiplier and a multiplicand that are used in the first product-sum operation.

FIG. 13B illustrates the following operation: X⁽¹⁾ as the second data, which is digital data, is input to the circuit XCS1 from the outside of the arithmetic circuit CDV, X⁽¹⁾ as the second data is converted into analog data (current) by the circuit XCS1, and X⁽¹⁾ as the second data that is converted into the analog data (current) is input to the arithmetic cell array MACA1. Here, X⁽¹⁾ as the second data is a matrix (a matrix of s rows and s columns) including s sets of the second data, where one set includes s pieces of the second data (which will be described later in detail). Thus, the first set to the s-th set of the second data, where one set includes s pieces of the second data, are sequentially input from the circuit XCS1 to the arithmetic cell array MACA1 through the wiring XCL1[1] to the wiring XCL1[s]. X⁽¹⁾ as the second data is the other of a multiplier and a multiplicand that are used in the second product-sum operation.

FIG. 13B also illustrates the following operation: the arithmetic cell array MACA1 outputs X⁽¹⁾W⁽¹⁾, which is the result of the initial product-sum operation of W⁽¹⁾ as the first data written to the arithmetic cell array MACA1 at the stage of FIG. 13A and X⁽¹⁾ as the input second data, and X⁽¹⁾W⁽¹⁾ is written to the memory cell array MEMA1. Note that X⁽¹⁾W⁽¹⁾ is a matrix of s rows and s columns.

FIG. 13C illustrates the following operation: W⁽²⁾ as the first data, which is digital data, is input to the circuit WCS from the outside of the arithmetic circuit CDV, W⁽²⁾ as the first data is converted into analog data (current) by the circuit WCS, and W⁽²⁾ as the first data that is converted into the analog data (current) is written to the arithmetic cell array MACA2. Note that W⁽²⁾ as the first data is a matrix of s rows and s columns like W⁽¹⁾.

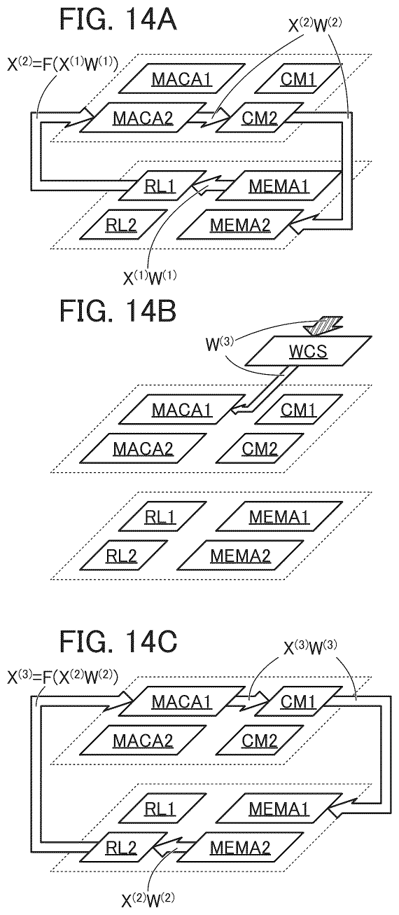

FIG. 14A illustrates the following operation: the memory cell array MEMA1 outputs X⁽¹⁾W⁽¹⁾ written at the stage of FIG. 13B, and the current generation circuit RL1 obtains X⁽¹⁾W⁽¹⁾ and outputs F(X⁽¹⁾W⁽¹⁾). Note that F(x) is a function for an arithmetic operation performed in the current generation circuit RL1, and specifically, F(X⁽¹⁾W⁽¹⁾)=X⁽²⁾ is defined. X⁽²⁾ is used as the second data for performing the second product-sum operation. Furthermore, X⁽²⁾ is transmitted to the arithmetic cell array MACA2.

FIG. 14A also illustrates the following operation: X⁽²⁾ W⁽²⁾, which is the result of the second product-sum operation of W⁽²⁾ as the first data written to the arithmetic cell array MACA2 at the stage of FIG. 13C and X⁽²⁾ input to the arithmetic cell array MACA2, is output, and X⁽²⁾ W⁽²⁾ is written to the memory cell array MEMA2. Note that X⁽²⁾W⁽²⁾ is a matrix of s rows and s columns like X⁽¹⁾W⁽¹⁾.

FIG. 14B illustrates the following operation: W⁽³⁾ as the first data, which is digital data, is input to the circuit WCS from the outside of the arithmetic circuit CDV, W⁽³⁾ as the first data is converted into analog data (current) by the circuit WCS, and W⁽³⁾ as the first data that is converted into the analog data (current) is written to the arithmetic cell array MACA1. Note that W⁽³⁾ as the first data is a matrix of s rows and s columns like W⁽¹⁾ and W⁽²⁾.

FIG. 14C illustrates the following operation: the memory cell array MEMA2 outputs X⁽²⁾W⁽²⁾ written at the stage of FIG. 14A, and the current generation circuit RL2 obtains X⁽²⁾W⁽²⁾ and outputs F(X⁽²⁾ W⁽²⁾). Note that the current generation circuit RL2 also performs an arithmetic operation of a function F(x) like the current generation circuit RL1. In addition, F(X⁽²⁾W⁽²⁾)=X⁽³⁾ is defined, and X⁽³⁾ is used as the second data for performing the third product-sum operation. Furthermore, X⁽³⁾ is transmitted to the arithmetic cell array MACA1.

FIG. 14C also illustrates the following operation: X⁽³⁾W⁽³⁾, which is the result of the third product-sum operation of W⁽³⁾ as the first data written to the arithmetic cell array MACA1 at the stage of FIG. 14B and X⁽³⁾ input to the arithmetic cell array MACA1, is output, and X⁽³⁾W⁽³⁾ is written to the memory cell array MEMA2. Note that X⁽³⁾ W⁽³⁾ is also a matrix of s rows and s columns like X⁽¹⁾W⁽¹⁾ and X⁽²⁾W⁽²⁾.

By repeating the operations in FIG. 13C to FIG. 14C thereafter, the product-sum operation and the arithmetic operation of a function system can be successively performed a plurality of times.

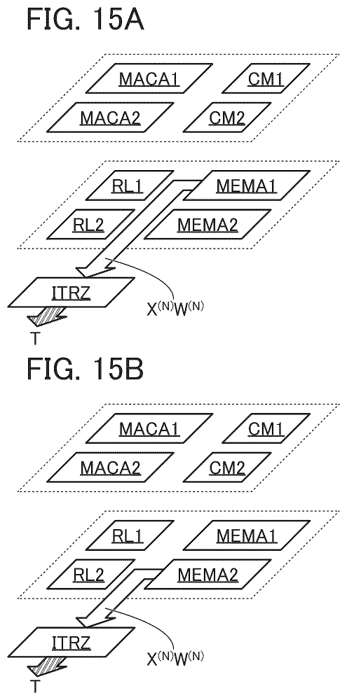

FIG. 15A and FIG. 15B show operations of the case where the last product-sum operation is performed. Note that in the case where the last product-sum operation is performed in the arithmetic cell array MACA1, the operation in FIG. 15A is performed; in the case where the last product-sum operation is performed in the arithmetic cell array MACA2, the operation in FIG. 15B is performed.

First, description of FIG. 15A is made. At the stage of FIG. 15A, X^{(N)}W^{(N)} (here, N is an odd number), which is the result of performing the last product-sum operation in the arithmetic cell array MACA1, is retained in the memory cell array MEMA1. In FIG. 15A, the memory cell array MEMA1 outputs X^{(N)}W^{(N)}, and the circuit ITRZ obtains X^{(N)}W^{(N)} and outputs T, which is data output from the arithmetic circuit CDV. Note that the circuit ITRZ also performs an arithmetic operation of a function F(x) like the current generation circuit RL1 and the current generation circuit RL2. Thus, T=F(X^{(N)}W^{(N)} can be described.

Next, description of FIG. 15B is made. At the stage of FIG. 15B, X^{(N)}W^{(N)} (here, N is an even number), which is the result of performing the last product-sum operation in the arithmetic cell array MACA2, is retained in the memory cell array MEMA2. In FIG. 15B, the memory cell array MEMA2 outputs X^{(N)}W^{(N)}, and the circuit ITRZ obtains X^{(N)} W^{(N)} and outputs T, which is data output from the arithmetic circuit CDV. Note that for T, the description of FIG. 15A is to be referred to.

The operation method of the arithmetic circuit CDV is described above with reference to FIG. 13A to FIG. 15B. Hereinafter, detailed operations of the circuits included in the arithmetic circuit CDV in FIG. 13A to FIG. 15B are described below.

### Operation Method Example 2 of Arithmetic Circuit CDV

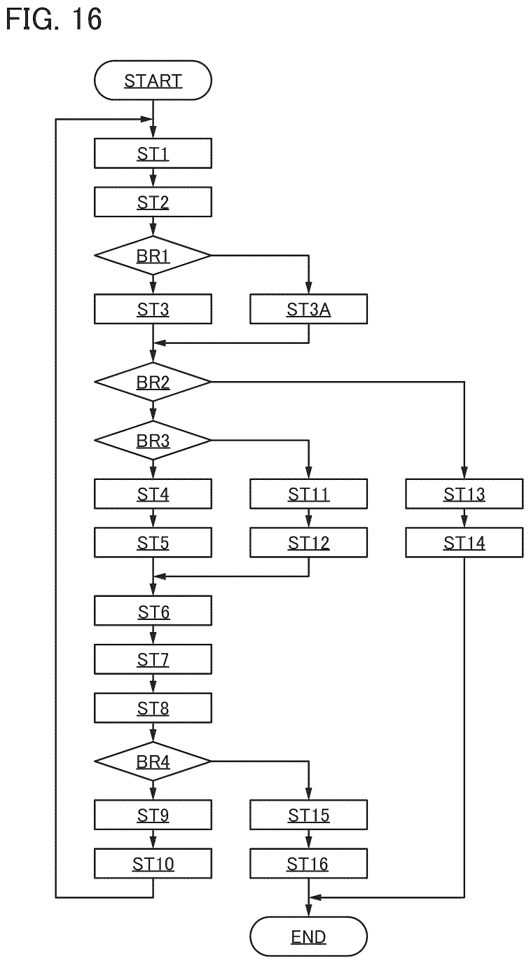

FIG. 16 is a flowchart showing an example of an operation method of the arithmetic circuit CDV in FIG. 1. As shown in FIG. 16, the operation method of the arithmetic circuit CDV in FIG. 1 includes Step ST1 to Step ST16, Step ST3A, and Step BR1 to Step BR4.

### [Step ST1]

To perform the N-th product-sum operation (Nin Step ST1 is an odd number greater than or equal to 1), Step ST1 includes a prior operation for writing a plurality of pieces of the first data to the arithmetic cell array MACA1. Note that in the case where Step ST1 is performed for the first time, N is 1. In the case where Step ST1 is performed for the second time, N is 3.

Step ST1 includes, for example, an operation in which the switching circuit SWC1 establishes a non-conduction state between the terminal T1a[k] and the terminal T1b[k] and a non-conduction state between the terminal T1a[k] and the terminal T1c[k].

Specifically, in the switching circuit SWC1 in FIG. 7A, the switch S1a[k] is turned off by supplying a low-level potential from the wiring SWL1a to the control terminal of the switch S1a[k], and the switch S1b[k] is turned off by supplying a low-level potential from the wiring SWL1b to the control terminal of the switch S1b[k]. Note that this operation corresponds to the operation of the switching circuit SWC1 from Time T11 to Time T12 in the timing chart in FIG. 12.

Step ST1 includes, for example, an operation in which the switching circuit SWC5 establishes a conduction state between the terminal T5a[k] and the terminal T5b[k] and a non-conduction state between the terminal T5b[k] and the terminal T5c[k].

Specifically, in the switching circuit SWC5 in FIG. 8A, the switch S5a[k] is turned on by supplying a high-level potential from the wiring SWL5a to the control terminal of the switch S5a[k], and the switch S5b[k] is turned off by supplying a low-level potential from the wiring SWL5b to the control terminal of the switch S5b[k].

Step ST1 includes, for example, an operation of establishing a conduction state between the circuit WCSa[k] and the wiring WCL1[k] in the circuit WCS.

Specifically, in the circuit SWCA in FIG. 2, the switch SA[k] is turned on by supplying a high-level potential from the wiring SWLA to the control terminal of the switch SA[k].

In the above manner, preparation for writing a plurality of pieces of the first data to the arithmetic cell array MACA1 is completed.

### [Step ST2]

To perform the N-th product-sum operation (N=1 in the case where Step ST2 is performed for the first time), Step ST2 includes an operation of writing a plurality of pieces of the first data to the arithmetic cell array MACA1.

For example, the first data is written to each of the cells IM1[1,1] to IM1[s,s] of the arithmetic cell array MACA1, with reference to the above description of the period from Time T11 to Time T20 in the timing chart of FIG. 12. Note that the first data written to the cell IM1[i,j] of the arithmetic cell array MACA1 is referred to as W^{(N)}[i,j]. Note that N in W^{(N)} [i,j] represents what number product-sum operation the product-sum operation is, and for example, W⁽¹⁾[i,j] means the first data used when the first product-sum operation is performed.

At this time, the first data written to the arithmetic cell array MACA1 is referred to as W⁽¹⁾ as a matrix. W^{(N)} can be expressed as follows.

$$[ Formula 19 ]$$

$${W}^{( N )} = ( \begin{matrix}{W}^{( N )} [ 1 , 1 ] & … & {W}^{( N ) [ 1 , s ]} \\ ⋮ & ⋱ & ⋮ \\ {W}^{( N )} [ s , 1 ] & … & {W}^{( N )} [ s , s ]\end{matrix} ) \qquad ( 1.19 )$$

Note that the operations performed in Step ST1 and Step ST2 correspond to the operations in the block diagram in FIG. 13A when N=1. When N is other than 1, the operations performed in Step ST1 and Step ST2 correspond to FIG. 14B.

### [Step BR1]

In Step BR1, whether N is 1 or not is determined in the operation of the arithmetic circuit CDV. The operation of the arithmetic circuit CDV proceeds to Step ST3 when N is 1, and the operation of the arithmetic circuit CDV proceeds to Step ST3A when N is not 1.

### [Step ST3]

Step ST3 includes a prior operation for inputting a plurality of pieces of the second data to the arithmetic cell array MACA1 in the case where the first product-sum operation is performed (in the case where N is 1).

Step ST3 includes, for example, an operation in which the switching circuit SWC5 establishes a conduction state between the terminal T5a[k] and the terminal T5b[k] and a non-conduction state between the terminal T5b[k] and the terminal T5c[k].

Specifically, in the switching circuit SWC5 in FIG. 8A, the switch S5a[k] is turned on by supplying a high-level potential from the wiring SWL5a to the control terminal of the switch S5a[k], and the switch S5b[k] is turned off by supplying a low-level potential from the wiring SWL5b to the control terminal of the switch S5b[k].

### [Step ST3A]

Step ST3A includes a prior operation for inputting a plurality of pieces of the second data to the arithmetic cell array MACA1 in the case where the N-th product-sum operation is performed (here, N is an odd number greater than or equal to 3).

Step ST3A includes, for example, an operation in which the switching circuit SWC5 establishes a non-conduction state between the terminal T5a[k] and the terminal T5b[k] and a conduction state between the terminal T5b[k] and the terminal T5c[k].

Specifically, in the switching circuit SWC5 in FIG. 8A, the switch S5a[k] is turned off by supplying a low-level potential from the wiring SWL5a to the control terminal of the switch S5a[k], and the switch S5b[k] is turned on by supplying a high-level potential from the wiring SWL5b to the control terminal of the switch S5b[k].

### [Step BR2]

In Step BR2, whether or not the process is terminated with the N-th product-sum operation (N is 1 in the case where Step BR2 is performed for the first time) is determined in the operation of the arithmetic circuit CDV. In the case where the process is not terminated with the N-th product-sum operation, the operation of the arithmetic circuit CDV proceeds to Step ST4; in the case where the process is terminated with the N-th product-sum operation, the operation of the arithmetic circuit CDV proceeds to Step ST13.

### [Step BR3]

In Step BR3, whether N is 1 or not is determined in the operation of the arithmetic circuit CDV. Note that in the case where Step BR3 is performed for the first time, N is 1. The operation of the arithmetic circuit CDV proceeds to Step ST4 when N is 1, and the operation of the arithmetic circuit CDV proceeds to Step ST11 when N is not 1.

### [Step ST4]

Step ST4 includes a prior operation for performing the first product-sum operation.

Step ST4 includes, for example, an operation in which the switching circuit SWC1 establishes a conduction state between the terminal T1a[k] and the terminal T1b[k] and a non-conduction state between the terminal T1a[k] and the terminal T1c[k].

Specifically, in the switching circuit SWC1 in FIG. 7A, the switch S1a[k] is turned on by supplying a high-level potential from the wiring SWL1a to the control terminal of the switch S1a[k], and the switch S1b[k] is turned off by supplying a low-level potential from the wiring SWL1b to the control terminal of the switch S1b[k]. Note that this operation corresponds to the operation of the switching circuit SWC1 from Time T21 to Time T22 in the timing chart in FIG. 12.

Step ST4 includes, for example, an operation in which the switching circuit SWC2 establishes a conduction state between the terminal T2a[k] and the terminal T2b[k] and a non-conduction state between the terminal T2b[k] and the terminal T2c[k].

Specifically, in the switching circuit SWC2 in FIG. 7B, the switch S2a[k] is turned on by supplying a high-level potential from the wiring SWL2a to the control terminal of the switch S2a[k], and the switch S2b[k] is turned off by supplying a low-level potential from the wiring SWL2b to the control terminal of the switch S2b[k].

Step ST4 includes, for example, an operation of establishing a non-conduction state between the circuit WCSa[k] and the wiring WCL1[k] in the circuit WCS.

Specifically, in the circuit SWCA in FIG. 2, the switch SA[k] is turned off by supplying a low-level potential from the wiring SWLA to the control terminal of the switch SA[k].

In the above manner, preparation for performing the first product-sum operation in the arithmetic cell array MACA1 is completed.

### [Step ST5]

Step ST5 includes an operation of performing the first product-sum operation in the arithmetic cell array MACA1. Note that a product-sum operation of W⁽¹⁾ as the first data and X⁽¹⁾ as the second data is performed here. Note that X⁽¹⁾ will be described later.

In Step ST5, the second data is transmitted to each of the cell IMD1[1] to the cell IMD1[s] and the cells IM1[1,1] to IM1[s,s] of the arithmetic cell array MACA1, with reference to the above description of the period from Time T22 to Time T23 in the timing chart of FIG. 12.

Note that in Step ST5, the circuit XCS1 sequentially generates currents corresponding to the first set to the s-th set of the second data, and transmits the sets of the second data to the cell IMD1[1] to the cell IMD1[s] and the cells IM1[1,1] to IM1[s,s] of the arithmetic cell array MACA1.

For example, the circuit XCS1 generates currents with amounts of X⁽¹⁾₍₁₎[1]×I_{Xut} to X⁽¹⁾₍₁₎[s]×I_{Xut} as the first set of the second data and transmits the currents to the arithmetic cell array MACA1. Note that N in X^{(N)}₍ₕ₎[i] represents what number product-sum operation the product-sum operation is, and X⁽¹⁾₍ₕ₎[i] means the second data used when the first product-sum operation is performed. Furthermore, h in X^{(N)}₍ₕ₎[i] means that the second data is included in the h-th set (h is an integer greater than or equal to 1 and less than or equal to s). Furthermore, i in X^{(N)}₍ₕ₎[i] means that the second data is transmitted to the i-th row of the arithmetic cell array MACA1, i.e., the wiring XCL1[i], and X^{(N)}₍ₕ₎[1] is the second data transmitted to the wiring XCL1[1].

For example, the circuit XCS1 generates currents with amounts of X⁽¹⁾₍ₛ₎ [1]×I_{Xut} to X⁽¹⁾₍ₛ₎ [s]×I_{Xut} as the s-th set of the second data and transmits the currents to the arithmetic cell array MACA1.

Here, the second data input to the arithmetic cell array MACA1 in Step ST5 is referred to as X⁽¹⁾ as a matrix. Note that X⁽¹⁾₍ₕ₎[i] included in the h-th set and input to the i-th row of the arithmetic cell array MACA1 refers to the h-th row and the i-th column of X⁽¹⁾. In this case, X⁽¹⁾ can be expressed by the following formula.

$$[ Formula 20 ]$$

$${X}^{( 1 )} = ( \begin{matrix}{X}_{( 1 )}^{( 1 )} [ 1 ] & … & {X}_{( 1 )}^{( 1 )} [ s ] \\ ⋮ & ⋱ & ⋮ \\ {X}_{( s )}^{( 1 )} [ 1 ] & … & {X}_{( s )}^{( 1 )} [ s ]\end{matrix} ) \qquad ( 1.2 )$$

Here, the case where the h-th set of the second data is input to the arithmetic cell array MACA1 is considered. At this time, the amount of a current flowing from the terminal C1Ti[j] of the current generation circuit CM1 to the wiring WCL1[j] extending in the arithmetic cell array MACA1 is I_{SUM}⁽¹⁾₍ₕ₎[j]. Note that N in I_{SUM}^{(N)}₍ₕ₎[j] represents what number product-sum operation the product-sum operation is, and I_{SUM}⁽¹⁾₍ₕ₎[j] means the current amount corresponding to the arithmetic operation result obtained by the first product-sum operation. Furthermore, h in I_{SUM}⁽¹⁾₍ₕ₎[j] means that the second data included in the h-th set is used.

In Step ST5, the switch S1a[j] of the switching circuit SWC1 is in an on state and the switch S1b[j] of the switching circuit SWC1 is in an off state; thus, a current of I_{SUM}⁽¹⁾₍ₕ₎[j] to the cell IM1[1,j] to the cell IM1[s,j] in the j-th column of the arithmetic cell array MACA1 flows from the terminal C1Ti[j] of the current generation circuit CM1 through the wiring WCL1[j].

In this case, the amounts of currents flowing from the terminal C1Ti[1] to the terminal C1Ti[s] of the current generation circuit CM1 to the wiring WCL1[1] to the wiring WCL1[s] extending in the arithmetic cell array MACA1 can be expressed by the following formula using (Formula 1.17).

$$[ Formula 21 ]$$

$$( {I}_{{SUM}_{( h )}^{( 1 )}} [ 1 ] … {I}_{{SUM}_{( h )}^{( 1 )}} [ s ] ) = {I}_{ref 0} ( {\sum }_{i = 1}^{s} {X}_{( h )}^{( 1 )} [ i ] \times {W}^{( 1 )} [ i , 1 ] … {\sum }_{i = 1}^{s} {X}_{( h )}^{( 1 )} [ i ] \times {W}^{( 1 )} [ i , s ] ) \qquad ( 1.21 )$$

Furthermore, a current of I_{SUM}⁽¹⁾₍ₕ₎[j] is output from the terminal C1Ti[j] of the current generation circuit CM1, and thus, a current of I_{SUM}⁽¹⁾₍ₕ₎[j] is also output from the terminal C1To[j] of the current generation circuit CM1.

In Step ST5, the switch S2a[j] of the switching circuit SWC2 is in an on state and the switch S2b[j] of the switching circuit SWC2 is in an off state; thus, a current of I_{SUM}⁽¹⁾₍ₕ₎[j] from the terminal C1To[j] of the current generation circuit CM1 flows to the wiring BL1[j] in the j-th column of the memory cell array MEMA1.

Here, the wiring WWL1[h] and the wiring RWL1[h] in the memory cell array MEMA1 in FIG. 1 and FIG. 4A are supplied with high-level potentials from the circuit WWD1 and the circuit RWD1, respectively. Accordingly, in the h-th row in the memory cell array MEMA1, a high-level potential is applied to each of the gates of the transistors F7 and the transistors F9 included in the cell MC1[h,1] to the cell MC1[h,s], so that the transistors F7 and the transistors F9 are turned on. At this time, a low-level potential is supplied from the circuit WWD1 to each of the wiring WWL1[1] to the wiring WWL1[s] other than the wiring WWL1[h], and a low-level potential is supplied from the circuit RWD1 to each of the wiring RWL1[1] to the wiring RWL1[s] other than the wiring RWL1[h]. Thus, the transistors F7 and the transistors F9 included in the cell MC1[1,1] to the cell MC1[s,s] in the rows other than the h-th row of the memory cell array MEMA1 are in an off state.

At this time, a conduction state is established between the wiring BL1[j] and the first terminal of the transistor F8 included in the cell MC1[h,j] in the h-th row of the memory cell array MEMA1, and a non-conduction state is established between the wiring BL1[j] and the first terminals of the transistors F8 included in the cell MC1[1,j] to the cell MC1[s,j] in the rows other than the h-th row of the memory cell array MEMA1; accordingly, a current with a current amount I_{SUM}⁽¹⁾₍ₕ₎[j] flows from the wiring BL1[j] to the cell MC1[h,j].

When the transistor F7 included in the cell MC1[h,j] is turned on, a conduction state is established between the gate and the drain of the transistor F8 included in the cell MC1[h,j] (diode-connected structure). Therefore, when a current flows from the wiring BL1[j] to the cell MC1[h,j], the potentials of the gate of the transistor F8 and the second terminal of the transistor F8 are substantially equal to each other. The potentials are determined by the amount of a current flowing from the wiring BL1[j] to the cell MC1[h,j], the potential of the first terminal of the transistor F8, and the like. The potentials are supplied from the wiring VE2 and are the ground potential GND, for example, in this operation example. In this operation example, a current with a current amount I_{SUM}⁽¹⁾₍ₕ₎[j] flows from the wiring BL1[j] to the cell MC1[h,j], whereby the potential of the gate of the transistor F8 becomes V_{MEM}[h,j], for example. That is, the gate-source voltage of the transistor F8 is V_{MEM}[h,j]-GND, and a current amount I_{SUM}⁽¹⁾₍ₕ₎[j] is set as a current flowing between the first terminal and the second terminal of the transistor F8.

Next, the wiring WWL1[h] and the wiring RWL1[h] in the memory cell array MEMA1 in FIG. 1 and FIG. 4A are supplied with low-level potentials from the circuit WWD1 and the circuit RWD1, respectively. Accordingly, in the h-th row in the memory cell array MEMA1, a low-level potential is applied to each of the gates of the transistors F7 and the transistors F9 included in the cell MC1[h,1] to the cell MC1[h,s], so that the transistors F7 and the transistors F9 are turned off.

When the transistor F7 included in the cell MC1[h,j] is turned off, V_{MEM}[h,j]-GND, which is the difference between the potential of the gate of the transistor F8 and the potential of the wiring VE3 (here, the ground potential GND, for example), is retained in the capacitor C6. Accordingly, I_{SUM}⁽¹⁾₍ₕ₎[j], which is the amount of a current flowing between the source and the drain of the transistor F8 in the cell MC1[h,j], can be maintained. When the transistor F9 included in the cell MC1[h,j] is turned off, a current with a current amount I_{SUM}⁽¹⁾₍ₕ₎[j] set in the cell MC1[h,j] does not flow from the wiring BL1[j] to the cell MC1[h,j].

As described above, a current amount I_{SUM}⁽¹⁾₍ₕ₎[j] corresponding to the value of the result of a product-sum operation of W⁽¹⁾[1,j] to W⁽¹⁾[s,j] in the j-th column in W⁽¹⁾ as the first data and X⁽¹⁾₍ₕ₎[1] to X⁽¹⁾₍ₕ₎[s] as the h-th set of the second data is set in MC1[h,j] of the memory cell array MEMA1.

Specifically, for example, a current amount I_{SUM}⁽¹⁾₍ₕ₎[j] corresponding to the value of the result of a product-sum operation of W⁽¹⁾[1,j] to W⁽¹⁾[s,j] in the first column in W⁽¹⁾ as the first data and X⁽¹⁾₍ₕ₎[1] to X⁽¹⁾₍ₕ₎[s] as the first set of the second data is set in the cell MC1[1,1] of the memory cell array MEMA1. For another example, a current amount I_{SUM}⁽¹⁾₍ₛ₎ [s] corresponding to the value of the result of a product-sum operation of W⁽¹⁾[1,s] to W⁽¹⁾[s,s] in the s-th column in W⁽¹⁾ as the first data and X⁽¹⁾₍ₛ₎ [1] to X⁽¹⁾₍ₛ₎[s] as the s-th set of the second data is set in MC1[s,s] of the memory cell array MEMA1.

In the arithmetic cell array MACA1, the first set to the s-th set of the second data from the circuit XCS1 are sequentially input, and every time the second data is input from the circuit XCS1, the arithmetic operation result is written sequentially from the first row of the memory cell array MEMA1, whereby current amounts are set in the cell MC1[1,1] to the cell MC1[s,s] of the memory cell array MEMA1; these current amounts are referred to as I_{SUM}⁽¹⁾ as a matrix. A current amount I_{SUM}⁽¹⁾₍ₕ₎[j] corresponding to the value of the result of a product-sum operation of W⁽¹⁾[1,j] to W⁽¹⁾[s,j] in the j-th column in W⁽¹⁾ as the first data and X⁽¹⁾₍ₕ₎[1] to X⁽¹⁾₍ₕ₎[s] as the h-th set of the second data refers to the h-th row and the j-th column of I_{SUM}⁽¹⁾. In this case, I_{SUM}⁽¹⁾ can be expressed by the following formula.

$$[ Formula 22 ]$$

$${I}_{SUM}^{( 1 )} = ( \begin{matrix}{I}_{SUM ( 1 )}^{( 1 )} [ 1 ] & … & {I}_{SUM ( 1 )}^{( 1 )} [ s ] \\ ⋮ & ⋱ & ⋮ \\ {I}_{SUM ( s )}^{( 1 )} [ 1 ] & … & {I}_{SUM ( s )}^{( 1 )} [ s ]\end{matrix} ) \qquad ( 1.22 )$$

By Step ST5, the first product-sum operation is completed. Note that when the process proceeds from Step ST5 to Step ST6, the second product-sum operation is performed from Step ST6.

Note that the operations performed in Step ST3 to Step ST5 correspond to the operations in the block diagram in FIG. 13B. Here, I_{SUM}⁽¹⁾ corresponds to X⁽¹⁾W⁽¹⁾.

### [Step ST6]

To perform the N+1-th product-sum operation (N+1 in Step ST6 is an even number greater than or equal to 2), Step ST6 includes a prior operation for writing a plurality of pieces of the first data to the arithmetic cell array MACA2. Note that in the case where Step ST6 is performed for the first time, N+1 is 2.

Step ST6 includes, for example, an operation in which the switching circuit SWC1 establishes a non-conduction state between the terminal T1a[k] and the terminal T1b[k], a conduction state between the terminal T1a[k] and the terminal T1c[k], and a non-conduction state between the terminal T1c[k] and the terminal T1d[k].

Specifically, in the switching circuit SWC1 in FIG. 7A, the switch S1a[k] is turned off by supplying a low-level potential from the wiring SWL1a to the control terminal of the switch S1a[k], the switch S1b[k] is turned on by supplying a high-level potential from the wiring SWL1b to the control terminal of the switch S1b[k], and the switch S1c[k] is turned off by supplying a low-level potential from the wiring SWL1c to the control terminal of the switch S1c[k].

Step ST6 includes, for example, an operation in which the switching circuit SWC6 establishes a conduction state between the terminal T6a[k] and the terminal T6b[k] and a non-conduction state between the terminal T6b[k] and the terminal T6c[k].

Specifically, in the switching circuit SWC6 in FIG. 8B, the switch S6a[k] is turned on by supplying a high-level potential from the wiring SWL6a to the control terminal of the switch S6a[k], and the switch S6b[k] is turned off by supplying a low-level potential from the wiring SWL6b to the control terminal of the switch S6b[k].

Step ST6 includes, for example, an operation of establishing a conduction state between the circuit WCSa[k] and the wiring WCL1[k] in the circuit WCS.

Specifically, in the circuit SWCA in FIG. 2, the switch SA[k] is turned on by supplying a high-level potential from the wiring SWLA to the control terminal of the switch SA[k].

Step ST6 includes, for example, an operation of establishing a non-conduction state between the circuit ITRZa[k] and the wiring WCL2[k] in the circuit ITRZ.

Specifically, in the circuit SWCB in FIG. 11, the switch SB[k] is turned off by supplying a low-level potential from the wiring SWLB to the control terminal of the switch SB[k].

That is, by the above operation, a conduction state is established between the circuit WCSa[k] in the circuit WCS, the wiring WCL1[k], and the wiring WCL2[k]. Thus, preparation for writing a plurality of pieces of the first data to the arithmetic cell array MACA2 is completed.

### [Step ST7]

To perform the N+1-th product-sum operation (N+1=2 in the case where Step ST7 is performed for the first time), Step ST7 includes an operation of writing a plurality of pieces of the first data to the arithmetic cell array MACA2.

For example, the first data is written to each of the cells IM2[1,1] to IM2[s,s] of the arithmetic cell array MACA2, with reference to the above description of the period from Time T11 to Time T20 in the timing chart of FIG. 12. Note that the first data written to the cell IM2[i,j] of the arithmetic cell array MACA2 is referred to as W^{(N+1)} [i,j].

At this time, the first data written to the arithmetic cell array MACA2 is referred to as W^{(N+1)} as a matrix. W^{(N+1)} can be expressed as follows.

$$[ Formula 23 ]$$

$${W}^{( N + 1 )} = ( \begin{matrix}{W}^{( N + 1 )} [ 1 , 1 ] & … & {W}^{( N + 1 )} [ 1 , s ] \\ ⋮ & ⋱ & ⋮ \\ {W}^{( N + 1 )} [ s , 1 ] & … & {W}^{( N + 1 )} [ s , s ]\end{matrix} ) \qquad ( 1.23 )$$

Note that the operations performed in Step ST6 and Step ST7 correspond to the operations in the block diagram in FIG. 13C when N=2.

### [Step ST8]

Step ST8 includes a prior operation for inputting a plurality of pieces of the second data to the arithmetic cell array MACA2 in the case of performing the N+1-th product-sum operation (N+1=2 in the case where Step ST8 is performed for the first time).

Step ST8 includes, for example, an operation in which the switching circuit SWC6 establishes a non-conduction state between the terminal T6a[k] and the terminal T6b[k] and a conduction state between the terminal T6b[k] and the terminal T6c[k].

Specifically, in the switching circuit SWC6 in FIG. 8B, the switch S6a[k] is turned off by supplying a low-level potential from the wiring SWL6a to the control terminal of the switch S6a[k], and the switch S6b[k] is turned on by supplying a high-level potential from the wiring SWL6b to the control terminal of the switch S6b[k].

### [Step BR4]

In Step BR4, whether or not the process is terminated with the N+1-th product-sum operation (N+1=2 in the case where Step BR4 is performed for the first time) is determined in the operation of the arithmetic circuit CDV. In the case where the process is not terminated with the N+1-th product-sum operation, the operation of the arithmetic circuit CDV proceeds to Step ST9; in the case where the process is terminated with the N+1-th product-sum operation, the operation of the arithmetic circuit CDV proceeds to Step ST15.

### [Step ST9]

Step ST9 includes a prior operation for performing the N+1-th product-sum operation (N+1=2 in the case where Step ST7 is performed for the first time).

Step ST9 includes, for example, an operation in which the switching circuit SWC1 establishes a non-conduction state between the terminal T1a[k] and the terminal T1c[k] and a conduction state between the terminal T1c[k] and the terminal T1d[k].

Specifically, in the switching circuit SWC1 in FIG. 7A, the switch S1b[k] is turned off by supplying a low-level potential from the wiring SWL1b to the control terminal of the switch S1b[k], and the switch S1c[k] is turned on by supplying a high-level potential from the wiring SWL1c to the control terminal of the switch S1c[k].

Step ST9 includes, for example, an operation in which the switching circuit SWC2 establishes a non-conduction state between the terminal T2a[k] and the terminal T2b[k] and a conduction state between the terminal T2b[k] and the terminal T2c[k].

Specifically, in the switching circuit SWC2 in FIG. 7B, the switch S2a[k] is turned off by supplying a low-level potential from the wiring SWL2a to the control terminal of the switch S2a[k], and the switch S2b[k] is turned on by supplying a high-level potential from the wiring SWL2b to the control terminal of the switch S2b[k].

Step ST9 includes, for example, an operation in which the switching circuit SWC3 establishes a conduction state between the terminal T3a[k] and the terminal T3b[k] and a non-conduction state between the terminal T3b[k] and the terminal T3c[k].

Specifically, in the switching circuit SWC3 in FIG. 7C, the switch S3a[k] is turned on by supplying a high-level potential from the wiring SWL3a to the control terminal of the switch S3a[k], and the switch S3b[k] is turned off by supplying a low-level potential from the wiring SWL3b to the control terminal of the switch S3b[k].

Step ST9 includes, for example, an operation of establishing a non-conduction state between the circuit ITRZa[k] and the wiring WCL2[k] in the circuit ITRZ.

Specifically, in the circuit SWCB in FIG. 11, the switch SB[k] is turned off by supplying a low-level potential from the wiring SWLB to the control terminal of the switch SB[k].

In the above manner, preparation for performing the N+1-th product-sum operation in the arithmetic cell array MACA2 is completed.

### [Step ST10]

Step ST10 includes an operation of performing the N+1-th product-sum operation of a plurality of pieces of the first data and a plurality of pieces of the second data in the arithmetic cell array MACA2. Note that in the case where Step ST10 is performed for the first time, the N+1-th=the second time. A product-sum operation of W^{(N+1)} as the first data and X^{(N+1)} as the second data is performed here. Note that X^{(N+1)} will be described later.

In Step ST10, the results of the first product-sum operations in the first row to the s-th row are sequentially read from the memory cell array MEMA1.

Here, the case where the results of the first arithmetic operations are read from the cell MC1[h,1] to the cell MC1[h,s] in the h-th row of the memory cell array MEMA1 is considered. Specifically, the wiring RWL1[h] in the memory cell array MEMA1 is supplied with a high-level potential from the circuit RWD1, for example. Accordingly, in the h-th row in the memory cell array MEMA1, a high-level potential is applied to each of the gates of the transistors F9 included in the cell MC1[h,1] to the cell MC1[h,s], so that the transistors F9 are turned on. At this time, a low-level potential is supplied from the circuit RWD1 to each of the wiring RWL1[1] to the wiring RWL1[s] other than the wiring RWL1[h]. Thus, the transistors F9 included in the cell MC1[1,1] to the cell MC1[s,s] in the rows other than the h-th row of the memory cell array MEMA1 are in an off state.

At this time, a conduction state is established between the wiring BL1[j] and the first terminal of the transistor F8 included in the cell MC1[h,j] in the h-th row of the memory cell array MEMA1, and a non-conduction state is established between the wiring BL1[j] and the first terminals of the transistors F8 included in the cell MC1[1,j] to the cell MC1[s,j] in the rows other than the h-th row of the memory cell array MEMA1. Furthermore, a conduction state is established between the terminal R1Ti[j] of the current generation circuit RL1 and the wiring BL1[j] by the switching circuit SWC2; thus, a current with a current amount I_{SUM}^{(N)}₍ₕ₎[j] flows from the terminal R1Ti[j] of the current generation circuit RL1 to the cell MC1[h,j] through the wiring BL1[j].

The current generation circuit RL1 performs an arithmetic operation of a function system with the use of a value corresponding to a current amount I_{SUM}^{(N)}₍ₕ₎[j] input to the terminal R1Ti[j] as an input value and outputs a current with an amount corresponding to the result of the arithmetic operation to the terminal R1To[j]. Here, when a function is F(x) (x is an input value) and the input value is I_{SUM}^{(N)}₍ₕ₎[j], the result of the arithmetic operation of the function is defined as F(I_{SUM}^{(N)}₍ₕ₎[j])=X^{(N+1)}₍ₕ₎[j]×I_{Xut}. That is, in the current generation circuit RL1, when a current with a current amount I_{SUM}^{(N)}₍ₕ₎[j] is input to the terminal R1Ti[j], a current amount X^{(N+1)}₍ₕ₎[j]×I_{Xut} is output from the terminal R1To[j]. Furthermore, X^{(N+1)}₍ₕ₎[j] is the second data in the N+1-th product-sum operation.

Here, the second data output from the terminal R1To[1] to the terminal R1To[s] of the current generation circuit RL1 is referred to as X^{(N+1)} as a matrix. Note that when a current with a current amount I_{SUM}^{(N)}₍ₕ₎[j] flows from the terminal R1Ti[j] of the current generation circuit RL1 to the cell MC1[h,j] in the h-th row of the memory cell array MEMA1, X^{(N+1)}₍ₕ₎[j] as the second data output from the terminal R1To[j] refers to the h-th row and the j-th column of X^{(N+1)}.

$$[ Formula 24 ]$$

$${X}^{( N + 1 )} = ( \begin{matrix}{X}_{( 1 )}^{( N + 1 )} [ 1 ] & … & {X}_{( 1 )}^{( N + 1 )} [ s ] \\ ⋮ & ⋱ & ⋮ \\ {X}_{( s )}^{( N + 1 )} [ 1 ] & … & {X}_{( s )}^{( N + 1 )} [ s ]\end{matrix} ) \qquad ( 1.24 )$$

Note that X^{(N+1)}₍ₕ₎[1] to X^{(N+1)}₍ₕ₎[s] of the h-th row of X^{(N+1)} are the h-th set of the second data in the N+1-th arithmetic circuit.

Since a conduction state is established between the terminal R1To[i] in the current generation circuit RL1 and the wiring XCL2[i] by the switching circuit SWC6, a current with a current amount I_{SUM}^{(N+1)}₍ₕ₎[i] flows from the terminal R1To[i] in the current generation circuit RL1 to the cell IMD2[i] and the cell IM2[i, 1] to the cell IM2[i,s] through the wiring XCL2[i].

Here, the results of the N-th product-sum operations in the first row to the s-th row are read row by row from the memory cell array MEMA1, so that currents corresponding to the first set to the s-th set of the second data are sequentially output from the terminal R1To[1] to the terminal R1To[s] of the current generation circuit RL1. Accordingly, sequentially from the first row to the s-th row of the memory cell array MEMA1, one set of the second data set in each row is transmitted to the cell IMD2[1] to the cell IMD2[s] and the cells IM2[1,1] to IM2[s,s] of the arithmetic cell array MACA2.

Specifically, for example, the current generation circuit RL1 outputs currents with amounts of X^{(N+1)}₍₁₎[1]×I_{Xut} to X^{(N+1)}₍₁₎ [s]×I_{Xut} as the first set of the second data to the arithmetic cell array MACA1. For example, the current generation circuit RL1 outputs currents with amounts of X^{(N+1)}₍ₛ₎ [1]×I_{Xut} to X^{(N+1)}₍ₛ₎ [s]×I_{Xut} as the s-th set of the second data to the arithmetic cell array MACA1.

Note that for the product-sum operation in the arithmetic cell array MACA2, the description of Time T22 to Time T23 in the timing chart in FIG. 12 or the description of Step ST5 is to be referred to as appropriate.

Here, the case where the h-th set of the second data is input to the arithmetic cell array MACA1 is considered. At this time, the amount of a current flowing from the terminal C2Ti[j] of the current generation circuit CM2 to the wiring WCL2[j] extending in the arithmetic cell array MACA2 is I_{SUM}^{(N+1)}₍ₕ₎[j].

In Step ST10, the switch S1b[j] of the switching circuit SWC1 is in an off state and the switch S1c[j] of the switching circuit SWC1 is in an on state; thus, a current of I_{SUM}^{(N+1)}₍ₕ₎[j] to the cell IM2[1,j] to the cell IM2[s,j] in the j-th column of the arithmetic cell array MACA2 flows from the terminal C2Ti[j] of the current generation circuit CM2 through the wiring WCL2[j].

In this case, the amounts of currents flowing from the terminal C2Ti[1] to the terminal C2Ti[s] of the current generation circuit CM2 to the wiring WCL2[1] to the wiring WCL2[s] extending in the arithmetic cell array MACA2 can be expressed by the following formula using (Formula 1.17).

$$[ Formula 25 ]$$

$$( {I}_{{SUM}_{( h )}^{( N + 1 )}} [ 1 ] … {I}_{{SUM}_{( h )}^{( N + 1 )}} [ s ] ) = {I}_{ref 0} ( {\sum }_{i = 1}^{s} {X}_{( h )}^{( N + 1 )} [ i ] \times {W}^{( N + 1 )} [ i , 1 ] … {\sum }_{i = 1}^{s} {X}_{( h )}^{( N + 1 )} [ i ] \times {W}^{( N + 1 )} [ i , s ] ) \qquad ( 1.25 )$$

Furthermore, a current of I_{SUM}^{(N+1)}₍ₕ₎[j] is output from the terminal C2Ti[j] of the current generation circuit CM2, and thus, a current of I_{SUM}^{(N+1)}₍ₕ₎[j] is also output from the terminal C2To[j] of the current generation circuit CM2.

In Step ST10, the switch S2a[j] of the switching circuit SWC2 is in an on state and the switch S2b[j] of the switching circuit SWC2 is in an off state; thus, a current of I_{SUM}^{(N+1)}₍ₕ₎[j] from the terminal C2To[j] of the current generation circuit CM2 flows to the wiring BL2[j] in the j-th column of the memory cell array MEMA2.

Here, the wiring WWL2[h] and the wiring RWL2[h] in the memory cell array MEMA2 in FIG. 1 and FIG. 4B are supplied with high-level potentials from the circuit WWD2 and the circuit RWD2, respectively. Accordingly, in the h-th row in the memory cell array MEMA2, a high-level potential is applied to each of the gates of the transistors F7 and the transistors F9 included in the cell MC2[h,1] to the cell MC2[h,s], so that the transistors F7 and the transistors F9 are turned on. At this time, a low-level potential is supplied from the circuit WWD2 to each of the wiring WWL2[1] to the wiring WWL2[s] other than the wiring WWL2[h], and a low-level potential is supplied from the circuit RWD2 to each of the wiring RWL2[1] to the wiring RWL2[s] other than the wiring RWL2[h]. Thus, the transistors F7 and the transistors F9 included in the cell MC2[1,1] to the cell MC2[s,s] in the rows other than the h-th row of the memory cell array MEMA2 are in an off state.

At this time, a conduction state is established between the wiring BL2[j] and the first terminal of the transistor F8 included in the cell MC1[h,j] in the h-th row of the memory cell array MEMA2, and a non-conduction state is established between the wiring BL2[j] and the first terminals of the transistors F8 included in the cell MC2[1,j] to the cell MC2[s,j] in the rows other than the h-th row of the memory cell array MEMA2; accordingly, a current with a current amount I_{SUM}⁽²⁾₍ₕ₎[j] flows from the wiring BL2[j] to the cell MC2[h,j].

When the transistor F7 included in the cell MC2[h,j] is turned on, a conduction state is established between the gate and the drain of the transistor F8 included in the cell MC2[h,j] (diode connection). Therefore, when a current flows from the wiring BL2[j] to the cell MC2[h,j], the potentials of the gate of the transistor F8 and the second terminal of the transistor F8 are substantially equal to each other. The potentials are determined by the amount of a current flowing from the wiring BL2[j] to the cell MC2[h,j], the potential of the first terminal of the transistor F8, and the like. The potentials are supplied from the wiring VE2 and are the ground potential GND, for example, in this operation example. In this operation example, a current with a current amount I_{SUM}^{(N+1)}₍ₕ₎[j] flows from the wiring BL2[j] to the cell MC2[h,j], whereby the potential of the gate of the transistor F8 becomes V_{MEM}[h,j], for example. That is, the gate-source voltage of the transistor F8 is V_{MEM}[h,j]-GND, and a current amount I_{SUM}^{(N+1)}₍ₕ₎[j] is set as a current flowing between the first terminal and the second terminal of the transistor F8.

Next, the wiring WWL2[h] and the wiring RWL2[h] in the memory cell array MEMA2 in FIG. 1 and FIG. 4A are supplied with low-level potentials from the circuit WWD2 and the circuit RWD2, respectively. Accordingly, in the h-th row in the memory cell array MEMA2, a low-level potential is applied to each of the gates of the transistors F7 and the transistors F9 included in the cell MC2[h,1] to the cell MC2[h,s], so that the transistors F7 and the transistors F9 are turned off.

When the transistor F7 included in the cell MC2[h,j] is turned off, V_{MEM}[h,j]-GND, which is the difference between the potential of the gate of the transistor F8 and the potential of the wiring VE3 (here, the ground potential GND, for example), is retained in the capacitor C6. Accordingly, I_{SUM}^{(N+1)}₍ₕ₎[j], which is the amount of a current flowing between the source and the drain of the transistor F8 in the cell MC2[h,j], can be maintained. When the transistor F9 included in the cell MC2[h,j] is turned off, a current with a current amount I_{SUM}^{(N+1)}₍ₕ₎[j] set in the cell MC2[h,j] does not flow from the wiring BL2[j] to the cell MC2[h,j].

As described above, a current amount I_{SUM}^{(N+1)}₍ₕ₎[j] corresponding to the value of the result of a product-sum operation of W^{(N+1)} [1,j] to W^{(N+1)} [s,j] in the j-th column in W^{(N+1)} as the first data and X^{(N+1)}₍ₕ₎[1] to X^{(N+1)}₍ₕ₎[s] as the h-th set of the second data is set in MC2[h,j] of the memory cell array MEMA2.

Specifically, for example, a current amount I_{SUM}^{(N+1)}₍₁₎ [1] corresponding to the value of the result of a product-sum operation of W^{(N+1)} [1,1] to W^{(N+1)} [s,1] in the first column in W^{(N+1)} as the first data and X^{(N+1)}₍₁₎ [1] to X^{(N+1)}₍₁₎ [s] as the first set of the second data is set in the cell MC2[1,1] of the memory cell array MEMA2. For another example, a current amount I_{SUM}^{(N+1)}₍ₛ₎ [s] corresponding to the value of the result of a product-sum operation of W^{(N+1)} [1,s] to W^{(N+1)} [s,s] in the s-th column in W^{(N+1)} as the first data and X^{(N+1)}₍ₛ₎ [1] to X^{(N+1)}₍ₛ₎ [s] as the s-th set of the second data is set in MC2[s,s] of the memory cell array MEMA2.

In the arithmetic cell array MACA2, the first set to the s-th set of the second data from the memory cell array MEMA1 are sequentially input, and every time the second data is input from the circuit XCS1, the arithmetic operation result is written sequentially from the first row of the memory cell array MEMA2, whereby current amounts are set in the cell MC2[1,1] to the cell MC2[1,1] of the memory cell array MEMA2; these current amounts are referred to as I_{SUM}^{(N+1)} as a matrix. A current amount I_{SUM}^{(N+1)}₍ₕ₎[j] corresponding to the value of the result of a product-sum operation of W^{(N+1)} [1,j] to W^{(N+1)} [s,j] in the j-th column in W^{(N+1)} as the first data and X^{(N+1)}₍ₕ₎[1] to X^{(N+1)}₍ₕ₎[s] as the h-th set of the second data refers to the h-th row and the j-th column of I_{SUM}^{(N+1)}. In this case, I_{SUM}^{(N+1)} can be expressed by the following formula.

$$[ Formula 26 ]$$

$${I}_{SUM}^{( N + 1 )} = ( \begin{matrix}{I}_{SUM ( 1 )}^{( N + 1 )} [ 1 ] & … & {I}_{SUM ( 1 )}^{( N + 1 )} [ s ] \\ ⋮ & ⋱ & ⋮ \\ {I}_{SUM ( s )}^{( N + 1 )} [ 1 ] & … & {I}_{SUM ( s )}^{( N + 1 )} [ s ]\end{matrix} ) \qquad ( 1.26 )$$

By Step ST10, the N+1-th product-sum operation is completed. After Step ST10 is completed, the value of N is increased by two and the process proceeds to Step ST1. For example, when N=1 in Step ST10 (when the N+1-th=the second product-sum operation is performed in Step ST10), N=3 in the next Step ST1.

Note that the operations performed in Step ST8 to Step ST10 correspond to the operations in the block diagram in FIG. 14A when N=2. Here, I_{SUM}⁽²⁾ corresponds to X⁽²⁾ W⁽²⁾.

### [Step ST11]

Step ST11 includes a prior operation for performing the N-th product-sum operation (N is an odd number greater than or equal to 3 in Step ST11). Note that in the case where Step ST11 is performed for the first time, N is 3.

Step ST11 includes, for example, an operation in which the switching circuit SWC1 establishes a conduction state between the terminal T1a[k] and the terminal T1b[k] and a non-conduction state between the terminal T1a[k] and the terminal T1b[k].

Specifically, in the switching circuit SWC1 in FIG. 7A, the switch S1a[k] is turned on by supplying a high-level potential from the wiring SWL1a to the control terminal of the switch S1a[k], and the switch S1b[k] is turned off by supplying a low-level potential from the wiring SWL1b to the control terminal of the switch S1b[k]. Note that this operation corresponds to the operation of the switching circuit SWC1 from Time T21 to Time T22 in the timing chart in FIG. 12.

Step ST11 includes, for example, an operation in which the switching circuit SWC2 establishes a conduction state between the terminal T2a[k] and the terminal T2b[k] and a non-conduction state between the terminal T2b[k] and the terminal T2c[k].

Specifically, in the switching circuit SWC2 in FIG. 7B, the switch S2a[k] is turned on by supplying a high-level potential from the wiring SWL2a to the control terminal of the switch S2a[k], and the switch S2b[k] is turned off by supplying a low-level potential from the wiring SWL2b to the control terminal of the switch S2b[k].

Step ST11 includes, for example, an operation in which the switching circuit SWC3 establishes a non-conduction state between the terminal T3a[k] and the terminal T3b[k] and a conduction state between the terminal T3b[k] and the terminal T3c[k].

Specifically, in the switching circuit SWC3 in FIG. 7C, the switch S3a[k] is turned off by supplying a low-level potential from the wiring SWL3a to the control terminal of the switch S3a[k], and the switch S3b[k] is turned on by supplying a high-level potential from the wiring SWL3b to the control terminal of the switch S3b[k].

Step ST11 includes, for example, an operation of establishing a non-conduction state between the circuit WCSa[k] and the wiring WCL1[k] in the circuit WCS.

Specifically, in the circuit SWCA in FIG. 2, the switch SA[k] is turned off by supplying a low-level potential from the wiring SWLA to the control terminal of the switch SA[k].

In the above manner, preparation for performing the N-th product-sum operation of a plurality of pieces of the first data and a plurality of pieces of the second data in the arithmetic cell array MACA1 is completed.

### [Step ST12]

Step ST12 includes an operation of performing the N-th product-sum operation (in Step ST12, N is an odd number greater than or equal to 3) in the arithmetic cell array MACA1. A product-sum operation of W^{(N)} as the first data and X^{(N)} as the second data is performed here. Note that X^{(N)} will be described later.

In Step ST12, the results of the N−1-th product-sum operations in the first row to the s-th row are sequentially read from the memory cell array MEMA2.

Here, the case where the results of the N−1-th arithmetic operations are read from the cell MC2[h,1] to the cell MC2[h,s] in the h-th row of the memory cell array MEMA2 is considered. Specifically, the wiring RWL2[h] in the memory cell array MEMA2 is supplied with a high-level potential from the circuit RWD2, for example. Accordingly, in the h-th row in the memory cell array MEMA2, a high-level potential is applied to each of the gates of the transistors F9 included in the cell MC2[h,1] to the cell MC2[h,s], so that the transistors F9 are turned on. At this time, a low-level potential is supplied from the circuit RWD2 to each of the wiring RWL2[1] to the wiring RWL2[s] other than the wiring RWL2[h]. Thus, the transistors F9 included in the cell MC2[1,1] to the cell MC2[s,s] in the rows other than the h-th row of the memory cell array MEMA2 are in an off state.

At this time, a conduction state is established between the wiring BL2[j] and the first terminal of the transistor F8 included in the cell MC2[h,j] in the h-th row of the memory cell array MEMA2, and a non-conduction state is established between the wiring BL2[j] and the first terminals of the transistors F8 included in the cell MC2[1,j] to the cell MC2[s,j] in the rows other than the h-th row of the memory cell array MEMA2. Furthermore, a conduction state is established between the terminal R2Ti[j] of the current generation circuit RL2 and the wiring BL2[j] by the switching circuit SWC3; thus, a current with a current amount I_{SUM}^{(N-1)}₍ₕ₎[j] flows from the terminal R2Ti[j] of the current generation circuit RL2 to the cell MC1[h,j] through the wiring BL2[j].

Like the current generation circuit RL1, the current generation circuit RL2 performs an arithmetic operation of a function system with the use of a value corresponding to a current amount I_{SUM}^{(N-1)}₍ₕ₎[j] input to the terminal R2Ti[j] as an input value and outputs a current with an amount corresponding to the result of the arithmetic operation to the terminal R2To[j]. Here, when a function is F(x) (x is an input value) and the input value is I_{SUM}^{(N-1)}₍ₕ₎[j], the result of the arithmetic operation of the function is defined as F(I_{SUM}^{(N-1)}₍ₕ₎[j])=X^{(N)}₍ₕ₎[j]×Iₓᵤₜ. That is, in the current generation circuit RL2, when a current with a current amount I_{SUM}^{(N-1)}₍ₕ₎[j] is input to the terminal R2Ti[j], a current amount X^{(N)}₍ₕ₎[j]×I_{Xut} is output from the terminal R2To[j]. Furthermore, X^{(N)}₍ₕ₎[j] is the second data in the N-th product-sum operation.

Here, the second data output from the terminal R2To[1] to the terminal R2To[s] of the current generation circuit RL2 is referred to as X^{(N)} as a matrix. Note that when a current with a current amount I_{SUM}^{(N-1)}₍ₕ₎[j] flows from the terminal R2Ti[j] of the current generation circuit RL2 to the cell MC2[h,j] in the h-th row of the memory cell array MEMA2, X^{(N)}₍ₕ₎[j] as the second data output from the terminal R2To[j] refers to the h-th row and the j-th column of X^{(N)}.

$$[ Formula 27 ]$$

$${X}^{( N )} = ( \begin{matrix}{X}_{( 1 )}^{( N )} [ 1 ] & … & {X}_{( 1 )}^{( N )} [ s ] \\ ⋮ & ⋱ & ⋮ \\ {X}_{( s )}^{( N )} [ 1 ] & … & {X}_{( s )}^{( N )} [ s ]\end{matrix} ) \qquad ( 1.27 )$$

Note that X^{(N)}₍ₕ₎[1] to X^{(N)}₍ₕ₎[s] of the h-th row of X^{(N)} are the h-th set of the second data in the N-th arithmetic circuit.

Since a conduction state is established between the terminal R2To[i] in the current generation circuit RL2 and the wiring XCL1[i] by the switching circuit SWC5, a current with a current amount I_{SUM}^{(N)}₍ₕ₎[i] flows from the terminal R2To[i] in the current generation circuit RL2 to the cell IMD1[i] and the cell IM1[i, 1] to the cell IM1[i,s] through the wiring XCL1[i].

Here, the results of the N−1-th product-sum operations in the first row to the s-th row are read row by row from the memory cell array MEMA2, so that currents corresponding to the first set to the s-th set of the second data are sequentially output from the terminal R2To[1] to the terminal R2To[s] of the current generation circuit RL2. Accordingly, sequentially from the first row to the s-th row of the memory cell array MEMA2, one set of the second data set in each row is transmitted to the cell IMD1[1] to the cell IMD1[s] and the cells IM1[1,1] to IM1[s,s] of the arithmetic cell array MACA1.

After that, a product-sum operation is performed in the arithmetic cell array MACA1 as in Step ST5, and the arithmetic operation result is written to the memory cell array MEMA1. Here, the current amounts set in the cell MC1[1,1] to the MC1[s,s] of the memory cell array MEMA1 are referred to as I_{SUM}^{(N)} as a matrix. A current amount I_{SUM}^{(N)}₍ₕ₎[j] corresponding to the value of the result of a product-sum operation of W^{(N)}[1,j] to W^{(N)}[s,j] in the j-th column in W^{(N)} as the first data and X^{(N)}₍ₕ₎[1] to X^{(N)}₍ₕ₎[s] as the h-th set of the second data refers to the h-th row and the j-th column of I_{SUM}^{(N)}. In this case, I_{SUM}^{(N)} can be expressed by the following formula.

$$[ Formaula 28 ]$$

$${I}_{SUM}^{( N )} = ( \begin{matrix}{I}_{SUM ( 1 )}^{( N )} [ 1 ] & … & {I}_{SUM ( 1 )}^{( N )} [ s ] \\ ⋮ & ⋱ & ⋮ \\ {I}_{SUM ( s )}^{( N )} [ 1 ] & … & {I}_{SUM ( s )}^{( N )} [ s ]\end{matrix} ) \qquad ( 1.28 )$$

By Step ST12, the N-th product-sum operation is completed. Note that when the process proceeds from Step ST12 to Step ST6, the N+1-th product-sum operation is performed from Step ST6.

Note that the operations performed in Step ST11 and Step ST12 correspond to the operations in the block diagram in FIG. 14C when N=3. Here, I_{SUM}⁽³⁾ corresponds to X⁽³⁾W⁽³⁾.

### [Step ST13]

Step ST13 includes a prior operation for inputting a plurality of pieces of the second data to the arithmetic cell array MACA1 and performing the last product-sum operation.

Step ST13 includes, for example, an operation in which the switching circuit SWC1 establishes a non-conduction state between the terminal T1a[k] and the terminal T1b[k], a conduction state between the terminal T1a[k] and the terminal T1c[k], and a non-conduction state between the terminal T1c[k] and the terminal T1d[k].

Specifically, in the switching circuit SWC1 in FIG. 7A, the switch S1a[k] is turned off by supplying a low-level potential from the wiring SWL1a to the control terminal of the switch S1a[k], the switch S1b[k] is turned on by supplying a high-level potential from the wiring SWL1b to the control terminal of the switch S1b[k], and the switch S1c[k] is turned off by supplying a low-level potential from the wiring SWL3a to the control terminal of the switch S1c[k].

Step ST13 includes, for example, an operation in which the switching circuit SWC6 establishes a conduction state between the terminal T6a[k] and the terminal T6b[k] and a non-conduction state between the terminal T6b[k] and the terminal T6c[k].

Specifically, in the switching circuit SWC6 in FIG. 8B, the switch S6a[k] is turned on by supplying a high-level potential from the wiring SWL6a to the control terminal of the switch S6a[k], and the switch S6b[k] is turned off by supplying a low-level potential from the wiring SWL6b to the control terminal of the switch S6b[k].

Step ST13 includes, for example, an operation of establishing a non-conduction state between the circuit WCSa[k] and the wiring WCL1[k] in the circuit WCS.

Specifically, in the circuit SWCA in FIG. 2, the switch SA[k] is turned off by supplying a low-level potential from the wiring SWLA to the control terminal of the switch SA[k].

Step ST13 includes, for example, an operation of establishing a non-conduction state between the circuit ITRZa[k] and the wiring WCL2[k] in the circuit ITRZ.

Specifically, in the circuit SWCB in FIG. 11, the switch SB[k] is turned on by supplying a high-level potential from the wiring SWLB to the control terminal of the switch SB[k].

In the above manner, preparation for performing the last product-sum operation in the arithmetic cell array MACA1 is completed.

### [Step ST14]

Step ST14 includes an operation of performing the last product-sum operation in the arithmetic cell array MACA1. Here, a product-sum operation of W^{(N)} as the first data and X^{(N)} as the second data (here, N is an odd number greater than or equal to 1) is performed.

Specifically, in Step ST14, the second data is transmitted from the wiring XCL1[1] to the wiring XCL1[s] to each of the cell IMD1[1] to the cell IMD1[s] and the cell IM1[1,1] to the cell IM1[s,s] of the arithmetic cell array MACA1 as in Step ST5 or Step ST10, for example.

Here, the second data input to the arithmetic cell array MACA1 in Step ST14 is referred to as X^{(N)} as a matrix (here, N is an odd number greater than or equal to 1). Note that X^{(N)} is the same as that in Formula (1.27).

In Step ST14, as in Step ST5 or Step ST10, the first set to the s-th set of the second data are sequentially input to the cell IMD1[1] to the cell IMD1[s] and the cells IM1[1,1] to IM1[s,s] of the arithmetic cell array MACA1, so that a current with an amount corresponding to the result of the product-sum operation of the first data and the second data flows through each of the wiring WCL1[1] to the wiring WCL1[s].

In Step ST14, the ground potential GND is supplied from the circuit XCS2 to each of the wiring XCL2[1] to the wiring XCL2[s]. Thus, no current flows from the wiring WCL2[j] to the cell IM2[1,j] to the cell IM2[s,j] of the arithmetic cell array MAC2 in the j-th column of the arithmetic cell array MAC2.

In Step ST14, the switch S1a[j] of the switching circuit SWC1 is in an off state, the switch S1b[j] of the switching circuit SWC1 is in an on state, and the switch S1c[j] of the switching circuit SWC1 is in an off state. The switch SB[j] (not shown) of the circuit SWCB in FIG. 11A is in an on state.

Thus, a current of I_{SUM}^{(N)}₍ₕ₎[j] to the cell IM1[1,j] to the cell IM1[s,j] in the j-th column of the arithmetic cell array MACA1 flows from the circuit ITRZa[j] (not shown) of the circuit ITRZ in FIG. 11 through the wiring WCL1[j] and the wiring WCL2[j].

Here, the case where the h-th set of the second data is input to the arithmetic cell array MACA1 is considered. At this time, the amount of a current flowing from the circuit ITRZa[j] to the wiring WCL1[j] extending in the arithmetic cell array MACA1 is I_{SUM}^{(N)}₍ₕ₎[j]. Note that N in I_{SUM}^{(N)}₍ₕ₎[j] represents what number product-sum operation the product-sum operation is, and I_{SUM}^{(N)}₍ₕ₎[j] means the current amount corresponding to the arithmetic operation result obtained by the N-th product-sum operation. Furthermore, h in I_{SUM}^{(N)}₍ₕ₎[i] means that the second data included in the h-th set is used.

In this case, the amounts of currents flowing from the circuit ITRZa[1] to the circuit ITRZa[s] to the wiring WCL1[1] to the wiring WCL1[s] extending in the arithmetic cell array MACA1 can be expressed by the following formula using (Formula 1.17).

$$[ Formula 29 ]$$

$$( {I}_{{SUM}_{( h )}^{( N )}} [ 1 ] … {I}_{{SUM}_{( h )}^{( N )}} [ s ] ) = {I}_{ref 0} ( {\sum }_{i = 1}^{s} {X}_{( h )}^{( N )} [ i ] \times {W}^{( N )} [ i , 1 ] … {\sum }_{i = 1}^{s} {X}_{( h )}^{( N )} [ i ] \times {W}^{( N )} [ i , s ] ) \qquad ( 1.29 )$$

In each of the circuit ITRZa[1] to the circuit ITRZa[s], the converter circuit RL3[j] performs an arithmetic operation of a function system with the use of a value corresponding to a current amount I_{SUM}^{(N)}₍ₕ₎[j] input to the terminal R3Ti[j] as an input value and outputs a current with an amount corresponding to the result of the arithmetic operation to the terminal R3To[j]. Here, when a function is F(x) (x is an input value) and the input value is I_{SUM}^{(N)}₍ₕ₎[j], the result of the arithmetic operation of the function is defined as F(I_{SUM}^{(N)}₍ₕ₎[j])=T₍ₕ₎[j]×I_{Tut}. Note that I_{Tut} is a reference current that flows when T₍ₕ₎[j] is 1. In the converter circuit RL3, when a current with a current amount I_{SUM}^{(N)}₍ₕ₎[j] is input to the terminal R3Ti[j], a current amount T₍ₕ₎[j]×I_{Tut} is output from the terminal R3To[j]. Furthermore, T₍ₕ₎[j] is the arithmetic operation result obtained with the arithmetic circuit CDV.

Here, the arithmetic operation results output from the terminal R3To[1] to the terminal R3To[s] of the converter circuit RL3[1] to the converter circuit RL3[s] are referred to as T as a matrix. Note that when a current with a current amount I_{SUM}^{(N)}₍ₕ₎ [j] flows from the terminal R3Ti[j] of the converter circuit RL3[j] to the cell MC1[h,j] in the h-th row of the memory cell array MEMA1, T₍ₕ₎[j], which is the arithmetic result output from the terminal R3To[j], refers to the h-th row and the j-th column of T.

$$[ Formula 30 ]$$

$$T = ( \begin{matrix}{T}_{( 1 )} [ 1 ] & … & {T}_{( 1 )} [ s ] \\ ⋮ & ⋱ & ⋮ \\ {T}_{( s )} [ 1 ] & … & {T}_{( s )} [ s ]\end{matrix} ) \qquad ( 1.3 )$$

Note that T₍ₕ₎[1] to T₍ₕ₎[s] of the h-th row of T are the results that are obtained using the h-th set of the second data in the N-th product-sum operation and output from the terminal R3To[1] to the terminal R3To[s] of the converter circuit RL3[1] to the converter circuit RL3[s].

On another note, when the first set to the s-th set of the second data are sequentially input in the arithmetic cell array MACA1, the results of arithmetic operations of the cases of the first set to the s-th set are sequentially output from the terminal R3To[1] to the terminal R3To[s] of the converter circuit RL3.

After that, the arithmetic operation results T₍₁₎ [j] to T₍ₛ₎ [j] sequentially output from the terminal R3To[j] of the converter circuit RL3 in the circuit ITRZa[j] are converted into digital signals by the analog-digital converter circuit ADC, and the digital signals are output from the wiring OL[j].

Note that the operations performed in Step ST13 and Step ST14 correspond to the operations in the block diagram in FIG. 15A.

### [Step ST15]

Step ST15 includes a prior operation for inputting a plurality of pieces of the second data to the arithmetic cell array MACA2 and performing the last product-sum operation.

Step ST15 includes, for example, an operation in which the switching circuit SWC1 establishes a non-conduction state between the terminal T1a[k] and the terminal T1b[k], a conduction state between the terminal T1a[k] and the terminal T1c[k], and a non-conduction state between the terminal T1c[k] and the terminal T1d[k].

Specifically, in the switching circuit SWC1 in FIG. 7A, the switch S1a[k] is turned off by supplying a low-level potential from the wiring SWL1a to the control terminal of the switch S1a[k], the switch S1b[k] is turned on by supplying a high-level potential from the wiring SWL1b to the control terminal of the switch S1b[k], and the switch S1c[k] is turned off by supplying a low-level potential from the wiring SWL3a to the control terminal of the switch S1c[k].

Step ST15 includes, for example, an operation in which the switching circuit SWC5 establishes a conduction state between the terminal T5a[k] and the terminal T5b[k] and a non-conduction state between the terminal T5b[k] and the terminal T5c[k].

Specifically, in the switching circuit SWC5 in FIG. 8A, the switch S5a[k] is turned on by supplying a high-level potential from the wiring SWL5a to the control terminal of the switch S5a[k], and the switch S5b[k] is turned off by supplying a low-level potential from the wiring SWL5b to the control terminal of the switch S5b[k].

Step ST15 includes, for example, an operation of establishing a non-conduction state between the circuit WCSa[k] and the wiring WCL1[k] in the circuit WCS.

Specifically, in the circuit SWCA in FIG. 2, the switch SA[k] is turned off by supplying a low-level potential from the wiring SWLA to the control terminal of the switch SA[k].

Step ST15 includes, for example, an operation of establishing a non-conduction state between the circuit ITRZa[k] and the wiring WCL2[k] in the circuit ITRZ.

Specifically, in the circuit SWCB in FIG. 11, the switch SB[k] is turned on by supplying a high-level potential from the wiring SWLB to the control terminal of the switch SB[k].

In the above manner, preparation for performing the last product-sum operation in the arithmetic cell array MACA2 is completed.

### [Step ST16]

Step ST16 includes an operation of performing the last product-sum operation of a plurality of pieces of the first data and a plurality of pieces of the second data in the arithmetic cell array MACA2. Here, a product-sum operation of W^{(N+1)} as the first data and X^{(N+1)} as the second data (here, N+1 is an even greater than or equal to 2) is performed.

Specifically, in Step ST16, the second data is transmitted from the wiring XCL2[1] to the wiring XCL2[s] to each of the cell IMD2[1] to the cell IMD2[s] and the cell IM2[1,1] to the cell IM2[s,s] of the arithmetic cell array MACA2 as in Step ST5 or Step ST10, for example.

Here, the second data input to the arithmetic cell array MACA2 in Step ST16 is referred to as X^{(N+1)} as a matrix (here, N+1 is an even number greater than or equal to 2). Note that X^{(N)} is the same as that in Formula (1.27).

In Step ST16, as in Step ST5 or Step ST10, the first set to the s-th set of the second data are sequentially input to the cell IMD2[1] to the cell IMD2[s] and the cells IM2[1,1] to IM2[s,s] of the arithmetic cell array MACA2, so that a current with an amount corresponding to the result of the product-sum operation of the first data and the second data flows through each of the wiring WCL2[1] to the wiring WCL2[s].

In Step ST16, the ground potential GND is supplied from the circuit XCS1 to each of the wiring XCL1[1] to the wiring XCL1[s]. Thus, no current flows from the wiring WCL1[j] to the cell IM1[1,j] to the cell IM1[s,j] of the arithmetic cell array MAC1 in the j-th column of the arithmetic cell array MAC1.

In Step ST16, the switch S1a[j] of the switching circuit SWC1 is in an off state, the switch S1b[j] of the switching circuit SWC1 is in an on state, and the switch S1c[j] of the switching circuit SWC1 is in an off state. The switch SB[j] (not shown) of the circuit SWCB in FIG. 11A is in an on state.

Thus, a current of I_{SUM}^{(N+1)}₍ₕ₎[j] to the cell IM2[1,j] to the cell IM2[s,j] in the j-th column of the arithmetic cell array MACA2 flows from the circuit ITRZa[j] (not shown) of the circuit ITRZ in FIG. 11 through the wiring WCL2[j].

Here, the case where the h-th set of the second data is input to the arithmetic cell array MACA2 is considered. At this time, the amount of a current flowing from the circuit ITRZa[j] to the wiring WCL2[j] extending in the arithmetic cell array MACA2 is I_{SUM}^{(N+1)}₍ₕ₎[j]. Note that N in I_{SUM}^{(N)}₍ₕ₎[j] represents what number product-sum operation the product-sum operation is, and I_{SUM}^{(N+}1)₍ₕ₎ [j] means the current amount corresponding to the arithmetic operation result obtained by the N+1-th product-sum operation. Furthermore, h in I_{SUM}^{(N)}₍ₕ₎ [i] means that the second data included in the h-th set is used.

In this case, the amounts of currents flowing from the circuit ITRZa[1] to the circuit ITRZa[s] to the wiring WCL1[1] to the wiring WCL1[s] extending in the arithmetic cell array MACA1 can be expressed using (Formula 1.17) as in Formula (1.25).

In each of the circuit ITRZa[1] to the circuit ITRZa[s], the converter circuit RL3[j] performs an arithmetic operation of a function system with the use of a value corresponding to a current amount I_{SUM}^{(N+1)}₍ₕ₎[j] input to the terminal R3Ti[j] as an input value and outputs a current with an amount corresponding to the result of the arithmetic operation to the terminal R3To[j]. In the converter circuit RL3, when a current with a current amount I_{SUM}^{(N+1)}₍ₕ₎[j] is input to the terminal R3Ti[j], a current amount T₍ₕ₎[j]×I_{Tut} is output from the terminal R3To[j], with a function defined as F(x) as in Step ST14. Accordingly, T₍ₕ₎[j] is obtained as the arithmetic operation result with the circuit CVD as in Step ST14.

The arithmetic operation results output from the terminal R3To[1] to the terminal R3To[s] of the converter circuit RL3[1] to the converter circuit RL3[s] are T as a matrix, as in Formula (1.30).

Note that T₍ₕ₎[1] to T₍ₕ₎[s] of the h-th row of T are the results that are obtained using the h-th set of the second data in the N-th product-sum operation and output from the terminal R3To[1] to the terminal R3To[s] of the converter circuit RL3[1] to the converter circuit RL3[s].

On another note, when the first set to the s-th set of the second data are sequentially input in the arithmetic cell array MACA2, the results of arithmetic operations of the cases of the first set to the s-th set are sequentially output from the terminal R3To[1] to the terminal R3To[s] of the converter circuit RL3.

After that, the arithmetic operation results T₍₁₎ [j] to T₍ₛ₎ [j] sequentially output from the terminal R3To[j] of the converter circuit RL3 in the circuit ITRZa[j] are converted into digital signals by the analog-digital converter circuit ADC, and the digital signals are output from the wiring OL[j].

Note that the operations performed in Step ST15 and Step ST16 correspond to the operations in the block diagram in FIG. 15B.

With the use of the arithmetic circuit CDV described in this embodiment, a product-sum operation can be performed once or a plurality of times. In the case where a conventional arithmetic circuit performs a product-sum operation a plurality of times, digital-analog conversion and analog-digital conversion are performed before and after one arithmetic operation; however, with the use of the arithmetic circuit CDV, generation of an analog current in the circuit WCS is the only digital-analog conversion, and processing by the analog-digital converter circuit ADC in the circuit ITRZ is the only analog-digital conversion. That is, the use of the arithmetic circuit CDV can reduce the number of digital-analog converter circuits and the number of analog-digital converter circuits, and thus, the circuit area of the arithmetic circuit CDV is smaller than that of the conventional structure. The power consumption of the arithmetic circuit CDV can be lower than that of the conventional structure.

Although this embodiment describes an example in which a plurality of arithmetic cells included in the arithmetic cell array MACA1, a plurality of arithmetic cells included in the arithmetic cell array MACA2, a plurality of memory cells included in the memory cell array MEMA1, and a plurality of memory cells included in the memory cell array MEMA2 are arranged in a matrix of s rows and s columns, all or some of the arithmetic cell array MACA1, the arithmetic cell array MACA2, the memory cell array MEMA1, and the memory cell array MEMA2 may have different numbers of rows. All or some of the arithmetic cell array MACA1, the arithmetic cell array MACA2, the memory cell array MEMA1, and the memory cell array MEMA2 may have different numbers of columns.

The semiconductor device of one embodiment of the present invention is not limited to the structure of the arithmetic circuit CDV described in this embodiment. The semiconductor device of one embodiment of the present invention may have an appropriately modified structure of the arithmetic circuit CDV described in this embodiment.

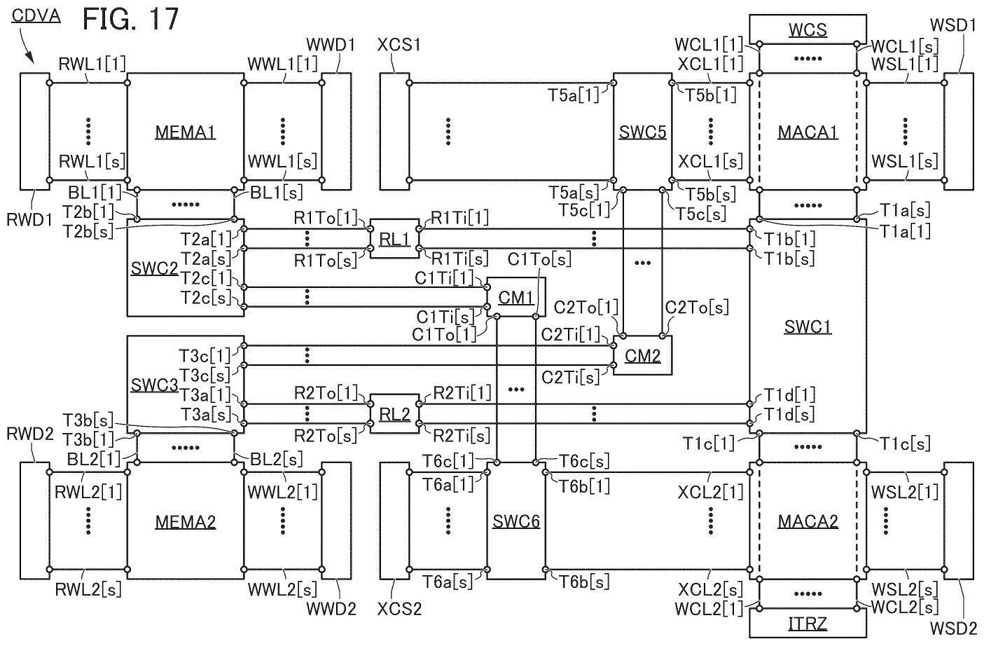

For example, the arithmetic circuit CDV illustrated in FIG. 1 may be changed to an arithmetic circuit CDVA illustrated in FIG. 17. The arithmetic circuit CDVA is a modification example of the arithmetic circuit CDV and is different from the arithmetic circuit CDV in that the current generation circuit RL1 and the current generation circuit CM1 are replaced with each other and the current generation circuit CM2 and the current generation circuit RL2 are replaced with each other.

Specifically, the terminal T1b[k] is electrically connected to the terminal R1Ti[k], the terminal R1To[k] is electrically connected to the terminal T2a[k], the terminal T1d[k] is electrically connected to the terminal R2Ti[k], the terminal R2To[k] is electrically connected to the terminal T3a[k], the terminal T2c[k] is electrically connected to the terminal C1Ti[k], the terminal C1To[k] is electrically connected to the terminal T6c[k], the terminal T3c[k] is electrically connected to the terminal C2Ti[k], and the terminal C2To[k] is electrically connected to the terminal T5c[k].

Thus, in the arithmetic circuit CDVA, a potential corresponding to the amount of a current output from the current generation circuit RL1 is written to the memory cell array MEMA1, and a potential corresponding to the amount of a current output from the current generation circuit RL2 is written to the memory cell array MEMA2. Even with such a structure, the arithmetic circuit CDVA can perform a product-sum operation and an arithmetic operation of a function system a plurality of times like the arithmetic circuit CDV.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 2

In this embodiment, a structure example of the arithmetic circuit CDV described in the above embodiment will be described.

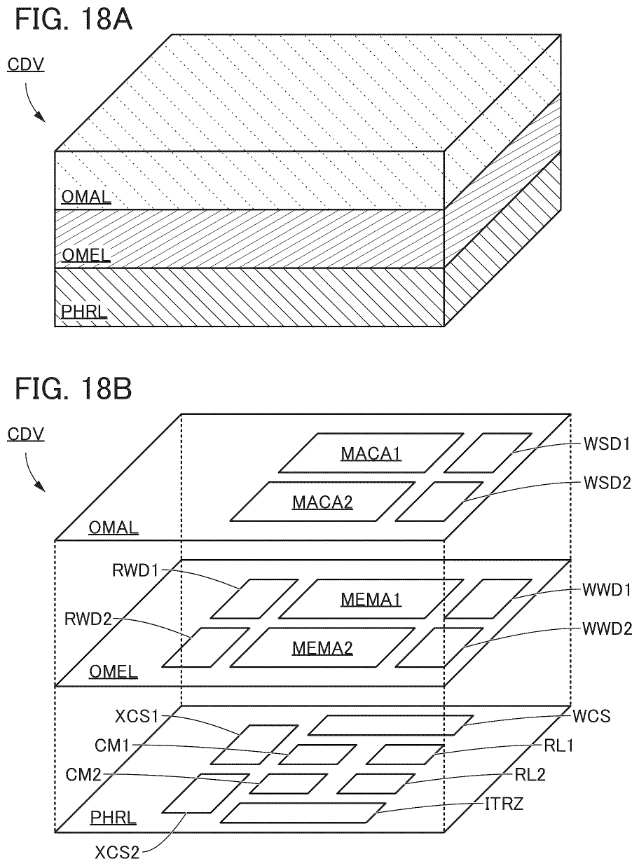

FIG. 18A is a schematic perspective view showing the arithmetic circuit CDV that is a semiconductor device of one embodiment of the present invention. The arithmetic circuit CDV shown in FIG. 18A includes a circuit layer PHRL, a memory layer OMEL, and an arithmetic layer OMAL, for example. The circuit layer PHRL is positioned below the memory layer OMEL, and the arithmetic layer OMAL is positioned above the memory layer OMEL. That is, the circuit layer PHRL, the memory layer OMEL, and the arithmetic layer OMAL are stacked in this order from the bottom in the arithmetic circuit CDV shown in FIG. 18A.

FIG. 18B is a block diagram showing structure examples of the circuit layer PHRL, the memory layer OMEL, and the arithmetic layer OMAL shown in FIG. 18A.

In FIG. 18B, the circuit layer PHRL includes, for example, the circuit WCS, the circuit XCS1, the circuit XCS2, the circuit ITRZ, the current generation circuit CM1, the current generation circuit CM2, the current generation circuit RL1, and the current generation circuit RL2 that are illustrated in FIG. 1. The memory layer OMEL includes, for example, the memory cell array MEMA1, the memory cell array MEMA2, the circuit WWD1, the circuit WWD2, the circuit RWD1, and the circuit RWD2 that are illustrated in FIG. 1. The arithmetic layer OMAL includes, for example, the arithmetic cell array MACA1, the arithmetic cell array MACA2, the circuit WSD1, and the circuit WSD2.

Note that the switching circuit SWC1, the switching circuit SWC2, the switching circuit SWC3, the switching circuit SWC5, and the switching circuit SWC6 illustrated in FIG. 1 may be included in the circuit layer PHRL, may be included in the memory layer OMEL, or may be included in the arithmetic layer OMAL.

The circuit layer PHRL can be formed by providing a circuit element such as a transistor or a capacitor over a substrate, for example. As the substrate, a semiconductor substrate (e.g., a single crystal substrate formed of silicon or germanium) can be used. Besides such a semiconductor substrate, for example, any of the following can be used: an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper and a base film each including a fibrous material. Examples of the glass substrate include a barium borosilicate glass substrate, an aluminoborosilicate glass substrate, and a soda lime glass substrate. Examples of materials for the flexible substrate, the attachment film, or the base film include plastics typified by polyethylene terephthalate (PET), polyethylene naphthalate (PEN), polyethersulfone (PES), and polytetrafluoroethylene (PTFE). Another example is a synthetic resin such as acrylic. Other examples are polypropylene, polyester, polyvinyl fluoride, and polyvinyl chloride. Other examples are polyamide, polyimide, aramid, an epoxy resin, an inorganic vapor-deposited film, and paper. Note that in the case where the manufacturing process of the arithmetic circuit CDV involves heat treatment, a highly heat-resistant material is preferably selected for the substrate.

Note that the substrate included in the circuit layer PHRL is described as a semiconductor substrate including silicon in this embodiment.

When the substrate included in the circuit layer PHRL is a semiconductor substrate including silicon as a material, for example, the transistors included in the circuit WCS, the circuit XCS1, the circuit XCS2, the circuit ITRZ, the current generation circuit CM1, the current generation circuit CM2, the current generation circuit RL1, and the current generation circuit RL2 can be formed on the semiconductor substrate. In that case, the transistors are Si transistors. The Si transistor has high field-effect mobility and thus can make a high on-state current flow. Accordingly, the driving speed of each of the above-described circuits can be increased, and the range of a signal can be expanded, for example.

The stacked-layer structure of the circuit layer PHRL and the memory layer OMEL can be fabricated by directly forming the memory layer OMEL on the circuit layer PHRL. Alternatively, the stacked-layer structure can be fabricated in the following manner: the memory layer OMEL is formed by providing a circuit element such as a transistor or a capacitor over a substrate, and the substrate is mounted over the circuit layer PHRL.

In the case where the memory layer OMEL is directly formed on the circuit layer PHRL, the memory layer OMEL preferably includes an OS transistor. The OS transistor can be formed not only over a semiconductor substrate but also over an insulator substrate, a conductor substrate, a conductive film, an insulating film, and a semiconductor film and thus can be easily provided over a semiconductor substrate where a Si transistor is formed (over the circuit layer PHRL).

In the case where the memory layer OMEL is formed by forming a circuit element such as a transistor or a capacitor over a substrate and the substrate is mounted over the circuit layer PHRL, a flip-chip bonding method or a wire bonding method can be used. Alternatively, the memory layer OMEL may be mounted over the circuit layer PHRL in the following manner: a first bonding layer is provided on the circuit layer PHRL side, a second bonding layer is provided on the substrate of the memory layer OMEL, and the first bonding layer and the second bonding layer are bonded to each other by one or both of a surface activated bonding method and a hydrophilic bonding method. Specifically, in what is called Cu—Cu junction, the first bonding layer and the second bonding layer each include copper (Cu) as a conductor, and copper (Cu) of the first bonding layer and that of the second bonding layer are bonded to each other.

### Cross-Sectional Structure Example 1

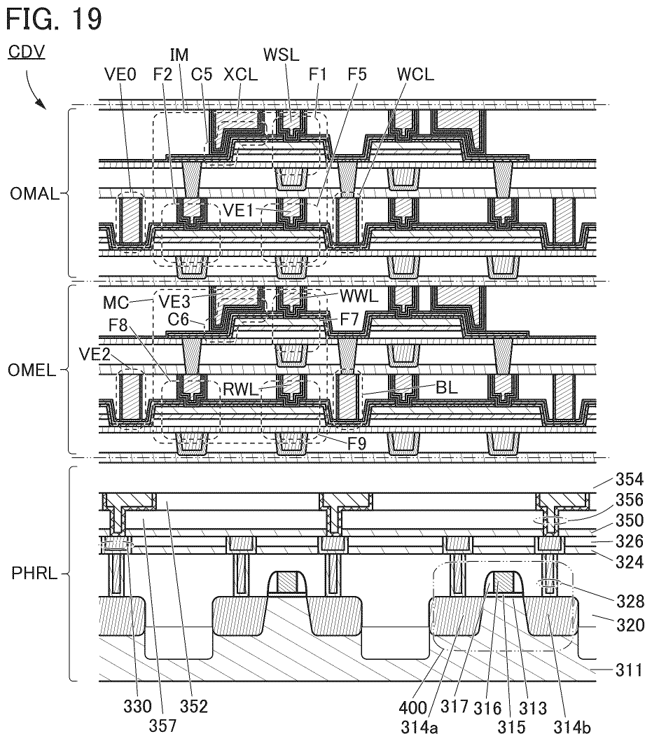

Next, a specific structure example of the arithmetic circuit CDV shown in FIG. 18A and FIG. 18B is described. FIG. 19 is a schematic cross-sectional view showing an example of the arithmetic circuit CDV shown in FIG. 18A and FIG. 18B.

The schematic cross-sectional view in FIG. 19 shows the circuit layer PHRL, the memory layer OMEL, and the arithmetic layer OMAL. Note that the arithmetic circuit CDV shown in FIG. 19 has a structure in which the memory layer OMEL is directly formed on the circuit layer PHRL and the arithmetic layer OMAL is directly formed on the memory layer OMEL.

FIG. 19 shows a transistor 400 included in the circuit layer PHRL. The transistor 400 is provided on a substrate 311 and includes a conductor 316 functioning as a gate, an insulator 315 and an insulator 317 functioning as gate insulators, a semiconductor region 313 that includes part of the substrate 311, and a low-resistance region 314a and a low-resistance region 314b functioning as a source region and a drain region. The transistor 400 may be a p-channel transistor or an n-channel transistor. As the substrate 311, a single crystal silicon substrate can be used, for example.

In the transistor 400 illustrated in FIG. 19, the semiconductor region 313 (part of the substrate 311) in which a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. Such a transistor 400 is also referred to as a FIN-type transistor because it utilizes a protruding portion of a semiconductor substrate. An insulator functioning as a mask for forming the protruding portion may be provided in contact with an upper portion of the protruding portion. Although the case where the protruding portion is formed by processing part of the semiconductor substrate is described here, a semiconductor film having a protruding shape may be formed by processing an SOI substrate.

Note that the transistor 400 shown in FIG. 19 is just an example and is not limited to the structure shown therein; an appropriate transistor may be used in accordance with a circuit structure or a driving method.

Wiring layers including an interlayer film, a wiring, and a plug may be provided between the structure bodies. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 324, and an insulator 326 are stacked over the transistor 400 in this order as interlayer films. A conductor 328 or the like is embedded in the insulator 320. A conductor 330 or the like is embedded in the insulator 324 and the insulator 326. Note that the conductor 328 and the conductor 330 function as contact plugs or wirings.

The insulator functioning as an interlayer film may function as a planarization film that covers an uneven shape thereunder. For example, the top surface of the insulator 320 may be planarized by planarization treatment using a chemical mechanical polishing (CMP) method to improve planarity.

A wiring layer may be provided over the insulator 326 and the conductor 330. For example, in FIG. 19, an insulator 350, an insulator 357, an insulator 352, and an insulator 354 are stacked in this order over the insulator 326 and the conductor 330. A conductor 356 is formed in the insulator 350, the insulator 357, and the insulator 352. The conductor 356 functions as a contact plug or a wiring.

The insulator 354 is provided over the insulator 352 and the conductor 356. In the insulator 354, a contact plug or a wiring for electrical connection to an upper circuit (e.g., a circuit included in the memory layer OMEL or a circuit included in the arithmetic layer OMAL) may be embedded.

FIG. 19 shows the cell MC included in the memory layer OMEL. Specifically, FIG. 19 shows the transistor F7, the transistor F8, the transistor F9, and the capacitor C6 included in the cell MC. Note that the cell MC can be any one of the cell MC1[1,1] to the cell MC1[s,s] and the cell MC2[1,1] to the cell MC2[s,s] described in the above embodiment.

In the memory layer OMEL of the arithmetic circuit CDV in FIG. 19, the transistor F7 and the capacitor C6 are positioned above the transistor F8 and the transistor F9.

In the memory layer OMEL shown in FIG. 19, the transistor F8 and the transistor F9 are provided to share one island-shaped semiconductor layer. Specifically, a gate insulating film and a gate electrode of the transistor F8 are formed in one of two regions of the one island-shaped semiconductor layer, and a gate insulating film and a gate electrode of the transistor F9 are formed in the other of the two regions of the one island-shaped semiconductor layer.

In the memory layer OMEL in FIG. 19, a transistor that includes a back gate is used as each of the transistor F8 and the transistor F9. Specifically, the back gate of the transistor F8 is positioned in a region overlapping with the gate insulating film and the gate electrode of the transistor F8 that are below the above-described one island-shaped semiconductor layer, and the back gate of the transistor F9 is positioned in a region overlapping with the gate insulating film and the gate electrode of the transistor F9 that are below the above-described one island-shaped semiconductor layer.

A conductor corresponding to the wiring VE2 is electrically connected to one of a source electrode and a drain electrode of the transistor F8. A conductor corresponding to the wiring BL is electrically connected to one of a source electrode and a drain electrode of the transistor F9. Note that the wiring BL can be any one of the wiring BL1[1] to the wiring BL1[s] and the wiring BL2[1] to the wiring BL2[s] described in the above embodiment. The wiring VE2 and the wiring BL extend in the channel width direction of the transistor F8 or the transistor F9, for example.

A conductor as the gate electrode of the transistor F9 extends in the channel width direction. This conductor corresponds to the wiring RWL. Note that the wiring RWL can be any one of the wiring RWL1[1] to the wiring RWL1[s] and the wiring RWL2[1] to the wiring RWL2[s] described in the above embodiment.

An insulator serving as an interlayer film is formed between the transistor F7 and each of the transistor F8 and the transistor F9. The insulator includes an opening portion in each of a region overlapping with the gate electrode of the transistor F8 and a region overlapping with the wiring BL, and conductors are embedded in the opening portions. One conductor is electrically connected to one of a source electrode and a drain electrode of the transistor F7, and the other conductor is electrically connected to the other of the source electrode and the drain electrode of the transistor F7.

As already described above, the transistor F7 is positioned above the transistor F8 and the transistor F9. A dielectric of the capacitor C6 is formed to cover an end portion of an island-shaped semiconductor layer of the transistor F7, and a conductor corresponding to the second terminal of the capacitor C6 is formed over the dielectric. The conductor corresponds to the wiring VE3.

As described in Embodiment 1, the wiring VE2 and the wiring VE3 may supply the same potential. In the case where the wiring VE2 and the wiring VE3 supply the same potential, the wiring VE2 and the wiring VE3 may be electrically connected to each other (not shown).

In a region of the island-shaped semiconductor layer of the transistor F7, a gate insulating film and a gate electrode of the transistor F7 are formed. Specifically, a conductor as the gate electrode of the transistor F7 extends in the channel width direction. This conductor corresponds to the wiring WWL. Note that the wiring WWL can be any one of the wiring WWL1[1] to the wiring WWL1[s] and the wiring WWL2[1] to the wiring WWL2[s] described in the above embodiment.

The transistor F7 is a transistor that includes a back gate like the transistor F8 and the transistor F9. Specifically, the back gate of the transistor F7 is positioned in a region overlapping with the gate insulating film and the gate electrode of the transistor F7 that are below the island-shaped semiconductor layer.

As described above, in each of the transistor F7, the transistor F8, and the transistor F9, the gate and the back gate are positioned to interpose a channel formation region of the semiconductor. The gate and the back gate are each formed using a conductor. The back gate can function in a manner similar to that of the gate. In addition, by changing the potential of the back gate, the threshold voltage of the transistor can be changed. The potential of the back gate may be the same as that of the gate or may be a ground potential or a freely selected potential.

Each of the gate and the back gate is formed using a conductor and thus has a function of preventing an electric field generated in the outside of the transistor from influencing the semiconductor in which the channel is formed (particularly, a function of blocking static electricity). That is, a variation in the electrical characteristics of the transistor due to the influence of an external electric field such as static electricity can be prevented. By providing the back gate, the amount of change in threshold voltage of the transistor before and after a bias-temperature stress test (which is sometimes referred to as BT test) can be reduced.

For example, when a transistor including a back gate is used as the transistor F7, the transistor F7 is less affected by an external electric field and can keep on being in an off state stably. As a result, data written to the first terminal of the capacitor C6 can be stably retained. Providing the back gate can make the operation of the cell MC stable and increase the reliability of the memory layer OMEL that includes the cell MC.

For each of the semiconductor layers in which the channels of the transistor F7, the transistor F8, and the transistor F9 are formed, one or a combination of a single crystal semiconductor, a polycrystalline semiconductor, a microcrystalline semiconductor, an amorphous semiconductor, and the like can be used. As a semiconductor material, for example, silicon, germanium, or the like can be used as described in Embodiment 1. For another example, a compound semiconductor such as silicon germanium, silicon carbide, gallium arsenide, an oxide semiconductor, or a nitride semiconductor may be used.

Each of the transistor F7, the transistor F8, and the transistor F9 is preferably a transistor using an oxide semiconductor, which is one type of metal oxide, in its semiconductor layer where a channel is formed (also referred to as an OS transistor). An oxide semiconductor has a band gap greater than or equal to 2 eV and thus enables an extremely low off-state current. Thus, power consumption of the cell MC can be reduced. Accordingly, power consumption of the arithmetic circuit CDV that includes the cell MC can be reduced.

A memory cell including an OS transistor can be referred to as an “OS memory”. The arithmetic circuit CDV that includes the memory cell can also be referred to as an “OS memory”. In addition, the OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature and lower than or equal to 200° C. In addition, the on-state current is less likely to decrease even in a high-temperature environment. Thus, the OS memory can operate stably and have high reliability even in a high-temperature environment.

FIG. 19 shows the cell IM included in the arithmetic layer OMAL. Specifically, FIG. 19 shows the transistor F1, the transistor F2, the transistor F5, and the capacitor C5 included in the cell IM. Note that the cell IM can be any one of the cell IM1[1,1] to the cell IM1[s,s] and the cell IM2[1,1] to the cell IM2[s,s] described in the above embodiment.

As shown in FIG. 19, the structure of the cell IM included in the arithmetic layer OMAL can be the same as that of the cell MC included in the memory layer OMEL. Thus, the above description of the cell MC included in the memory layer OMEL is to be referred to for the structure of the cell IM included in the arithmetic layer OMAL. The description of the cell IM included in the arithmetic layer OMAL is made when, in the description of the cell MC included in the memory layer OMEL, the transistor F7 is replaced with the transistor F1, the transistor F8 is replaced with the transistor F2, the transistor F9 is replaced with the transistor F5, the capacitor C6 is replaced with the capacitor C5, the wiring BL is replaced with the wiring WCL, the wiring VE2 is replaced with the wiring VE0, the wiring RWL is replaced with the wiring VE1, the wiring VE3 is replaced with the wiring XCL, and the wiring WWL is replaced with the wiring WSL.

Note that the wiring WCL can be any one of the wiring WCL1[1] to the wiring WCL1[s] and the wiring WCL2[1] to the wiring WCL2[s] described in the above embodiment. The wiring WSL can be any one of the wiring WSL1[1] to the wiring WSL1[s] and the wiring WSL2[1] to the wiring WSL2[s] described in the above embodiment. The wiring XCL can be any one of the wiring XCL1[1] to the wiring XCL1[s] and the wiring XCL2[1] to the wiring XCL2[s] described in the above embodiment.

### Cross-Sectional Structure Example 2

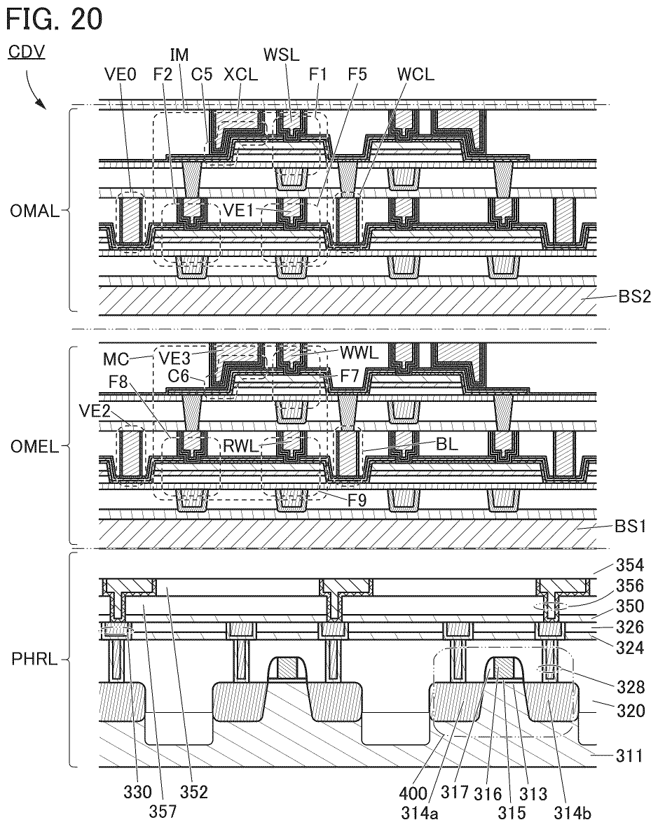

FIG. 20 is a schematic cross-sectional view, which differs from FIG. 19, showing an example of the arithmetic circuit CDV shown in FIG. 18A and FIG. 18B.

The arithmetic circuit CDV in FIG. 20 differs from the arithmetic circuit CDV in FIG. 19 in that each of the memory layer OMEL and the arithmetic layer OMAL includes a substrate.

The memory layer OMEL of the arithmetic circuit CDV in FIG. 20 includes a substrate BS1. The transistor F7, the transistor F8, the transistor F9, and the capacitor C6 are formed over the substrate BS1. The structure of the cell MC formed over the substrate BS1 is the same as that of the cell MC of the arithmetic circuit CDV in FIG. 19; however, the structure of the cell MC in FIG. 20 may be changed depending on circumstances.

The arithmetic layer OMAL of the arithmetic circuit CDV in FIG. 20 includes a substrate BS2. The transistor F1, the transistor F2, the transistor F5, and the capacitor C5 are formed over the substrate BS2. The structure of the cell IM formed over the substrate BS2 is the same as that of the cell IM of the arithmetic circuit CDV in FIG. 19; however, the structure of the cell IM in FIG. 20 may be changed depending on circumstances.

That is, in the arithmetic circuit CDV in FIG. 20, the substrate BS1 included in the memory layer OMEL and the substrate BS2 included in the arithmetic layer OMAL are mounted over the substrate 311 over which the circuit XCS1, the circuit WCS, and the circuit ITRZ are formed.

As each of the substrate BS1 and the substrate BS2, a substrate that can be applied to the substrate (e.g., the substrate 311) included in the circuit layer PHRL can be used. For example, when a semiconductor substrate including silicon as a material is used as each of the substrate BS1 and the substrate BS2, the transistor F1, the transistor F2, the transistor F5, and the transistor F7 to the transistor F9 can be Si transistors.

As a method for mounting the substrate BS1 over the substrate 311 and a method for mounting the substrate BS2 over the substrate BS1, a flip-chip bonding method or a wire bonding method can be used as described above. A bonding layer may be provided between the substrates to be bonded, and one or both of a surface activated bonding method and a hydrophilic bonding method may be used.

The structure of a semiconductor device of one embodiment of the present invention is not limited to the structures shown in FIG. 18A, FIG. 18B, FIG. 19, and FIG. 20. Any of the structures shown in FIG. 18A, FIG. 18B, FIG. 19, and FIG. 20 may be modified as appropriate to be used for the semiconductor device of one embodiment of the present invention.

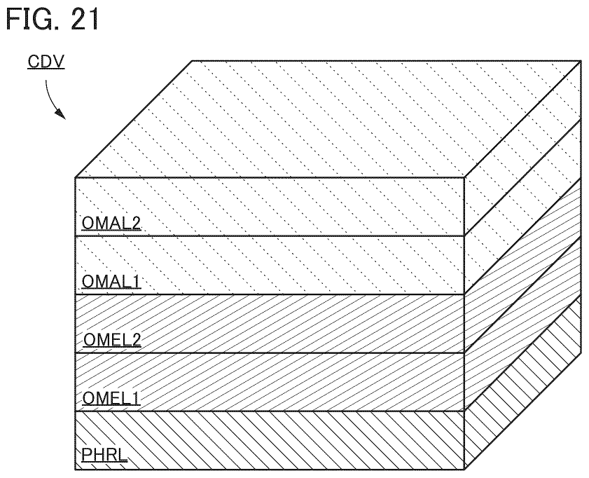

FIG. 21 shows a modification example of the arithmetic circuit CDV shown in FIG. 18A. The arithmetic circuit CDV shown in FIG. 21 differs from the arithmetic circuit CDV in FIG. 18A in including a memory layer OMEL1 and a memory layer OMEL2 instead of the memory layer OMEL and including an arithmetic layer OMAL1 and an arithmetic layer OMAL2 instead of the arithmetic layer OMAL. In other words, the arithmetic circuit CDV in FIG. 21 includes the circuit layer PHRL, the memory layer OMEL1, the memory layer OMEL2, the arithmetic layer OMAL1, and the arithmetic layer OMAL2.

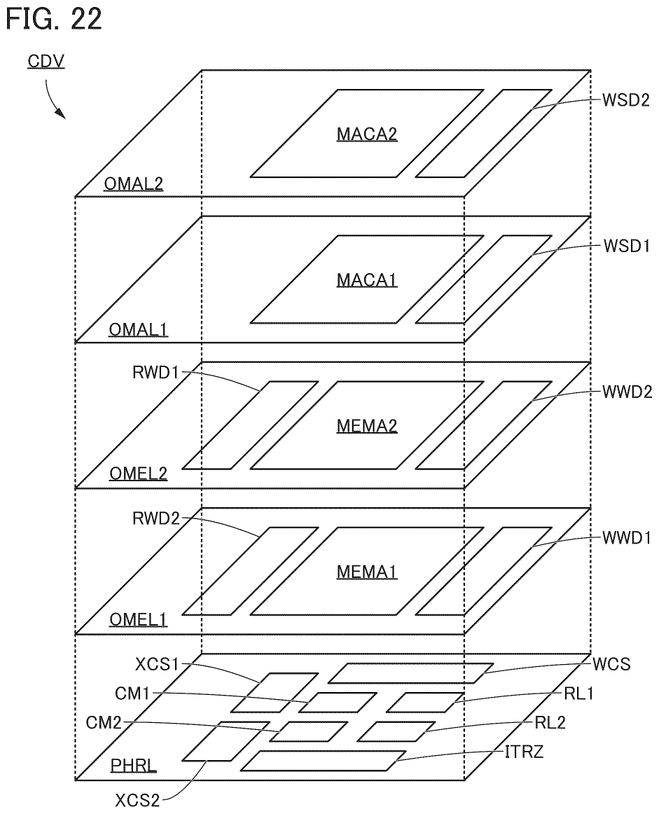

FIG. 22 is a block diagram illustrating structure examples of the circuit layer PHRL, the memory layer OMEL1, the memory layer OMEL2, the arithmetic layer OMAL1, and the arithmetic layer OMAL2 illustrated in FIG. 21.

In FIG. 22, the circuit layer PHRL includes the circuit WCS, the circuit XCS1, the circuit XCS2, the circuit ITRZ, the current generation circuit CM1, the current generation circuit CM2, the current generation circuit RL1, and the current generation circuit RL2 that are illustrated in FIG. 1, like the circuit layer PHRL illustrated in FIG. 18B, for example. The memory layer OMEL1 includes, for example, the memory cell array MEMA1, the circuit WWD1, and the circuit RWD1 illustrated in FIG. 1. The memory layer OMEL2 includes, for example, the memory cell array MEMA2, the circuit WWD2, and the circuit RWD2 illustrated in FIG. 1. The arithmetic layer OMAL1 includes, for example, the arithmetic cell array MACA1 and the circuit WSD1. The arithmetic layer OMAL2 includes, for example, the arithmetic cell array MACA2 and the circuit WSD2.

As described above, in the arithmetic circuit CDV, two or four of the memory layer(s) OMEL and the arithmetic layer(s) OMAL can be provided over the circuit layer PHRL. Note that the total number of the memory layers OMEL and the arithmetic layers OMAL provided over the circuit layer PHRL may be three or five or more.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 3

In this embodiment, a transistor whose channel formation region includes an oxide semiconductor (OS transistor) is described. In the description of the OS transistor, comparison with a transistor whose channel formation region includes silicon (also referred to as Si transistor) is also described briefly.

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as V_{O}H) may be formed and may generate an electron serving as a carrier. When V_{O}H is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel exists and a current flows through the transistor even when no voltage is applied to the gate electrode). Therefore, the impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometime also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during an operation of the transistor and to the width of a bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 4

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

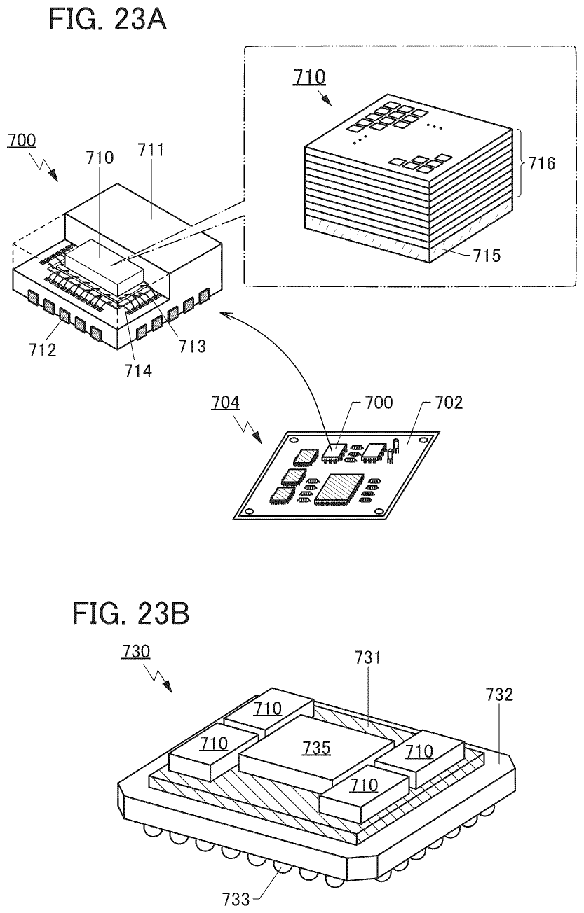

FIG. 23A is a perspective view of a substrate (a circuit board 704) on which an electronic component 700 is mounted. The electronic component 700 illustrated in FIG. 23A includes a semiconductor device 710 in a mold 711. Some components are omitted in FIG. 23A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 23B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 23B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

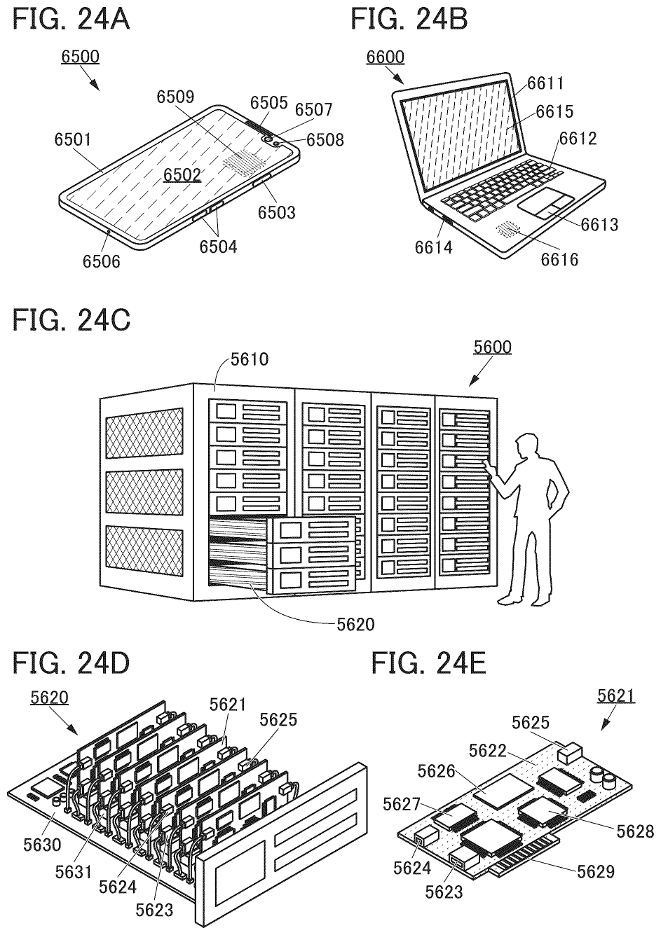

FIG. 24A is a perspective view of an electronic device 6500. The electronic device 6500 illustrated in FIG. 24A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are provided as the control device 6509, for example. The semiconductor device of one embodiment of the present invention can be used for the display portion 6502, the control device 6509, and the like, for example.

An electronic device 6600 illustrated in FIG. 24B is an information terminal that can be used as a notebook personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 24C is a perspective view of a large computer 5600. In the large computer 5600 illustrated in FIG. 24C, a plurality of rack mount computers 5620 are stored in a rack 5610. Note that the large computer 5600 may be referred to as a supercomputer.

The computer 5620 can have a structure in a perspective view of FIG. 24D, for example. In FIG. 24D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 24E is an example of a processing board provided with a CPU, a GPU, a memory device, and the like. The PC card 5621 includes a board 5622. The board 5622 includes the connection terminal 5623, the connection terminal 5624, and the connection terminal 5625, a semiconductor device 5626, a semiconductor device 5627, a semiconductor device 5628, and a connection terminal 5629. Although FIG. 24E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

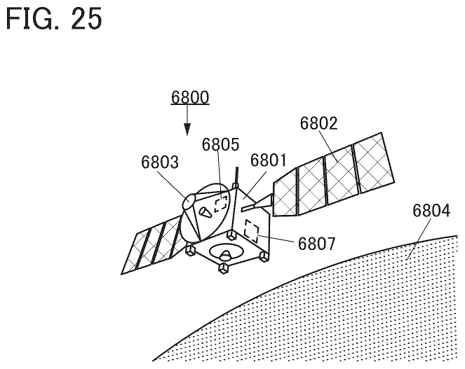

FIG. 25 illustrates an artificial satellite 6800 as an example of space equipment. The artificial satellite 6800 includes a body 6801, a solar panel 6802, an antenna 6803, a secondary battery 6805, and a control device 6807. FIG. 25 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 25, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. One or more selected from a CPU, a GPU, and a memory device are used as the control device 6807, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. The management of long-term data needs an increase in building size owing to installation of storages and servers for storing an enormous amount of data, stable electric power for data retention, cooling equipment necessary for data retention, and the like.

With the use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high-temperature environment. Thus, the reliability of the data center can be increased.

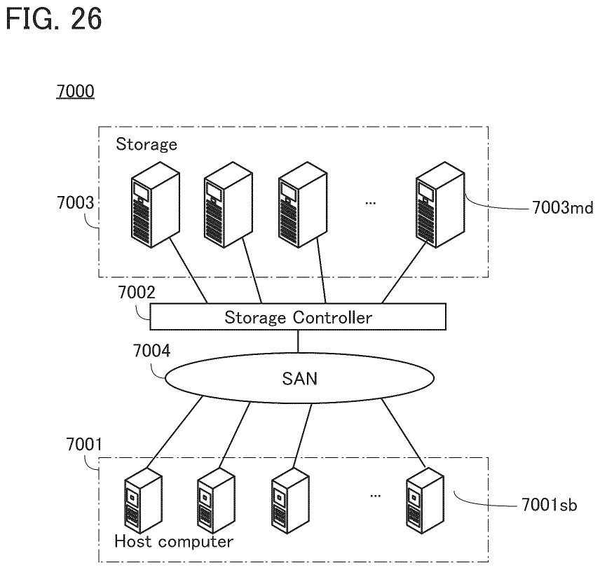

FIG. 26 illustrates a storage system that can be used in a data center. A storage system 7000 illustrated in FIG. 26 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM (Dynamic Random Access Memory) that can be used as a cache memory in a storage. In the storage system, in order to solve the problem of low access speed of the storage 7003, a cache memory is normally provided in the storage to shorten data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### REFERENCE NUMERALS

CDV: arithmetic circuit, CDVA: arithmetic circuit, MACA1: arithmetic cell array, MACA2: arithmetic cell array, MEMA1: memory cell array, MEMA2: memory cell array, WSD1: circuit, WSD2: circuit, XCS1: circuit, XCS2: circuit, WCS: circuit, ITRZ: circuit, WWD1: circuit, WWD2: circuit, RWD1: circuit, RWD2: circuit, CM: current generation circuit, CM1: current generation circuit, CM2: current generation circuit, RL: current generation circuit, RL1: current generation circuit, RL2: current generation circuit, RL3: converter circuit, SWC1: switching circuit, SWC2: switching circuit, SWC3: switching circuit, SWC5: switching circuit, SWC6: switching circuit, C1Ti[1]: terminal, C1Ti[s]: terminal, C1To[1]: terminal, C1To[s]: terminal, C2Ti[1]: terminal, C2Ti[s]: terminal, C2To[1]: terminal, C2To[s]: terminal, CTi[1]: terminal, CTi[s]: terminal, CTo[1]: terminal, CTo[s]: terminal, R1Ti[1]: terminal, R1Ti[s]: terminal, R1To[1]: terminal, R1To[s]: terminal, R2Ti[1]: terminal, R2Ti[s]: terminal, R2To[1]: terminal, R2To[s]: terminal, RTi[1]: terminal, RTi[s]: terminal, RTo[1]: terminal, RTo[s]: terminal, T1a[1]: terminal, T1a[s]: terminal, T1b[1]: terminal, T1b[s]: terminal, T1c[1]: terminal, T1c[s]: terminal, T1d[1]: terminal, T1d[s]: terminal, T2a[1]: terminal, T2a[s]: terminal, T2b[1]: terminal, T2b[s]: terminal, T2c[1]: terminal, T2c[s]: terminal, T3a[1]: terminal, T3a[s]: terminal, T3b[1]: terminal, T3b[s]: terminal, T3c[1]: terminal, T3c[s]: terminal, T5a[1]: terminal, T5a[s]: terminal, T5b[1]: terminal, T5b[s]: terminal, T5c[1]: terminal, T5c[s]: terminal, T6a[1]: terminal, T6a[s]: terminal, T6b[1]: terminal, T6b[s]: terminal, T6c[1]: terminal, T6c[s]: terminal, IM1[1,1]: cell, U1: terminal, U2: terminal, IM1[s, 1]: cell, IM1[1,s]: cell, IM1[s,s]: cell, IM2[1,1]: cell, IM2[s, 1]: cell, IM2[1,s]: cell, IM2[s,s]: cell, MC1[1, 1]: cell, MC1[s, 1]: cell, MC1[1,s]: cell, MC1[s,s]: cell, MC2[1,1]: cell, MC2[s,1]: cell, MC2[1,s]: cell, MC2[s,s]: cell, WCSa[1]: circuit, WCSa[s]: circuit, XCSa[1]: circuit, XCSa[s]: circuit, ITRZa[1]: circuit, ITRZa[s]: circuit, SWCA: circuit, SWCB: circuit, CG[1]: circuit, CG[s]: circuit, RCG[1]: circuit, RCG[s]: circuit, WSL1[1]: wiring, WSL1[s]: wiring, WCL1[1]: wiring, WCL1[s]: wiring, XCL1[1]: wiring, XCL1[s]: wiring, WSL2[1]: wiring, WSL2[s]: wiring, WCL2[1]: wiring, WCL2[s]: wiring, XCL2[1]: wiring, XCL2[s]: wiring, WWL1[1]: wiring, WWL1[s]: wiring, RWL1[1]: wiring, RWL1[s]: wiring, BL1[1]: wiring, BL1[s]: wiring, WWL2[1]: wiring, WWL2[s]: wiring, RWL2[1]: wiring, RWL2[s]: wiring, BL2[1]: wiring, BL2[s]: wiring, VE0: wiring, VE1: wiring, VE2: wiring, VE3: wiring, VDE: wiring, VSE: wiring, DW[1]: wiring, DW[2]: wiring, DW[M]: wiring, DX[1]: wiring, DX[2]: wiring, DX[Z]: wiring, VTL: wiring, VTHL: wiring, SWLA: wiring, SWLB: wiring, RSWL1: wiring, RSWL2: wiring, RSWL3: wiring, IM: cell, MC: cell, WSL: wiring, WCL: wiring, XCL: wiring, BL: wiring, WWL: wiring, RWL: wiring, IWL[1]: wiring, IWL[s]: wiring, IXL[1]: wiring, IXL[s]: wiring, OL[1]: wiring, OL[s]: wiring, F1: transistor, F1d: transistor, F2: transistor, F2d: transistor, F5: transistor, F5d: transistor, Tr7: transistor, Tr7m: transistor, Tr8: transistor, Tr8m: transistor, Tr9: transistor, Tr9m: transistor, Tr10: transistor, Tr10m: transistor, Tr11: transistor, Tr11m: transistor, Tr12: transistor, Tr12m: transistor, Tr13: transistor, Tr13m: transistor, Tr14: transistor, Tr14m: transistor, Tr15: transistor, Tr15m: transistor, Tr16: transistor, Tr16m: transistor, Tr17: transistor, Tr17m: transistor, C5: capacitor, C5d: capacitor, CI: constant current source, N[1,1]: node, N[s, 1]: node, N[1,s]: node, N[s,s]: node, Nd[1]: node, Nd[s]: node, SA[1]: switch, SA[s]: switch, SA[k]: switch, SB[1]: switch, SB[s]: switch, SB[k]: switch, SWW: switch, SWX: switch, OP1: operational amplifier, LE: load, PHRL: circuit layer, OMEL: memory layer, OMEL1: memory layer, OMEL2: memory layer, OMAL: arithmetic layer, OMAL1: arithmetic layer, OMAL2: arithmetic layer, BS1: substrate, BS2: substrate, 311: substrate, 400: transistor, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 735: semiconductor device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001: host, 7001sb: server, 7002: storage control circuit, 7003: storage, 7003md: memory device, 7004: storage area network

1. A semiconductor device comprising:
a first cell, a second cell, a third cell, and a fourth cell;
a first circuit and a second circuit;
a first current generation circuit, a second current generation circuit, a third current generation circuit, and a fourth current generation circuit,
wherein the first cell is electrically connected to a first input terminal of the first current generation circuit through a first wiring,
wherein the first cell is electrically connected to the first circuit and a fourth output terminal of the fourth current generation circuit through a second wiring,
wherein the second cell is electrically connected to a second input terminal of the second current generation circuit through a third wiring,
wherein the second cell is electrically connected to the second circuit and a third output terminal of the third current generation circuit through a fourth wiring,
wherein the third cell is electrically connected to a first output terminal of the first current generation circuit and a third input terminal of the third current generation circuit,
wherein the fourth cell is electrically connected to a second output terminal of the second current generation circuit and a fourth input terminal of the fourth current generation circuit,
wherein the first circuit is configured to generate a first current and to output the first current to the second wiring,
wherein the second circuit is configured to generate a second current and to output the second current to the fourth wiring,
wherein the first current generation circuit as a current mirror circuit is configured to output, from the first output terminal, a current with an amount corresponding to an amount of a current flowing through the first input terminal,
wherein the second current generation circuit as a current mirror circuit is configured to output, from the second output terminal, a current with an amount corresponding to an amount of a current flowing through the second input terminal,
wherein the third current generation circuit as an arithmetic circuit of a function system is configured to output, from the third output terminal, a third current with an amount corresponding to an amount of a current flowing through the third input terminal,
wherein the fourth current generation circuit as an arithmetic circuit of a function system is configured to output, from the fourth output terminal, a fourth current with an amount corresponding to an amount of a current flowing through the fourth input terminal,
wherein the first cell is configured to retain a potential corresponding to first data and is configured to generate a fifth current with an amount corresponding to a product of a value of the first data and a value corresponding to the first current or the fourth current flowing through the second wiring and to output the fifth current to the first wiring,
wherein the second cell is configured to retain a potential corresponding to second data and is configured to generate a sixth current with an amount corresponding to a product of a value of the second data and a value corresponding to the second current or the third current flowing through the fourth wiring and to output the sixth current to the third wiring,
wherein the third cell is configured to retain a potential corresponding to the fifth current, and
wherein the fourth cell is configured to retain a potential corresponding to the sixth current.

2. The semiconductor device according to claim 1, further comprising:
a first switching circuit, a second switching circuit, a third switching circuit, a fourth switching circuit, and a fifth switching circuit,
wherein the first switching circuit comprises a first terminal, a second terminal, a third terminal, and a fourth terminal,
wherein the second switching circuit comprises a fifth terminal, a sixth terminal, and a seventh terminal,
wherein the third switching circuit comprises an eighth terminal, a ninth terminal, and a tenth terminal,
wherein the fourth switching circuit comprises an eleventh terminal, a twelfth terminal, and a thirteenth terminal,
wherein the fifth switching circuit comprises a fourteenth terminal, a fifteenth terminal, and a sixteenth terminal,
wherein the first terminal of the first switching circuit is electrically connected to the first wiring,
wherein the second terminal of the first switching circuit is electrically connected to the first input terminal of the first current generation circuit,
wherein the third terminal of the first switching circuit is electrically connected to the third wiring,
wherein the fourth terminal of the first switching circuit is electrically connected to the second input terminal of the second current generation circuit,
wherein the fifth terminal of the second switching circuit is electrically connected to the first output terminal of the first current generation circuit,
wherein the sixth terminal of the second switching circuit is electrically connected to the third cell,
wherein the seventh terminal of the second switching circuit is electrically connected to the third input terminal of the third current generation circuit,
wherein the eighth terminal of the third switching circuit is electrically connected to the second output terminal of the second current generation circuit,
wherein the ninth terminal of the third switching circuit is electrically connected to the fourth cell,
wherein the tenth terminal of the third switching circuit is electrically connected to the fourth input terminal of the fourth current generation circuit,
wherein the eleventh terminal of the fourth switching circuit is electrically connected to the first circuit,
wherein the twelfth terminal of the fourth switching circuit is electrically connected to the second wiring,
wherein the thirteenth terminal of the fourth switching circuit is electrically connected to the fourth output terminal of the fourth current generation circuit,
wherein the fourteenth terminal of the fifth switching circuit is electrically connected to the second circuit,
wherein the fifteenth terminal of the fifth switching circuit is electrically connected to the fourth wiring,
wherein the sixteenth terminal of the fifth switching circuit is electrically connected to the third output terminal of the third current generation circuit,
wherein the first switching circuit is configured to establish a conduction state or a non-conduction state between the first terminal and the second terminal, is configured to establish a conduction state or a non-conduction state between the first terminal and the third terminal, and is configured to establish a conduction state or a non-conduction state between the third terminal and the fourth terminal,
wherein the second switching circuit is configured to establish a conduction state or a non-conduction state between the fifth terminal and the sixth terminal and is configured to establish a conduction state or a non-conduction state between the sixth terminal and the seventh terminal,
wherein the third switching circuit is configured to establish a conduction state or a non-conduction state between the eighth terminal and the ninth terminal and is configured to establish a conduction state or a non-conduction state between the ninth terminal and the tenth terminal,
wherein the fourth switching circuit is configured to establish a conduction state or a non-conduction state between the eleventh terminal and the twelfth terminal and is configured to establish a conduction state or a non-conduction state between the twelfth terminal and the thirteenth terminal, and
wherein the fifth switching circuit is configured to establish a conduction state or a non-conduction state between the fourteenth terminal and the fifteenth terminal and is configured to establish a conduction state or a non-conduction state between the fifteenth terminal and the sixteenth terminal.

3. The semiconductor device according to claim 2, further comprising:
a third circuit,
wherein the third circuit is electrically connected to the first wiring, and
wherein the third circuit is configured to make a seventh current corresponding to the first data flow to the first cell and is configured to make an eighth current corresponding to the second data flow to the second cell.

4. The semiconductor device according to claim 3, further comprising:
a fifth cell and a sixth cell,
wherein each of the first cell, the second cell, the fifth cell, and the sixth cell comprises a first transistor, a second transistor, and a first capacitor,
wherein a channel formation region of each of the first transistor and the second transistor comprises a first oxide semiconductor,
wherein the first oxide semiconductor comprises one or more selected from indium, zinc, and an element M,
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony,
wherein in each of the first cell, the second cell, the fifth cell, and the sixth cell:
one of a source and a drain of the first transistor is electrically connected to a gate of the second transistor;
one of a source and a drain of the second transistor is electrically connected to the one of the source and the drain of the first transistor; and
one of a pair of terminals of the first capacitor is electrically connected to the gate of the second transistor,
wherein in the first cell:
the other of the source and the drain of the first transistor is electrically connected to the first wiring; and
the other of the pair of terminals of the first capacitor is electrically connected to the second wiring,
wherein in the second cell:
the other of the source and the drain of the first transistor is electrically connected to the third wiring; and
the other of the pair of terminals of the first capacitor is electrically connected to the fourth wiring,
wherein in the fifth cell:
the other of the source and the drain of the first transistor is electrically connected to the second wiring; and
the other of the pair of terminals of the first capacitor is electrically connected to the second wiring, and
wherein in the sixth cell:
the other of the source and the drain of the first transistor is electrically connected to the fourth wiring; and
the other of the pair of terminals of the first capacitor is electrically connected to the fourth wiring.

5. The semiconductor device according to claim 4,
wherein each of the third cell and the fourth cell comprises a third transistor, a fourth transistor, a fifth transistor, and a second capacitor,
wherein a channel formation region of each of the third transistor and the fourth transistor comprises a second oxide semiconductor,
wherein the second oxide semiconductor comprises one or more selected from indium, zinc, and the element M,
wherein in each of the third cell and the fourth cell:
one of a source and a drain of the third transistor is electrically connected to a gate of the fourth transistor;
one of a source and a drain of the fourth transistor is electrically connected to one of a source and a drain of the fifth transistor;
the other of the source and the drain of the fifth transistor is electrically connected to the other of the source and the drain of the third transistor; and
the one of the pair of terminals of the first capacitor is electrically connected to the gate of the fourth transistor,
wherein in the third cell:
the other of the source and the drain of the third transistor is electrically connected to the sixth terminal of the second switching circuit, and
wherein in the fourth cell:
the other of the source and the drain of the third transistor is electrically connected to the ninth terminal of the third switching circuit.

6. The semiconductor device according to claim 5, further comprising:
a first layer, a second layer located above the first layer, and a third layer located above the second layer,
wherein the first layer comprises the first circuit, the second circuit, the third circuit, the first current generation circuit, the second current generation circuit, the third current generation circuit, and the fourth current generation circuit,
wherein the second layer comprises the third cell and the fourth cell, and
wherein the third layer comprises the first cell, the second cell, the fifth cell, and the sixth cell.

7. The semiconductor device according to claim 5, further comprising:
a first layer, a second layer located above the first layer, a third layer located above the second layer, a fourth layer located above the third layer, and a fifth layer located above the fourth layer,
wherein the first layer comprises the first circuit, the second circuit, the third circuit, the first current generation circuit, the second current generation circuit, the third current generation circuit, and the fourth current generation circuit,
wherein the second layer comprises the third cell,
wherein the third layer comprises the fourth cell,
wherein the fourth layer comprises the first cell and the fifth cell, and
wherein the fifth layer comprises the second cell and the sixth cell.

8. An electronic device comprising:
the semiconductor device according to claim 1; and
a housing.
